(19) United States
(12) Patent Application Publication
(10) Pub. No.: US 2014/0034924 A1
(43) Pub. Date: Feb. 6, 2014

(54) Heterocyclic Compound and Light-Emitting Device, Display Device, Lighting Device, and Electronic Device Using the Same

(71) Applicant: Semiconductor Energy Laboratory Co., Ltd., Kanagawa-ken (JP)

(72) Inventors: Yuko Kawata, Atsugi (JP); Hiroshi Kadoma, Sagamihara (JP); Satoko Shitagaki, Isehara (JP); Satoshi Seo, Sagamihara (JP)

(73) Assignee: Semiconductor Energy Laboratory Co., Ltd., Kanagawa-ken (JP)

(21) Appl. No.: 13/953,965

(22) Filed: Jul. 30, 2013

(30) Foreign Application Priority Data
Jul. 31, 2012 (JP) 2012-169696
May 3, 2013 (JP) 2013-097202

(51) Int. Cl. H01L 51/00; H01L 51/50

(52) U.S. Cl. CPC H01L 51/0072; H01L 51/5016; H01L 51/0094
USPC 257/40; 548/305.1; 548/301.1; 548/110; 544/343

(57) ABSTRACT

Provided is a compound having an indolo[3,2,1-jk]carbazole skeleton and a heterocyclic skeleton which are bonded to each other through an arylene group. The heterocyclic skeleton contains an imidazole skeleton, a pyrazine skeleton, a pyrimidine skeleton, a triazole skeleton, or a condensed heteroaromatic ring including any of these heterocycles. The high carrier-transport property and the large band gap of the compound allows the used as a host material of a phosphorescent dopant, leading to the formation of a green to blue emissive phosphorescent light-emitting element having high emission efficiency, low driving voltage, and reduced power consumption.

### BACKGROUND OF THE INVENTION

1. Field of the Invention

The present invention relates to a carbazole compound that can be used as a light-emitting element material. The present invention further relates to a light-emitting element and an organic semiconductor element each using the carbazole compound.

2. Description of the Related Art

As next generation lighting devices or display devices, display devices using light-emitting elements (organic EL elements) in which organic compounds are used as light-emitting substances have been rapidly developed because of their advantages of thinness, lightweightness, high speed response to input signals, low power consumption, etc.

In an organic EL element, voltage application between electrodes, between which a light-emitting layer is interposed, causes recombination of electrons and holes injected from the electrodes, which brings a light-emitting substance into an excited state, and the return from the excited state to the ground state is accompanied by light emission. Since the wavelength of light emitted from a light-emitting substance depends on the light-emitting substance, use of different organic compounds as light-emitting substances makes it possible to obtain light-emitting elements which exhibit various wavelengths, i.e., various colors.

In the case of display devices which are used to display images, such as displays, at least three-color light, i.e., red light, green light, and blue light is necessary for reproduction of full-color images. Further, in application to lighting devices, it is ideal to provide light thoroughly in the visible region for obtaining a high color rendering property, but in reality, light obtained by mixing two or more kinds of light having different wavelengths is used for lighting application in many cases. It is known that, with a mixture of three-color light, i.e., red light, green light, and blue light, white light having a high color rendering property can be obtained.

Color of light emitted from a light-emitting substance depends on the substance, as described above. However, important performances as a light-emitting element, such as lifetime, power consumption, and even emission efficiency, are not only dependent on a light-emitting substance but also greatly dependent on layers other than a light-emitting layer, an element structure, properties of an emission substance and a host material, interrelation between their properties, carrier balance, or the like. Therefore, it is true that many kinds of materials for light-emitting elements are necessary for the growth of this field. For the above-described reasons, materials for light-emitting elements with a variety of molecular structures have been proposed (e.g., see Patent Document 1).

As is generally known, the generation ratio of a singlet excited state to a triplet excited state in a light-emitting element thought electroluminescence is 1:3. Therefore, a light-emitting element in which a phosphorescent material capable of converting the triplet excited state to light emission is used as an emission substance can theoretically realize higher emission efficiency than a light-emitting element in which a fluorescent material capable of converting the singlet excited state to light emission is used as an emission substance.

However, the triplet excited state of a substance is at a lower energy level than its singlet excited state. Therefore, when a fluorescent material and a phosphorescent material give emissions at the same wavelength, the phosphorescent material has a wider band gap (energy difference between a ground state and a lowest singlet excited state) than the fluorescent material.

As a substance serving as a host material in a host-guest type light-emitting layer or a substance contained in each transport layer in contact with a light-emitting layer, a substance having a wider band gap or higher triplet excitation energy (T₁ energy that is, energy difference between a triplet excited state and a singlet ground state) than an emission substance is used for efficient conversion of excitation energy to light emission from the emission substance.

Therefore, a host material and a carrier-transport material each having a further wider band gap are necessary in order to efficiently obtain phosphorescence at a short wavelength. It is very difficult to develop a material that is used for a light-emitting element and has a sufficiently wide band gap while achieving a good balance between important characteristics of a light-emitting element, such as low driving voltage and high emission efficiency.

### REFERENCE

### Patent Document

[Patent Document 1] Japanese Published Patent Application No. 2007-15933

### SUMMARY OF THE INVENTION

In view of the above, an object of one embodiment of the present invention is to provide a light-emitting element having high emission efficiency. Another object of one embodiment of the present invention is to provide a light-emitting element having a low driving voltage. Still another object of one embodiment of the present invention is to provide a light-emitting element emitting green to blue phosphorescence with high emission efficiency.

Furthermore, another object of one embodiment of the present invention is to provide a novel heterocyclic compound that can be used for a transport layer, a host material, or a light-emitting material in a light-emitting element. Specifically, an object of one embodiment of the present invention is to provide a heterocyclic compound which enables to obtain a light-emitting element having good characteristics even when the heterocyclic compound is used in a light-emitting element emitting phosphorescence at a shorter wavelength than green light.

Another object of one embodiment of the present invention is to provide a heterocyclic compound which has high T₁ level. Specifically, the object of one embodiment of the present invention is to provide a heterocyclic compound which enables to obtain a light-emitting element having high emission efficiency when the heterocyclic compound is used in a light-emitting element emitting phosphorescence at a shorter wavelength than green light.

Another object of one embodiment of the present invention is to provide a heterocyclic compound having a high carrier-transport property. Specifically, the object of one embodiment of the present invention is to provide a heterocyclic compound which can be used in a light-emitting element emitting phosphorescence at a shorter wavelength than green light and enables to obtain a light-emitting element with low driving voltage.

Another object of one embodiment of the present invention is to provide a light-emitting element containing the heterocyclic compound.

Another object of one embodiment of the present invention is to provide a display module, a lighting module, a light-emitting device, a lighting device, a display device, and an electronic device each using the heterocyclic compound and achieving low power consumption.

It is only necessary that at least one of the above-described objects be achieved in the present invention.

One embodiment of the present invention is a light-emitting element which includes an EL layer containing at least an emission substance between a pair of electrodes, and emits light by voltage application between the pair of electrodes. The EL layer includes a heterocyclic compound having an indolo[3,2,1-jk]carbazole skeleton and a heterocyclic skeleton that has two or more nitrogen atoms in the ring.

Another embodiment of the present invention is a light-emitting element with the above-mentioned structure, in which the heterocyclic skeleton which has two or more nitrogen atoms in the ring is any one of an imidazole skeleton, a pyrazine skeleton, a pyrimidine skeleton, a triazole skeleton and these skeletons to which benzene is fused (i.e., condensed heteroaromatic ring containing the heterocycle therein).

Another embodiment of the present invention is a light-emitting element with the above-mentioned structure in which, in the heterocyclic compound, the indolo[3,2,1-jk]carbazole skeleton and the heterocyclic skeleton are bonded to each other through an arylene group.

Another embodiment of the present invention is a light-emitting element with the above-mentioned structure, in which the EL layer includes a light-emitting layer and an electron-transport layer in contact with a cathode side surface of the light-emitting layer, and the light-emitting layer contains at least an emission substance and the heterocyclic compound.

Another embodiment of the present invention is a light-emitting element with the above-mentioned structure, in which the EL layer includes a light-emitting layer and an electron-transport layer in contact with a cathode side surface of the light-emitting layer, the light-emitting layer contains at least an emission substance and the heterocyclic compound, and a common skeleton is included in the heterocyclic compound and an electron-transport material contained in the electron-transport layer. That is, the electron-transport material includes the imidazole skeleton, the pyrazine skeleton, the triazole skeleton, or the indolo[3,2,1-jk]carbazole skeleton.

Another embodiment of the present invention is a light-emitting element with the above-mentioned structure, in which the electron-transport material is the heterocyclic compound.

Another embodiment of the present invention is a heterocyclic compound represented by General Formula (G1).

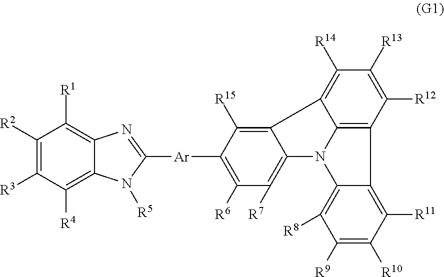

In General Formula (G1), R¹ to R⁴ and R⁶ to R¹⁵ each independently represent any one of hydrogen, an alkyl group having 1 to 4 carbon atoms, and an aryl group having 6 to 13 carbon atoms, R⁵ represents an alkyl group having 1 to 4 carbon atoms or an aryl group having 6 to 13 carbon atoms, and Ar represents an arylene group having 6 to 13 carbon atoms.

Another embodiment of the present invention is a heterocyclic compound with the above structure, in which Ar is a substituted or unsubstituted phenylene group or a substituted or unsubstituted biphenyldiyl group.

Another embodiment of the present invention is a heterocyclic compound with the above structure, in which Ar is a substituted or unsubstituted phenylene group.

Another embodiment of the present invention is a heterocyclic compound with the above structure, in which Ar is a substituted or unsubstituted m-phenylene group.

Another embodiment of the present invention is a heterocyclic compound represented by General Formula (G2).

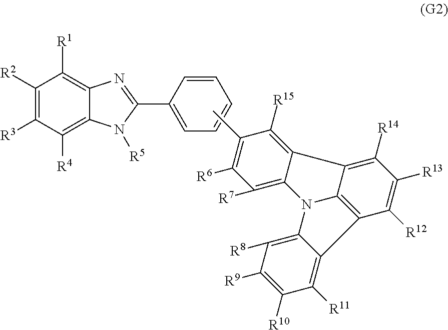

In General Formula (G2), R¹ to R⁴ and R⁶ to R¹⁵ each independently represent any one of hydrogen, an alkyl group having 1 to 4 carbon atoms, and an aryl group having 6 to 13 carbon atoms, and R⁵ represents an alkyl group having 1 to 4 carbon atoms or an aryl group having 6 to 13 carbon atoms.

Another embodiment of the present invention is a heterocyclic compound represented by General Formula (G3).

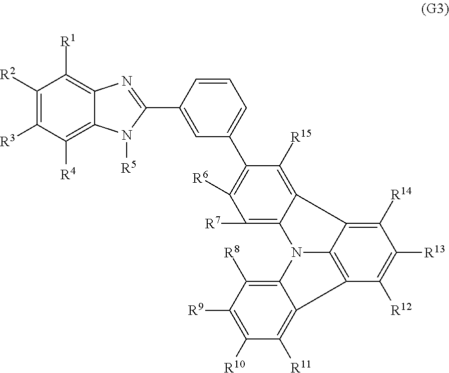

In General Formula (G3), R¹ to R⁴ and R⁶ to R¹⁵ each independently represent any one of hydrogen, an alkyl group having 1 to 4 carbon atoms, and an aryl group having 6 to 13 carbon atoms, and R⁵ represents an alkyl group having 1 to 4 carbon atoms or an aryl group having 6 to 13 carbon atoms.

Another embodiment of the present invention is a heterocyclic compound represented by General Formula (G4).

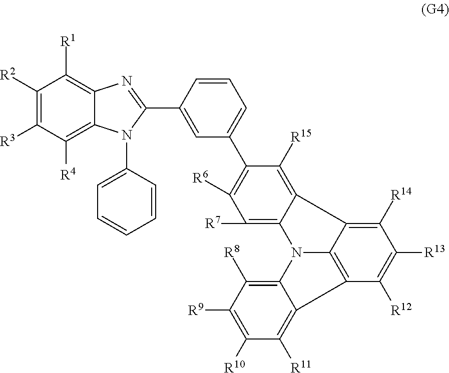

In General Formula (G4), R¹ to R⁴ and R⁶ to R¹⁵ each independently represent any one of hydrogen, an alkyl group having 1 to 4 carbon atoms and an aryl group having 6 to 13 carbon atoms.

Another embodiment of the present invention is a heterocyclic compound represented by Structural Formula (100).

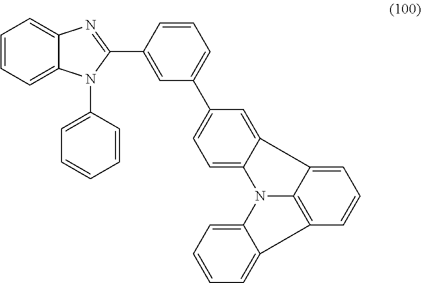 [SMILES: c1ccc(-n2c(-c3cccc(-c4ccc5c(c4)c4cccc6c7ccccc7n5c64)c3)nc3ccccc32)cc1]

Another embodiment of the present invention is a light-emitting element including a pair of electrodes and an EL layer between the pair of electrodes. The EL layer contains the heterocyclic compound with any of the above structures.

Another embodiment of the present invention is a light-emitting element including a pair of electrodes and an EL layer between the pair of electrodes. The EL layer includes a light-emitting layer. The light-emitting layer contains an emission substance and the heterocyclic compound with any of the above structures.

Another embodiment of the present invention is a light-emitting element with the above structure, further including an electron-transport layer in contact with a cathode side surface of the light-emitting layer. In the light-emitting element, a substance contained in the electron-transport layer has a skeleton (i.e., the imidazole skeleton, the pyrazine skeleton, the triazole skeleton, or the indolo[3,2,1-jk]carbazole skeleton) that is the same as a skeleton included in the heterocyclic compound.

Another embodiment of the present invention is a light-emitting element with the above structure, in which the emission substance is a phosphorescent material.

Another embodiment of the present invention is a light-emitting element with the above structure, in which an emission peak of the phosphorescent material is from 400 nm to 550 nm.

Another embodiment of the present invention is a display module including the light-emitting element with any of the above structures.

Another embodiment of the present invention is a lighting module including the light-emitting element with any of the above structures.

Another embodiment of the present invention is a light-emitting device including the light-emitting element with any of the above structures and a unit for controlling the light-emitting element.

Another embodiment of the present invention is a display device including the light-emitting element with any of the above structures in a display portion, and a unit for controlling the light-emitting element.

Another embodiment of the present invention is a lighting device including the light-emitting element with any of the above structures in a lighting portion, and a unit for controlling the light-emitting element.

Another embodiment of the present invention is an electronic device including the light-emitting element with any of the above structures.

A light-emitting element in accordance with one embodiment of the present invention has high emission efficiency, low driving voltage, or high emission efficiency and emits light in green to blue regions.

A heterocyclic compound of one embodiment of the present invention has a wide band gap. Further, the heterocyclic compound has a high carrier-transport property. Accordingly, the heterocyclic compound can be suitably used in a light-emitting element, as a material of a transport layer, a host material in a light-emitting layer, or an emission substance in the light-emitting layer.

Another embodiment of the present invention can provide a display module, a lighting module, a light-emitting device, a lighting device, a display device, and an electronic device each using the heterocyclic compound and achieving low power consumption.

### BRIEF DESCRIPTION OF THE DRAWINGS

FIGS. 1A and 1B are conceptual diagrams of light-emitting elements.

FIG. 2 is a conceptual diagram of an organic semiconductor element.

FIGS. 3A and 3B are conceptual diagrams of an active matrix light-emitting device.

FIGS. 4A and 4B are conceptual diagrams of active matrix light-emitting devices.

FIG. 5 is a conceptual diagram of an active matrix light-emitting device.

FIGS. 6A and 6B are conceptual diagrams of a passive matrix light-emitting device.

FIGS. 7A to 7D illustrate electronic devices.

FIG. 8 illustrates a light source device.

FIG. 9 illustrates a lighting device.

FIG. 10 illustrates a lighting device.

FIG. 11 illustrates car-mounted display devices and lighting devices.

FIGS. 12A to 12C illustrate an electronic device.

FIGS. 13A and 13B are NMR charts of 5-[3-(N-phenylbenzimidazol-2-yl)phenyl]indolo[3,2,1-jk]carbazole (abbreviation: mIcBIm).

FIGS. 14A and 14B show an absorption spectrum and an emission spectrum of mIcBIm.

FIGS. 15A and 15B show the results of LC/MS analysis of mIcBIm.

FIG. 16 shows current density-luminance characteristics of a light-emitting element 1.

FIG. 17 shows voltage-luminance characteristics of the light-emitting element 1.

FIG. 18 shows luminance-current efficiency characteristics of the light-emitting element 1.

FIG. 19 shows voltage-current characteristics of the light-emitting element 1.

FIG. 20 shows an emission spectrum of the light-emitting element 1.

FIG. 21 shows current density-luminance characteristics of a light-emitting element 2.

FIG. 22 shows voltage-luminance characteristics of the light-emitting element 2.

FIG. 23 shows luminance-current efficiency characteristics of the light-emitting element 2.

FIG. 24 shows voltage-current characteristics of the light-emitting element 2.

FIG. 25 shows an emission spectrum of the light-emitting element 2.

FIG. 26 shows current density-luminance characteristics of a light-emitting element 3.

FIG. 27 shows voltage-luminance characteristics of the light-emitting element 3.

FIG. 28 shows luminance-current efficiency characteristics of the light-emitting element 3.

FIG. 29 shows voltage-current characteristics of the light-emitting element 3.

FIG. 30 shows an emission spectrum of the light-emitting element 3.

FIG. 31 shows time dependence of normalized luminance of the light-emitting element 3.

FIG. 32 shows current density-luminance characteristics of a light-emitting element 4.

FIG. 33 shows voltage-luminance characteristics of the light-emitting element 4.

FIG. 34 shows luminance-current efficiency characteristics of the light-emitting element 4.

FIG. 35 shows voltage-current characteristics of the light-emitting element 4.

FIG. 36 shows an emission spectrum of the light-emitting element 4.

### DETAILED DESCRIPTION OF THE INVENTION

Hereinafter, embodiments of the present invention will be described. It is easily understood by those skilled in the art that modes and details disclosed herein can be modified in various ways without departing from the spirit and the scope of the present invention. Therefore, the present invention is not construed as being limited to description of the embodiments.

### Embodiment 1

A light-emitting element of this embodiment includes a heterocyclic compound which has an indolo[3,2,1-jk]carbazole skeleton and a heterocyclic skeleton having two or more nitrogen atoms in the ring. The heterocyclic compound is a substance having a wide band gap and high triplet level. Moreover, the heterocyclic compound has a high carrier-transport property.

Therefore, a light-emitting element containing the heterocyclic compound can have high emission efficiency. In addition, a light-emitting element containing the heterocyclic compound can have low driving voltage.

The heterocyclic skeleton having two or more nitrogen atoms in the ring, which is contained in the heterocyclic compound, is preferably an imidazole skeleton, a pyrazine skeleton, a pyrimidine skeleton, a triazole skeleton, or any of these skeletons to which benzene is fused. With the use of these skeletons, heterocyclic compounds having a high electron-transport property can be provided.

In the heterocyclic compound, it is preferable that the indolo[3,2,1-jk]carbazole skeleton and the heterocyclic skeleton having two or more nitrogen atoms in the ring be bonded to each other through an arylene group. By the bonding between these skeletons through an arylene group, the compound can have a wide band gap and high triplet level. The arylene group preferably has 6 to 13 carbon atoms. Examples of the arylene group having 6 to 13 carbon atoms include a phenylene group, a naphthylene group, a biphenyldiyl group, and a fluorenediyl group. Note that the arylene group may have a substituent, and the substituent can be an alkyl group having 1 to 4 carbon atoms, an aryl group having 6 to 12 carbon atoms, or the like. Furthermore, the substituent may be an alkylene group having 1 to 4 carbon atoms or an arylene group having 6 to 12 carbon atoms by which a ring may be formed.

It is preferable that the indolo[3,2,1-jk]carbazole skeleton and the heterocyclic skeleton be bonded not linearly to each other but bonded to each other so as to form a folded structure. This is because an interaction between orbits of the two skeletons can be smaller, the band gap width can be larger, and the triplet level can be higher. For example, when the arylene group is a phenylene group, meta substitution is preferred to para substitution. When the arylene group is a biphenyldiyl group, a 1,1′-biphenyl-3,3′-diyl group is preferred.

Since the heterocyclic compound with such a structure has a wide band gap, the heterocyclic compound can be used as a host material for a fluorescent material that emits blue light or light having a shorter wavelength than blue light, or can be used for a carrier-transport layer that is adjacent to the light-emitting layer. Since the heterocyclic compound also has high triplet level, the heterocyclic compound can be used as a host material for a phosphorescent material (in particular, a phosphorescent material emitting light with a wavelength shorter than green light), or can be used for a carrier-transport layer that is adjacent to the light-emitting layer. The heterocyclic compound has a wide band gap and high triplet level (T₁ level), so that the excited energy of carriers that has recombined in a host material can be effectively transferred to an emission substance. Thus, a light-emitting element having high emission efficiency can be manufactured.

The heterocyclic compound can be suitably used as a host material or for a carrier-transport layer in a light-emitting element also in terms of its high carrier-transport property. Owing to the high carrier-transport property of the heterocyclic compound, a light-emitting element with low driving voltage can be manufactured. Furthermore, in the case where the heterocyclic compound is used for a carrier-transport layer closer to a light-emitting region in a light-emitting layer, loss of excitation energy of an emission center substance can be suppressed because of a wide band gap or high triplet level of the heterocyclic compound, so that a light-emitting element having high emission efficiency can be achieved.

### Embodiment 2

In this embodiment, description will be made of the compound having the indolo[3,2,1-jk]carbazole skeleton and the heterocyclic skeleton described in Embodiment 1. The indolo[3,2,1-jk]carbazole compound can be represented by General Formula (G1) shown below.

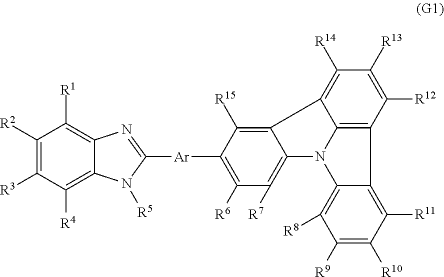

In the formula, Ar represents an arylene group having 6 to 13 carbon atoms. For simplifying the synthesis, Ar is preferably a phenylene group or a biphenyldiyl group, more preferably a phenylene group. It is preferable that Ar bond the benzimidazole skeleton and the indolo[3,2,1-jk]carbazole skeleton so as to form a folded structure compared with the case where they are bonded linearly. This is because an interaction between orbits of the two skeletons can be smaller, the band gap can be larger, and the triplet level can be higher.

Furthermore, Ar may have a substituent, and the substituent can be an alkyl group or alkylene group having 1 to 4 carbon atoms or an aryl group or arylene group having 6 to 12 carbon atoms. Alternatively, the substituent can be a 9H-9-silafluorene-9,9-diyl group.

The heterocyclic compound can be represented by General Formulae (G2) or (G3) shown below.

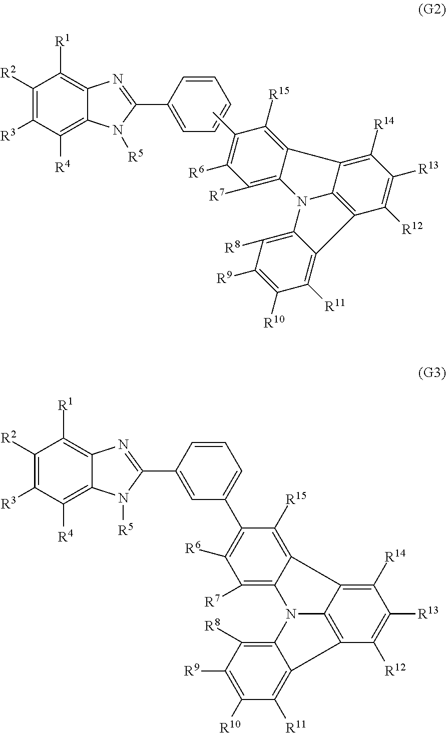

In General Formulae (G1) to (G3), R¹ to R⁴ and R⁶ to R¹⁵ each independently represent any one of hydrogen, an alkyl group having 1 to 4 carbon atoms, and an aryl group having 6 to 13 carbon atoms, R⁵ represents any one of an alkyl group having 1 to 4 carbon atoms and an aryl group having 6 to 13 carbon atoms. It is preferable that R⁵ be a phenyl group.

In the case where any of R¹ to R¹⁵ is an aryl group, the aryl group may have a substituent. The substituent can be an alkyl group having 1 to 4 carbon atoms, for example. In addition, R⁵ may further have an aryl group or arylene group having 6 to 12 carbon atoms as a substituent.

The heterocyclic compound can be represented by General Formula (G4) shown below. Note that R¹ to R⁴ and R⁶ to R¹⁵ are the same as those in the above.

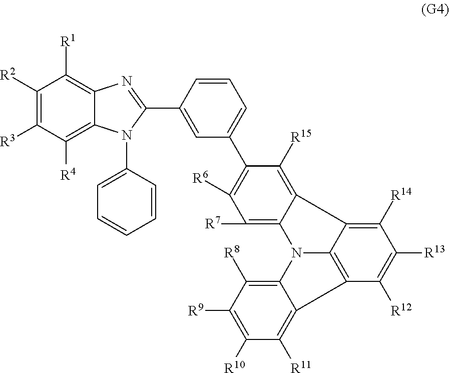

Specific examples of structures of the heterocyclic compounds represented by General Formulae (G1) to (G4) are represented by Structural Formulae (100) to (134) shown below.

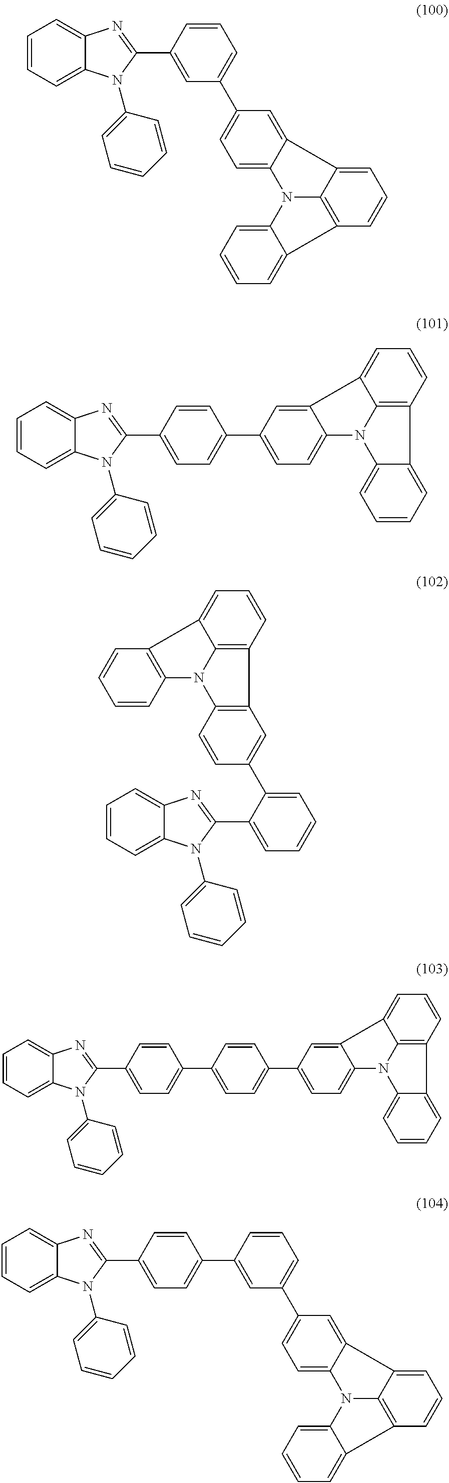

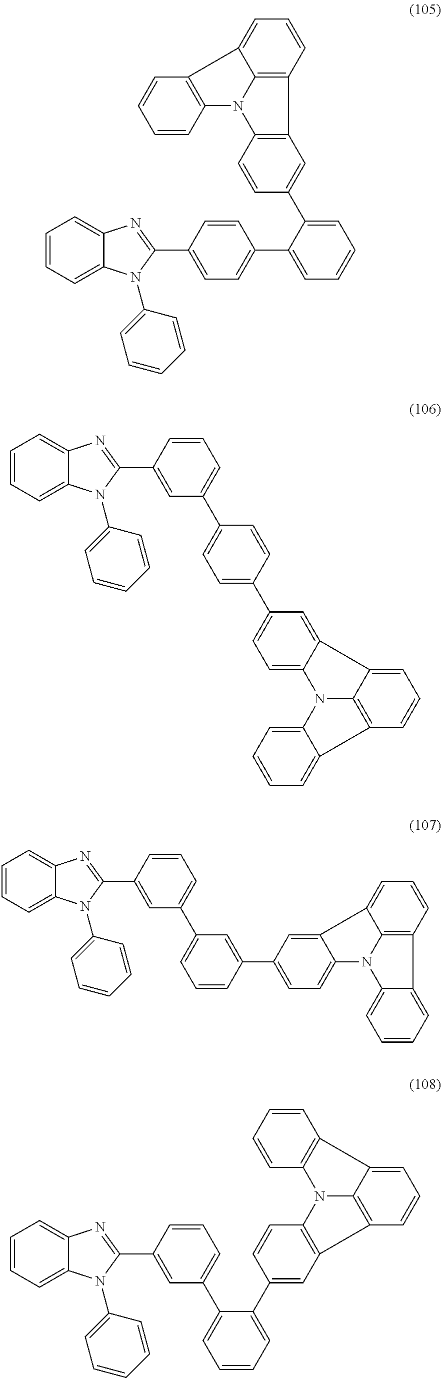

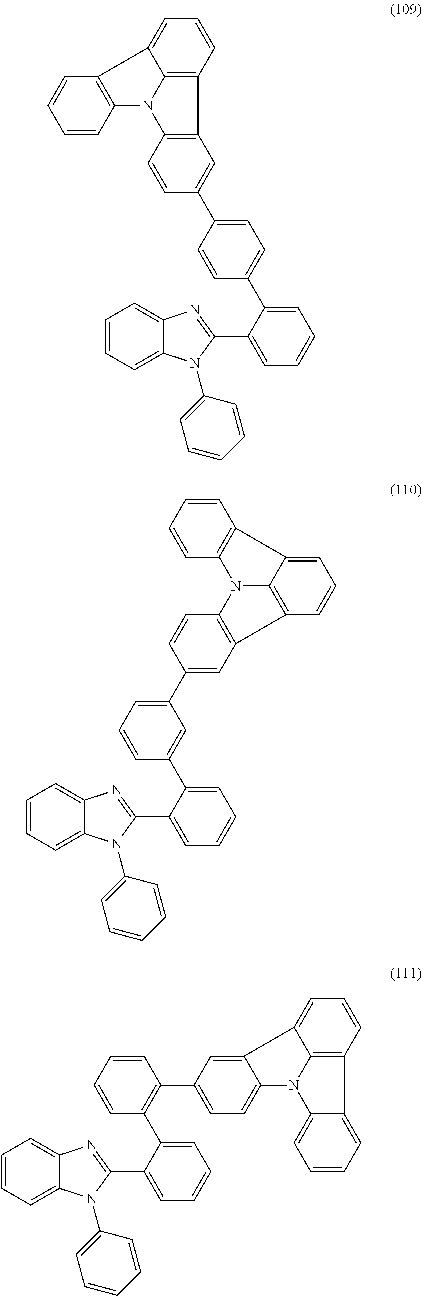

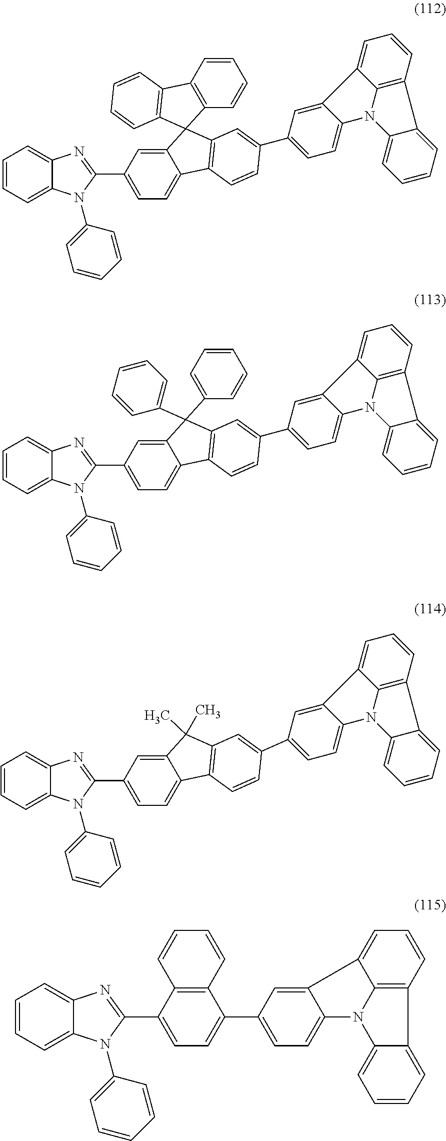

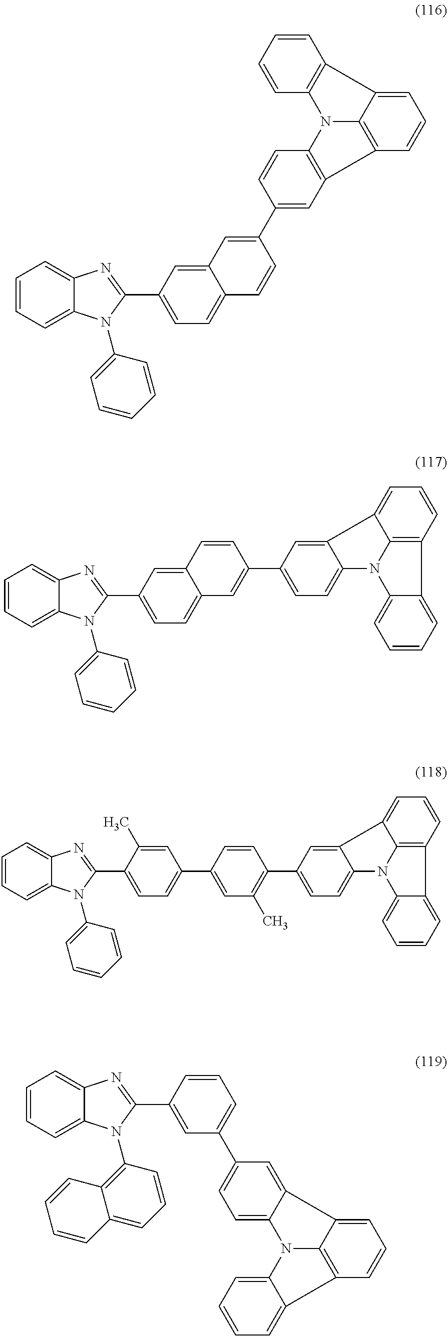

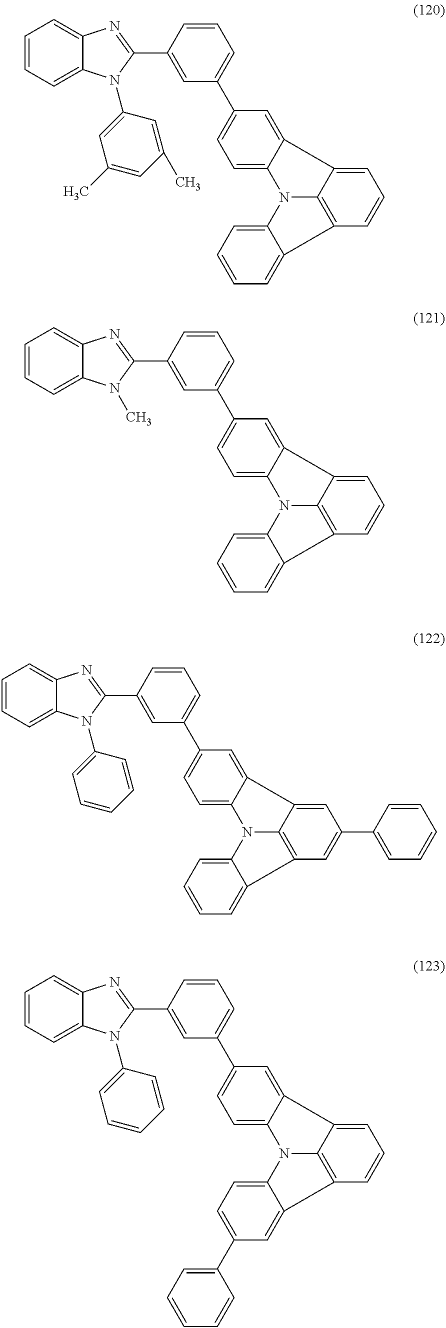

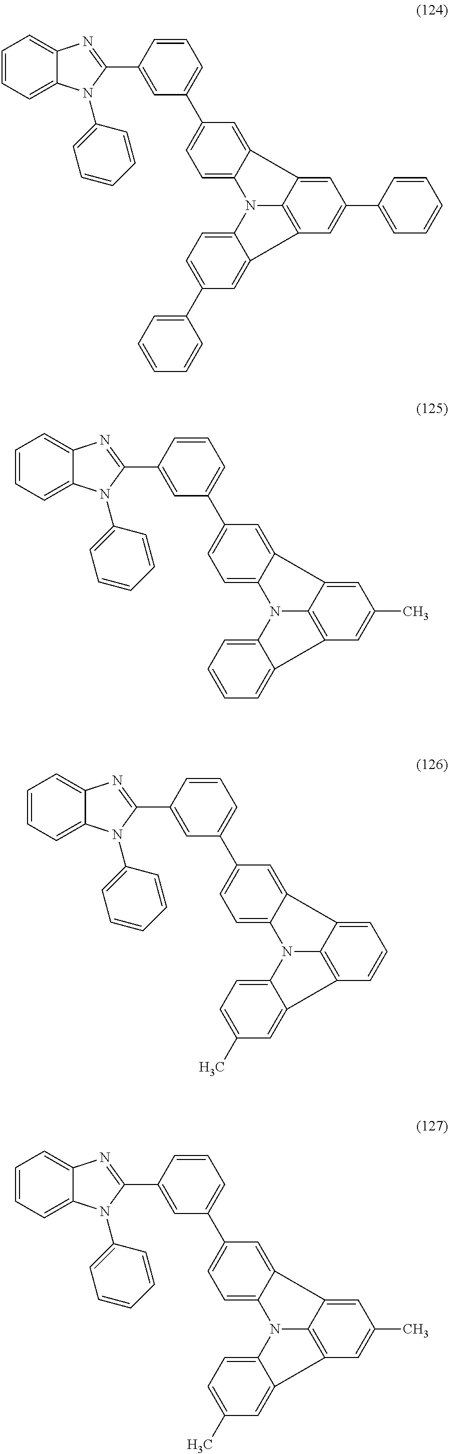

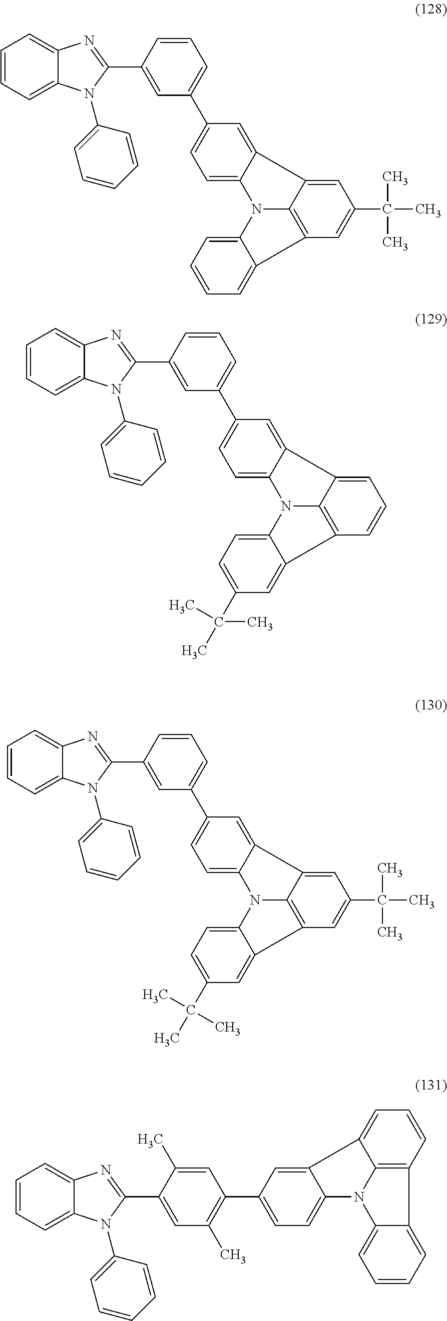

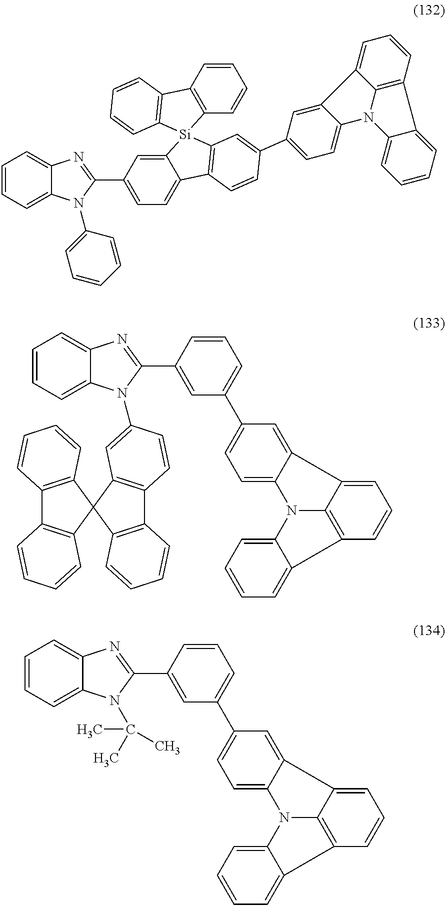

Any of the above heterocyclic compounds is suitable as a carrier-transport material or a host material because of its high carrier-transport property. Owing to this, a light-emitting element with low driving voltage can also be provided. Furthermore, a phosphorescent light-emitting element having high emission efficiency can be obtained because of the high triplet level of the heterocyclic compounds. Moreover, the high triplet level means that the heterocyclic compounds have a wide band gap, which allows a blue-emissive fluorescent light-emitting element to efficiently emit light.

Furthermore, the heterocyclic compound can be used as a light-emitting material that emits blue to ultraviolet light.

### Embodiment 3

In this embodiment, an example will be described in which the heterocyclic compound represented by General Formula (G1) described in Embodiment 2 is used for an active layer of a vertical transistor (SIT), which is a kind of an organic semiconductor element.

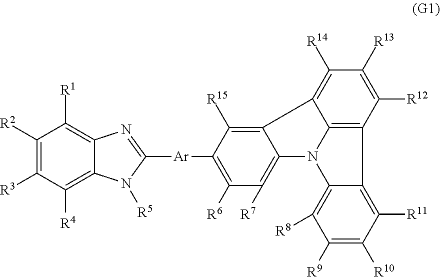

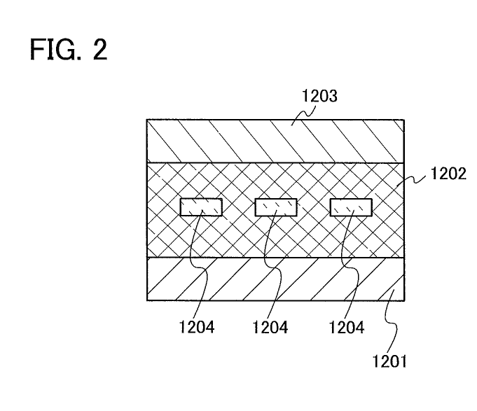

The element has a structure in which a thin-film active layer 1202 containing the heterocyclic compound represented by General Formula (G1) is interposed between a source electrode 1201 and a drain electrode 1203, and a gate electrode 1204 is embedded in the active layer 1202, as illustrated in FIG. 2. The gate electrode 1204 is electrically connected to a unit to apply a gate voltage, and the source electrode 1201 and the drain electrode 1203 are electrically connected to a unit to control the voltage between the source and the drain.

In such an element structure, when a voltage is applied between the source and the drain under the condition that a gate voltage is not applied, a current flows (an ON state). Then, when a gate voltage is applied in this state, a depletion layer is generated in the periphery of the gate electrode 1204, and thus a current does not flow (an OFF state). With such a mechanism, the element operates as a transistor.

In a vertical transistor, a material which has both a carrier-transport property and favorable film quality are required for an active layer like in a light-emitting element. Any of the heterocyclic compounds described represented by General Formula (G1) can be suitably used because it sufficiently meets these requirements.

### Embodiment 4

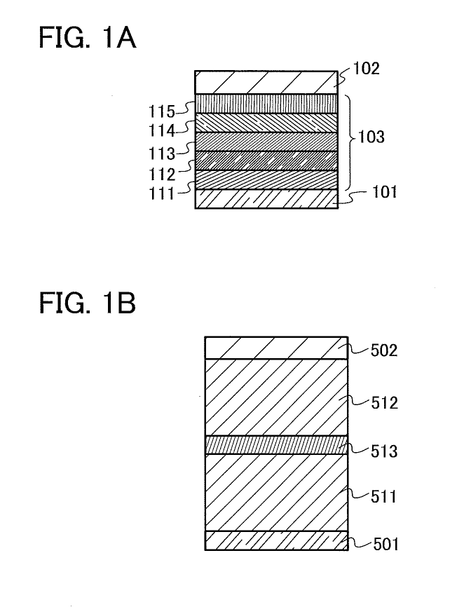

In this embodiment, description will be made with reference to FIG. 1A of one mode of the light-emitting element that contains the heterocyclic compound having an indolo[3,2,1-jk]carbazole skeleton and a heterocyclic skeleton having two or more nitrogen atoms in the ring.

The light-emitting element of this embodiment has a plurality of layers between a pair of electrodes. In this embodiment, the light-emitting element includes a first electrode 101, a second electrode 102, and an EL layer 103 provided between the first electrode 101 and the second electrode 102. Note that in FIG. 1A, the first electrode 101 functions as an anode and the second electrode 102 functions as a cathode. In other words, when a voltage is applied between the first electrode 101 and the second electrode 102 such that the potential of the first electrode 101 is higher than that of the second electrode 102, light emission can be obtained. Of course, a structure in which the first electrode functions as a cathode and the second electrode functions as an anode can be employed. In that case, the stacking order of layers in the EL layer is reversed from the stacking order described below. Note that in the light-emitting element of this embodiment, any layer in the EL layer 103 may contain the heterocyclic compound. Note that a layer that contains the heterocyclic compound is preferably a light-emitting layer or an electron-transport layer because characteristics of the heterocyclic compound can be utilized and a light-emitting element having favorable characteristics can be obtained.

For the electrode functioning as an anode, any of metals, alloys, electrically conductive compounds, and mixtures thereof which have a high work function (specifically, a work function of 4.0 eV or more) or the like is preferably used. Specifically, for example, indium oxide-tin oxide (ITO: indium tin oxide), indium oxide-tin oxide containing silicon or silicon oxide, indium oxide-zinc oxide, indium oxide containing tungsten oxide and zinc oxide (IWZO), and the like can be given. Films of these electrically conductive metal oxides are usually formed by a sputtering method but may be formed by application of a sol-gel method or the like. For example, a film of indium oxide-zinc oxide can be formed by a sputtering method using a target obtained by adding 1 wt % to 20 wt % of zinc oxide to indium oxide. Further, a film of indium oxide containing tungsten oxide and zinc oxide (IWZO) can be formed by a sputtering method using a target in which tungsten oxide and zinc oxide are added to indium oxide at 0.5 wt % to 5 wt % and 0.1 wt % to 1 wt %, respectively. Besides, gold (Au), platinum (Pt), nickel (Ni), tungsten (W), chromium (Cr), molybdenum (Mo), iron (Fe), cobalt (Co), copper (Cu), palladium (Pd), nitrides of metal materials (e.g., titanium nitride), and the like can be given. In addition, graphene may be used.

There is no particular limitation on a stacked structure of the EL layer 103. The EL layer 103 can be formed by combining a layer that contains a substance having a high electron-transport property, a layer that contains a substance having a high hole-transport property, a layer that contains a substance having a high electron-injection property, a layer that contains a substance having a high hole-injection property, a layer that contains a bipolar substance (a substance having a high electron-transport and hole-transport property), a layer having a carrier-blocking property, and the like as appropriate. In this embodiment, the EL layer 103 has a structure in which a hole-injection layer 111, a hole-transport layer 112, a light-emitting layer 113, an electron-transport layer 114, and an electron-injection layer 115 are stacked in this order from the side of the electrode functioning as an anode. Materials included in the layers are specifically given below.

The hole-injection layer 111 is a layer containing a substance having a hole-injection property. Molybdenum oxide, vanadium oxide, ruthenium oxide, tungsten oxide, manganese oxide, or the like can be used. Alternatively, the hole-injection layer 111 can be formed with a phthalocyanine-based compound such as phthalocyanine (abbreviation: H₂Pc) or copper phthalocyanine (abbreviation: CuPc), an aromatic amine compound such as 4,4′-bis[N-(4-diphenylaminophenyl)-N-phenylamino]biphenyl (abbreviation: DPAB) or N,N′-bis{4-[bis(3-methylphenyl)amino]phenyl}-N,N′-diphenyl-(1,1′-biphenyl)-4,4′-diamine (abbreviation: DNTPD), a high molecular compound such as poly(ethylenedioxythiophene)/poly(styrenesulfonic acid) (PEDOT/PSS), or the like.

The hole-injection layer 111 can be formed using a composite material in which a substance exhibiting an electron-accepting property (hereinafter, simply referred to as “electron-accepting substance”) with respect to a substance having a hole-transport property is contained in the substance having a hole-transport property. In this specification, the composite material refers to not a material in which two materials are simply mixed but a material in the state where charge transfer between the materials can be caused by a mixture of a plurality of materials. This charge transfer includes the charge transfer that occurs only when an electric field exists.

Note that the use of such a substance having a hole-transport property which contains an electron-accepting substance enables selection of a material used to form an electrode regardless of its work function. In other words, besides a material having a high work function, a material having a low work function can also be used for the electrode functioning as an anode. As the electron-accepting substance, 7,7,8,8-tetracyano-2,3,5,6-tetrafluoroquinodimethane (abbreviation: F₄-TCNQ), chloranil, and the like can be given. In addition, transition metal oxides can be given. Oxides of the metals that belong to Group 4 to Group 8 of the periodic table can be given. Specifically, vanadium oxide, niobium oxide, tantalum oxide, chromium oxide, molybdenum oxide, tungsten oxide, manganese oxide, and rhenium oxide are preferable in that their electron-accepting property is high. Among these, molybdenum oxide can be suitably used as the electron-accepting substance because it is stable in the air, has a low hygroscopic property, and is easily treated.

As the substance having a hole-transport property used for the composite material, any of a variety of organic compounds such as aromatic amine compounds, carbazole compounds, aromatic hydrocarbons, and high molecular compounds (e.g., oligomers, dendrimers, or polymers) can be used. Note that the organic compound used for the composite material is preferably an organic compound having a high hole-transport property. Specifically, a substance having a hole mobility of 1×10⁻⁶ cm²/Vs or more is preferably used. However, any other substance may be used as long as the substance has a hole-transport property higher than an electron-transport property. Organic compounds that can be used as the substance having a hole-transport property in the composite material are specifically given below.

Examples of the aromatic amine compounds are N,N′-di(p-tolyl)-N,N′-diphenyl-p-phenylenediamine (abbreviation: DTDPPA), DPAB, DNTPD, 1,3,5-tris[N-(4-diphenylaminophenyl)-N-phenylamino]benzene (abbreviation: DPA3B), and the like.

Specific examples of the carbazole compounds that can be used for the composite material are 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), 3-[N-(1-naphthyl)-N-(9-phenylcarbazol-3-yl)amino]-9-phenylcarbazole (abbreviation: PCzPCN1), and the like.

Other examples of the carbazole compounds that can be used for the composite material are 4,4′-di(N-carbazolyl)biphenyl (abbreviation: CBP), 1,3,5-tris[4-(N-carbazolyl)phenyl]benzene (abbreviation: TCPB), 9-[4-(10-phenyl-9-anthryl)phenyl]-9H-carbazole (abbreviation: CzPA), 1,4-bis[4-(N-carbazolyl)phenyl]-2,3,5,6-tetraphenylbenzene, and the like.

Examples of the aromatic hydrocarbons that can be used for the composite material are 2-tert-butyl-9,10-di(2-naphthyl)anthracene (abbreviation: t-BuDNA), 2-tert-butyl-9,10-di(1-naphthyl)anthracene, 9,10-bis(3,5-diphenylphenyl)anthracene (abbreviation: DPPA), 2-tert-butyl-9,10-bis(4-phenylphenyl)anthracene (abbreviation: t-BuDBA), 9,10-di(2-naphthyl)anthracene (abbreviation: DNA), 9,10-diphenylanthracene (abbreviation: DPAnth), 2-tert-butylanthracene (abbreviation: t-BuAnth), 9,10-bis(4-methyl-1-naphthyl)anthracene (abbreviation: DMNA), 2-tert-butyl-9,10-bis[2-(1-naphthyl)phenyl]anthracene, 9,10-bis[2-(1-naphthyl)phenyl]anthracene, 2,3,6,7-tetramethyl-9,10-di(1-naphthyl)anthracene, 2,3,6,7-tetramethyl-9,10-di(2-naphthyl)anthracene, 9,9′-bianthryl, 10,10′-diphenyl-9,9′-bianthryl, 10,10′-bis(2-phenylphenyl)-9,9′-bianthryl, 10,10′-bis[(2,3,4,5,6-pentaphenyl)phenyl]-9,9′-bianthryl, anthracene, tetracene, rubrene, perylene, 2,5,8,11-tetra(tert-butyl)perylene, and the like. Besides, pentacene, coronene, or the like can also be used. As these aromatic hydrocarbons given here, it is preferable that an aromatic hydrocarbon having a hole mobility of 1×10⁻⁶ cm²/Vs or more and having 14 to 42 carbon atoms be used.

Note that the aromatic hydrocarbons that can be used for the composite material may have a vinyl skeleton. Examples of the aromatic hydrocarbon having a vinyl group are 4,4′-bis(2,2-diphenylvinyl)biphenyl (abbreviation: DPVBi), 9,10-bis[4-(2,2-diphenylvinyl)phenyl]anthracene (abbreviation: DPVPA), and the like.

A high molecular compound such as poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N-phenylamino}phenyl)methacrylamide] (abbreviation: PTPDMA), or poly[N,N′-bis(4-butylphenyl)-N,N-bis(phenyl)benzidine] (abbreviation: poly-TPD) can also be used.

The hole-transport layer 112 is a layer containing a substance having a hole-transport property. As the substance having a hole-transport property, those given above as the substances having hole-transport properties, which can be used for the above composite material, can also be used. Note that detailed description is omitted to avoid repetition. Refer to the description of the composite material.

The light-emitting layer 113 is a layer containing a light-emitting substance. The light-emitting layer 113 may be formed with a film containing only a light-emitting substance or a film in which an emission substance is dispersed in a host material.

There is no particular limitation on a material that can be used as the emission substance in the light-emitting layer 113, and both fluorescent materials and phosphorescent materials can be used. The following substances can be used as the emission substance. Examples of fluorescent materials include N,N′-bis[4-(9-phenyl-9H-fluoren-9-yl)phenyl]-N,N′-diphenyl-pyrene-1,6-diamine (abbreviation: 1,6FLPAPrn), N,N′-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra-tert-butylperylene (abbreviation: TBP), 4-(10-phenyl-9-anthryl)-4′-(9-phenyl-9H-carbazol-3-yl)triphenylamine (abbreviation: PCBAPA), N,N″-(2-tert-butylanthracene-9,10-diyldi-4,1-phenylene)bis[N,N′,N′-triphenyl-1,4-phenylenediamine] (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N′,N′-triphenyl-1,4-phenylenediamine (abbreviation: 2DPAPPA), N,N,N′,N′,N″,N″,N′″,N′″-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(1,1′-biphenyl-2-yl)-2-anthryl]-N,9-diphenyl-9H-carbazol-3-amine (abbreviation: 2PCABPhA), N-(9,10-diphenyl-2-anthryl)-N,N′,N′-triphenyl-1,4-phenylenediamine (abbreviation: 2DPAPA), N-[9,10-bis(1,1′-biphenyl-2-yl)-2-anthryl]-N,N′,N′-triphenyl-1,4-phenylenediamine (abbreviation: 2DPABPhA), 9,10-bis(1,1′-biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N′-diphenylquinacridone (abbreviation: DPQd), rubrene, 5,12-bis(1,1′-biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), and 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), and N,N′-bis[4-(9-phenyl-9H-fluoren-9-yl)phenyl]-N,N′-diphenylpyrene-1,6-diamine (abbreviation: 1,6FLPAPrn). Examples of blue-emissive phosphorescent materials include an organometallic iridium complex having a 4H-triazole skeleton, such as tris{2-[5-(2-methylphenyl)-4-(2,6-dimethylphenyl)-4H-1,2,4-triazol-3-yl-κN2]phenyl-κC}iridium(III) (abbreviation: Ir(mpptz-dmp)₃), tris(5-methyl-3,4-diphenyl-4H-1,2,4-triazolato)iridium(III) (abbreviation: Ir(Mptz)₃), or tris[4-(3-biphenyl)-5-isopropyl-3-phenyl-4H-1,2,4-triazolato]iridium(III) (abbreviation: Ir(iPrptz-3b)₃); an organometallic iridium complex having a 1H-triazole skeleton, such as tris[3-methyl-1-(2-methylphenyl)-5-phenyl-1H-1,2,4-triazolato]iridium(III) (abbreviation: Ir(Mptz1-mp)₃) or tris(1-methyl-5-phenyl-3-propyl-1H-1,2,4-triazolato)iridium(II) (abbreviation: Ir(Prptz1-Me)₃); an organometallic iridium complex having an imidazole skeleton, such as fac-tris[1-(2,6-diisopropylphenyl)-2-phenyl-1H-imidazole]iridium(III) (abbreviation: Ir(iPrpmi)₃), or tris[3-(2,6-dimethylphenyl)-7-methylimidazo[1,2-f]phenanthridinato]iridium(III) (abbreviation: Ir(dmpimpt-Me)₃); and an organometallic iridium complex in which a phenylpyridine derivative having an electron-withdrawing group is a ligand, such as bis[2-(4′,6′-difluorophenyl)pyridinato-N,C²′]iridium(III) tetrakis(1-pyrazolyl)borate (abbreviation: FIr6), bis[2-(4′,6′-difluorophenyl)pyridinato-N,C²′]iridium(III) picolinate (abbreviation: FIrpic), bis{2-[3′,5′-bis(trifluoromethyl)phenyl]pyridinato-N,C²′}iridium(III) picolinate (abbreviation: Ir(CF₃ppy)₂(pic)), or bis[2-(4′,6′-difluorophenyl)pyridinato-N,C²′]iridium(III) acetylacetonate (abbreviation: FIr(acac)). Note that an organometallic iridium complex having a 4H-triazole skeleton has excellent reliability and emission efficiency and thus is especially preferable. Examples of green-emissive phosphorescent materials include an organometallic iridium complex having a pyrimidine skeleton, such as tris(4-methyl-6-phenylpyrimidinato)iridium(III) (abbreviation: Ir(mppm)₃), tris(4-t-butyl-6-phenylpyrimidinato)iridium(III) (abbreviation: Ir(tBuppm)₃), (acetylacetonato)bis(6-methyl-4-phenylpyrimidinato)iridium(III) (abbreviation: Ir(mppm)₂(acac)), (acetylacetonato)bis(6-tert-butyl-4-phenylpyrimidinato)iridium(III) (abbreviation: Ir(tBuppm)₂(acac)), (acetylacetonato)bis[6-(2-norbornyl)-4-phenylpyrimidinato]iridium(III) (abbreviation: Ir(nbppm)₂(acac)), (acetylacetonato)bis[5-methyl-6-(2-methylphenyl)-4-phenylpyrimidinato]iridium(III) (abbreviation: Ir(mpmppm)₂(acac)), or (acetylacetonato)bis(4,6-diphenylpyrimidinato)iridium(III) (abbreviation: Ir(dppm)₂(acac)); an organometallic iridium complex having a pyrazine skeleton, such as (acetylacetonato)bis(3,5-dimethyl-2-phenylpyrazinato)iridium(III) (abbreviation: Ir(mppr-Me)₂(acac)) or (acetylacetonato)bis(5-isopropyl-3-methyl-2-phenylpyrazinato)iridium(III) (abbreviation: Ir(mppr-iPr)₂(acac)); an organometallic iridium complex having a pyridine skeleton, such as tris(2-phenylpyridinato-N,C²′)iridium(III) (abbreviation: Ir(ppy)₃) or bis(2-phenylpyridinato-N,C²′)iridium(III) acetylacetonate (abbreviation: Ir(ppy)₂(acac)); an organometallic iridium complex having a quinoline skeleton, such as bis(benzo[h]quinolinato)iridium(III) acetylacetonate (abbreviation: Ir(bzq)₂(acac)), tris(benzo[h]quinolinato)iridium(III) (abbreviation: Ir(bzq)₃), tris(2-phenylquinolinato-N,C²′)iridium(III) (abbreviation: Ir(pq)₃), or bis(2-phenylquinolinato-N,C²′)iridium(III) acetylacetonate (abbreviation: Ir(pq)₂(acac)); and a rare earth metal complex such as tris(acetylacetonato)(monophenanthroline)terbium(III) (abbreviation: Tb(acac)₃(Phen)). Note that an organometallic iridium complex having a pyrimidine skeleton has distinctively high reliability and emission efficiency and thus is especially preferable.

Examples of red-emissive phosphorescent materials include an organometallic iridium complex having a pyrimidine skeleton, such as bis[4,6-bis(3-methylphenyl)pyrimidinato](diisobutyrylmethano)iridium(III) (abbreviation: Ir(5mdppm)₂(dibm)), bis[4,6-bis(3-methylphenyl)pyrimidinato](dipivaloylmethanato)iridium(III) (abbreviation: Ir(5mdppm)₂(dpm)), or bis[4,6-di(naphthalen-1-yl)pyrimidinato](dipivaloylmethanato)iridium(III) (abbreviation: Ir(d1npm)₂(dpm)); an organometallic iridium complex having a pyrazine skeleton, such as (acetylacetonato)bis(2,3,5-triphenylpyrazinato)iridium(III) (abbreviation: Ir(tppr)₂(acac)) or bis(2,3,5-triphenylpyrazinato)(dipivaloylmethanato)iridium(III) (abbreviation: Ir(tppr)₂(dpm)); an organometallic iridium complex having a quinoxaline skeleton, such as (acetylacetonato)bis[2,3-bis(4-fluorophenyl)quinoxalinato]iridium(III) (abbreviation: Ir(Fdpq)₂(acac)); an organometallic iridium complex having an isoquinoline skeleton, such as tris(1-phenylisoquinolinato-N,C²′)iridium(III) (abbreviation: Ir(piq)₃) or bis(1-phenylisoquinolinato-N, C²′) iridium(III)acetylacetonate (abbreviation: Ir(piq)₂(acac)); a platinum complex such as 2,3,7,8,12,13,17,18-octaethyl-21H,23H-porphyrin platinum(II) (abbreviation: PtOEP); and a rare earth metal complex such as tris(1,3-diphenyl-1,3-propanedionato)(monophenanthroline)europium(III) (abbreviation: Eu(DBM)₃(Phen)) or tris[1-(2-thenoyl)-3,3,3-trifluoroacetonato](monophenanthroline)europium(III) (abbreviation: Eu(TTA)₃(Phen)). Note that an organometallic iridium complex having a pyrimidine skeleton has distinctively high reliability and emission efficiency and thus is especially preferable. Further, because an organometallic iridium complex having a pyrazine skeleton can provide red light emission with favorable chromaticity, the use of the organometallic iridium complex in a white light-emitting element improves a color rendering property of the white light-emitting element. Note that the heterocyclic compound according to one embodiment of the present invention exhibits light in a blue region to an ultraviolet region, and can be used as the emission substance.

The material that can be used as the emission substance may be selected from known substances as well as from the substances given above.

As a host material in which the emission substance is dispersed, the heterocyclic compound according to one embodiment of the present invention is suitably used.

Since the heterocyclic compound according to one embodiment of the present invention has a wide band gap and high triplet level, the heterocyclic compound can be suitably used as a host material in which an emission substance emitting high-energy light is dispersed, such as an emission substance emitting blue fluorescence or an emission substance emitting green to blue phosphorescence. Needless to say, the heterocyclic compound can also be used as a host material in which an emission substance emitting fluorescence having a wavelength longer than the blue light wavelength or an emission substance emitting phosphorescence having a wavelength longer than the green light wavelength is dispersed. In addition, it is effective to use the heterocyclic compound as a material of a carrier-transport layer (preferably an electron-transport layer) adjacent to a light-emitting layer. Since the heterocyclic compound has a wide band gap or high triplet level, even when the emission substance is a material emitting high-energy light, such as an emission substance emitting blue fluorescence or an emission substance emitting green to blue phosphorescence, the energy of carriers that has recombined in a host material can be effectively transferred to the emission substance. Thus, a light-emitting element having high emission efficiency can be manufactured. Note that in the case where the heterocyclic compound is used as a host material or a material of a carrier-transport layer, the emission substance is preferably, but not limited to, a substance having a narrower band gap than the heterocyclic compound or a substance having lower triplet level than the heterocyclic compound.

In the heterocyclic compound according to one embodiment of the present invention, the heterocyclic skeleton is preferably an imidazole skeleton, a pyrazine skeleton, a pyrimidine skeleton, a triazole skeleton, or any of these skeletons to which benzene is fused.

The heterocyclic compound according to one embodiment of the present invention preferably has the structure in which the indolo[3,2,1-jk]carbazole skeleton and the heterocyclic skeleton are bonded to each other through an arylene group to achieve a wide band gap or high triplet level. The heterocyclic compound with such a structure has advantages in that the quality of a film formed by evaporation is good and synthesis can be easily performed.

The heterocyclic compound described in Embodiment 1 (the heterocyclic compound represented by General Formula (G1)) is a preferable mode of the heterocyclic compound according to one embodiment of the present invention.

In the case where the heterocyclic compound according to one embodiment of the present invention is not used as a host material, a known material can be used as the host material.

Examples of materials which can be used as the above host material are given below. The following are examples of materials having an electron-transport property: a metal complex such as bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), or bis[2-(2-benzothiazolyl)phenolato]zinc(II) (abbreviation: ZnBTZ); a heterocyclic compound having a polyazole skeleton such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11); a heterocyclic compound having a benzimidazole skeleton such as 2,2′,2″-(1,3,5-benzenetriyl)tris(1-phenyl-1H-benzimidazole) (abbreviation: TPBI) or 2-[3-(dibenzothiophen-4-yl)phenyl]-1-phenyl-1H-benzimidazole (abbreviation: mDBTBIm-II); a heterocyclic compound having a quinoxaline skeleton such as 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), or 2-[3′-(9H-carbazol-9-yl)biphenyl-3-yl]dibenzo[f,h]quinoxaline (abbreviation: 2mCzBPDBq); a heterocyclic compound having a diazine skeleton such as 4,6-bis[3-(phenanthren-9-yl)phenyl]pyrimidine (abbreviation: 4,6mPnP2Pm), or 4,6-bis[3-(4-dibenzothienyl)phenyl]pyrimidine (abbreviation: 4,6mDBTP2Pm-II); and a heterocyclic compound having a pyridine skeleton such as 3,5-bis[3-(9H-carbazol-9-yl)phenyl]pyridine (abbreviation: 35DCzPPy) or 1,3,5-tri[3-(3-pyridyl)phenyl]benzene (abbreviation: TmPyPB). Among the above materials, a heterocyclic compound having a diazine skeleton and a heterocyclic compound having a pyridine skeleton have high reliability and are thus preferable. Specifically, a heterocyclic compound having a diazine (pyrimidine or pyrazine) skeleton has a high electron-transport property to contribute to a reduction in drive voltage. Note that the heterocyclic compound according to one embodiment of the present invention has a relatively high electron-transport property, and is classified as a material having an electron-transport property.

The following are examples of materials which have a hole-transport property and can be used as the host material: a compound having an aromatic amine skeleton such as 4,4′-bis[N-(1-naphthyl)-N-phenylamino]biphenyl (abbreviation: NPB), N,N′-bis(3-methylphenyl)-N,N′-diphenyl-[1,1′-biphenyl]-4,4′-diamine (abbreviation: TPD), 4,4′-bis[N-(spiro-9,9′-bifluoren-2-yl)-N-phenylamino]biphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), or N-phenyl-N-[4-(9-phenyl-9H-carbazol-3-yl)phenyl]spiro-9,9′-bifluoren-2-amine (abbreviation: PCBASF); a compound having a carbazole skeleton such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), or 3,3′-bis(9-phenyl-9H-carbazole) (abbreviation: PCCP); a compound having a thiophene skeleton such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), or 4-[4-(9-phenyl-9H-fluoren-9-yl)phenyl]-6-phenyldibenzothiophene (abbreviation: DBTFLP-IV); and a compound having a furan skeleton such as 4,4′,4″-(benzene-1,3,5-triyl)tri(dibenzofuran) (abbreviation: DBF3P-II) or 4-{3-[3-(9-phenyl-9H-fluoren-9-yl)phenyl]phenyl}dibenzofuran (abbreviation: mmDBFFLBi-II). Among the above materials, a compound having an aromatic amine skeleton and a compound having a carbazole skeleton are preferable because these compounds are highly reliable and have high hole-transport properties to contribute to a reduction in drive voltage.

Note that when the emission substance is a phosphorescent material, a substance having larger triplet level than the phosphorescent material is preferably selected as the host material, and when the emission substance is a fluorescent material, a substance having a wider band gap than the fluorescent material is preferably selected as the host material. The light-emitting layer may contain a third substance in addition to the host material and the phosphorescent substance.

Here, for obtaining a light-emitting element having high emission efficiency, it is necessary to increase the efficiency of the energy transfer from the host material to the phosphorescent material because carrier recombination occurs in both the host material and the phosphorescent substance. It is well-known that the efficiency of the energy transfer from the host material to the phosphorescent material increases with increasing overlap of the emission spectrum of the host material with the absorption spectrum of the guest material.

Here, the inventors found that the absorption band on the longest wavelength side (lowest energy side) in the absorption spectrum of the guest molecule is of great importance in considering the overlap between the emission spectrum of the host molecule and the absorption spectrum of the guest molecule.

In this embodiment, a phosphorescent compound is used as the guest material. In an absorption spectrum of the phosphorescent compound, an absorption band that is considered to contribute to light emission most greatly is at an absorption wavelength corresponding to direct transition from a ground state to a triplet excitation state and a vicinity of the absorption wavelength, which is on the longest wavelength side. From these considerations, the inventors conceived that it is preferable to control the emission spectrum (a fluorescent spectrum and a phosphorescent spectrum) of the host material so as to overlap with the absorption band on the longest wavelength side in the absorption spectrum of the phosphorescent compound.

For example, most organometallic complexes, especially light-emitting iridium complexes, have a broad absorption band at around 500 nm to 600 nm as the absorption band on the longest wavelength side. This absorption band is mainly based on a triplet MLCT (metal to ligand charge transfer) transition. Note that it is considered that the absorption band also includes absorptions based on a triplet π-π* transition and a singlet MLCT transition, and that these absorptions overlap each other to form a broad absorption band on the longest wavelength side in the absorption spectrum. Therefore, the inventors propose that, when an organometallic complex (especially iridium complex) is used as the guest material, it is preferable to make the broad absorption band on the longest wavelength side largely overlap with the emission spectrum of the host material as described above.

Here, first, energy transfer from a host material in a triplet excited state will be considered. From the above-described discussion, it is preferable that, in energy transfer from a triplet excited state, the phosphorescent spectrum of the host material and the absorption band on the longest wavelength side of the guest material largely overlap each other.

However, a question here is energy transfer from the host molecule in the singlet excited state. In order to efficiently perform not only energy transfer from the triplet excited state but also energy transfer from the singlet excited state, it is clear from the above-described discussion that the host material needs to be designed such that not only its phosphorescent spectrum but also its fluorescent spectrum overlaps with the absorption band on the longest wavelength side of the guest material. In other words, unless the host material is designed so as to have its fluorescent spectrum in a position similar to that of its phosphorescent spectrum, it is not possible to achieve efficient energy transfer from the host material in both the singlet excited state and the triplet excited state.

However, in general, the S₁ level differs greatly from the T₁ level (S₁ level>T₁ level); therefore, the fluorescence emission wavelength also differs greatly from the phosphorescence emission wavelength (fluorescence emission wavelength<phosphorescence emission wavelength). For example, CBP, which is commonly used in a light-emitting element containing a phosphorescent compound, has a phosphorescent spectrum at around 500 nm and has a fluorescent spectrum at around 400 nm, which are largely different by about 100 nm. This example also shows that it is extremely difficult to design a host material so as to have its fluorescent spectrum in a position similar to that of its phosphorescent spectrum.

Fluorescence is emitted from an energy level higher than that of phosphorescence, and the T₁ level of a host material whose fluorescence spectrum corresponds to a wavelength close to an absorption spectrum of a guest material on the longest wavelength side is lower than the T₁ level of the guest material.

Thus, in the case where a phosphorescent material is used as the emission substance, it is preferable that the light-emitting element in this embodiment include a third substance in the light-emitting layer in addition to the host material and the emission substance and a combination of the host material and the third substance form an exciplex.

In that case, at the time of recombination of carriers (electrons and holes) in the light-emitting layer, the host material and the third substance form an exciplex. A fluorescence spectrum of the exciplex is on a longer wavelength side than a fluorescence spectrum of the host material alone or the third substance alone. Therefore, energy transfer from a singlet excited state can be maximized while the T₁ levels of the host material and the third substance are kept higher than the T₁ level of the guest material. In addition, the exciplex is in a state where the T₁ level and the S₁ level are close to each other; therefore, the fluorescence spectrum and the phosphorescence spectrum exist at substantially the same position. Accordingly, both the fluorescence spectrum and the phosphorescence spectrum of the exciplex can overlap largely with an absorption corresponding to transition of the guest molecule from the singlet ground state to the triplet excited state (a broad absorption band of the guest molecule existing on the longest wavelength side), and thus a light-emitting element having high energy transfer efficiency can be obtained.

There is no particular limitation on the host materials and the third substance as long as they can form an exciplex; a combination of a compound which readily accepts electrons (a compound having an electron-transport property) and a compound which readily accepts holes (a compound having a hole-transport property) is preferably employed.

In the case where a compound having an electron-transport property and a compound having a hole-transport property are used for the host material and the third substance, carrier balance can be controlled by the mixture ratio of the compounds. Specifically, the ratio of the host material to the third substance is preferably from 1:9 to 9:1. Note that in that case, the following structure may be employed: a light-emitting layer in which one kind of an emission substance is dispersed is divided into two layers, and the two layers have different mixture ratios of the host material to the third substance. With this structure, the carrier balance of the light-emitting element can be optimized, so that the lifetime of the light-emitting element can be improved. Furthermore, one of the light-emitting layers may be a hole-transport layer and the other of the light-emitting layers may be an electron-transport layer.

In the case where the light-emitting layer having the above-described structure is formed using a plurality of materials, the light-emitting layer can be formed using co-evaporation by a vacuum evaporation method; or an inkjet method, a spin coating method, a dip coating method, or the like. Note that co-evaporation is an evaporation method by which a plurality of different substances is concurrently vaporized from respective different evaporation sources.

The electron-transport layer 114 is a layer containing a substance having an electron-transport property. For example, a layer containing a metal complex having a quinoline skeleton or a benzoquinoline skeleton, such as tris(8-quinolinolato)aluminum (abbreviation: Alq), tris(4-methyl-8-quinolinolato)aluminum (abbreviation: Almq₃), BeBq₂, or BAlq, or the like can be used. Alternatively, a metal complex having an oxazole-based or thiazole-based ligand, such as ZnBOX or ZnBTZ, or the like can be used. Besides the metal complexes, PBD, OXD-7, TAZ, bathophenanthroline (abbreviation: BPhen), bathocuproine (abbreviation: BCP), or the like can also be used. The substances mentioned here are mainly ones that have an electron mobility of 10⁻⁶ cm²/Vs or higher. The electron-transport layer may be formed of other substances than those described above as long as the substances have electron-transport properties higher than hole-transport properties.

Alternatively, the heterocyclic compound according to one embodiment of the present invention may be used as a material of the electron-transport layer 114. The heterocyclic compound has a wide band gap and high T₁ level and thus can effectively prevent excitation energy in the light-emitting layer from transferring to the electron-transport layer 114; accordingly, a reduction in emission efficiency due to the excitation energy transfer can be prevented and a light-emitting element having high emission efficiency can be manufactured. Moreover, the heterocyclic compound has a high carrier-transport property, so that a light-emitting element with low driving voltage can be provided.

The electron-transport layer is not limited to a single layer, and may be a stack of two or more layers containing any of the above substances.

Between the electron-transport layer and the light-emitting layer, a layer that controls transport of electron carriers may be provided. This is a layer formed by addition of a small amount of a substance having a high electron-trapping property to the aforementioned materials having a high electron-transport property, and the layer is capable of adjusting carrier balance by retarding transport of electron carriers. Such a structure is very effective in preventing a problem (such as a reduction in element lifetime) caused when electrons pass through the light-emitting layer.

It is preferable that the host material in the light-emitting layer and a material of the electron-transport layer have the same skeleton, in which case transfer of carriers can be smooth and thus the driving voltage can be reduced. Moreover, it is effective that the host material and the material of the electron-transport layer be the same material.

The electron-injection layer 115 may be provided in contact with the second electrode 102 between the electron-transport layer 114 and the second electrode 102. For the electron-injection layer 115, lithium, calcium, lithium fluoride (LiF), cesium fluoride (CsF), or calcium fluoride (CaF₂) can be used. A composite material of a substance having an electron-transport property and a substance exhibiting an electron-donating property (hereinafter, simply referred to as electron-donating substance) with respect to the substance having an electron-transport property can also be used. Examples of the electron-donating substance include an alkali metal, an alkaline earth metal, and compounds thereof. Note that such a composite material is preferably used for the electron-injection layer 115, in which case electrons are injected efficiently from the second electrode 102. With this structure, a conductive material as well as a material having a low work function can be used for the cathode.

For the electrode functioning as a cathode, any of metals, alloys, electrically conductive compounds, and mixtures thereof which have a low work function (specifically, a work function of 3.8 eV or less) or the like can be used. Specific examples of such a cathode material are elements belonging to Groups 1 and 2 of the periodic table, such as lithium (Li), cesium (Cs)), magnesium (Mg), calcium (Ca), and strontium (Sr), alloys thereof (e.g., MgAg and AlLi), rare earth metals such as europium (Eu) and ytterbium (Yb), alloys thereof, and the like. However, when the electron-injection layer is provided between the second electrode 102 and the electron-transport layer, for the second electrode 102, any of a variety of conductive materials such as Al, Ag, ITO, or indium oxide-tin oxide containing silicon or silicon oxide can be used regardless of the work function. Films of these electrically conductive materials can be formed by a sputtering method, an inkjet method, a spin coating method, or the like.

Any of a variety of methods can be used to form the EL layer 103 regardless whether it is a dry process or a wet process. For example, a vacuum evaporation method, an inkjet method, a spin coating method, or the like may be used. Different formation methods may be used for the electrodes or the layers.

In addition, the electrode may be formed by a wet method using a sol-gel method, or by a wet method using paste of a metal material. Alternatively, the electrode may be formed by a dry method such as a sputtering method or a vacuum evaporation method.

Note that the structure of the EL layer provided between the first electrode 101 and the second electrode 102 is not limited to the above structure. However, it is preferable that a light-emitting region where holes and electrons recombine be positioned away from the first electrode 101 and the second electrode 102 so as to prevent quenching due to the proximity of the light-emitting region and a metal used for an electrode or a carrier-injection layer.

In order to suppress energy transfer from an exciton which is generated in the light-emitting layer 113, the hole-transport layer or the electron-transport layer in direct contact with the light-emitting layer, particularly a carrier-transport layer closer to a light-emitting region, is preferably formed with a material that has a wider energy gap than the substances contained in the light-emitting layer.

In the light-emitting element having the above-described structure, current flows due to a potential difference applied between the first electrode 101 and the second electrode 102, and holes and electrons recombine in the light-emitting layer 113 which contains a substance having a high light-emitting property, so that light is emitted. That is, a light-emitting region is formed in the light-emitting layer 113.

Light emission is extracted out through one or both of the first electrode 101 and the second electrode 102. Therefore, one or both of the first electrode 101 and the second electrode 102 are light-transmitting electrodes. In the case where only the first electrode 101 is a light-transmitting electrode, light emission is extracted from the substrate side through the first electrode 101. In the case where only the second electrode 102 is a light-transmitting electrode, light emission is extracted from the side opposite to the substrate side through the second electrode 102. In the case where both the first electrode 101 and the second electrode 102 are light-transmitting electrodes, light emission is extracted from both of the substrate side and the side opposite to the substrate through the first electrode 101 and the second electrode 102.

Since the light-emitting element of this embodiment is formed using any of the heterocyclic compound, which has a wide energy gap, light emission can be efficiently obtained even if an emission substance has a wide energy gap and emits blue fluorescence or green to blue phosphorescence, and the light-emitting element can have high emission efficiency. Accordingly, a light-emitting element having lower power consumption can be provided. Moreover, since the heterocyclic compound has a high carrier-transport property, a light-emitting element with low driving voltage can be provided.

### Embodiment 5

In this embodiment is described one mode of a light-emitting element having a structure in which a plurality of light-emitting units are stacked (hereinafter, also referred to as stacked-type element), with reference to FIG. 1B. This light-emitting element includes a plurality of light-emitting units between a first electrode and a second electrode. Each light-emitting unit can have the same structure as the EL layer 103 which is described in Embodiment 4. In other words, the light-emitting element described in Embodiment 4 is a light-emitting element having one light-emitting unit while the light-emitting element described in this embodiment is a light-emitting element having a plurality of light-emitting units.

In FIG. 1B, a first light-emitting unit 511 and a second light-emitting unit 512 are stacked between a first electrode 501 and a second electrode 502, and a charge generation layer 513 is provided between the first light-emitting unit 511 and the second light-emitting unit 512. The first electrode 501 and the second electrode 502 respectively correspond to the first electrode 101 and the second electrode 102 in Embodiment 4, and materials described in Embodiment 4 can be used. Further, the structures of the first light-emitting unit 511 and the second light-emitting unit 512 may be the same or different.

The charge-generation layer 513 includes a composite material of an organic compound and a metal oxide. As this composite material of an organic compound and a metal oxide, the composite material that can be used for the hole-injection layer and described in Embodiment 4 can be used. As the organic compound, any of a variety of compounds such as aromatic amine compounds, carbazole compounds, aromatic hydrocarbons, and high molecular compounds (oligomers, dendrimers, polymers, or the like) can be used. Note that the organic compound preferably has a hole mobility of 1×10⁻⁶ cm²/Vs or more. However, any other substance may be used as long as the substance has a hole-transport property higher than an electron-transport property. Note that in the light-emitting unit whose anode side surface is in contact with the charge-generation layer, a hole-transport layer is not necessarily provided because the charge-generation layer can also function as the hole-transport layer.

The charge generation layer 513 may have a stacked structure in such a way that the layer containing the composite material is combined with a layer containing another material, for example, with a layer that contains a compound selected from substances having an electron-donating property and a compound having a high electron-transport property. The charge generation layer 513 may be formed in such a way that the layer containing the composite material is combined with a transparent conductive film.

The charge generation layer 513 provided between the first light-emitting unit 511 and the second light-emitting unit 512 may have any structure as long as electrons can be injected to a light-emitting unit on one side and holes can be injected to a light-emitting unit on the other side when a voltage is applied between the first electrode 501 and the second electrode 502. For example, in FIG. 1B, any layer can be used as the charge generation layer 513 as long as the layer injects electrons into the first light-emitting unit 511 and holes into the second light-emitting unit 512 when a voltage is applied such that the potential of the first electrode is higher than that of the second electrode.

Although the light-emitting element having two light-emitting units is described in this embodiment, the present invention can be similarly applied to a light-emitting element in which three or more light-emitting units are stacked. With a plurality of light-emitting units partitioned by the charge generation layer between a pair of electrodes, as in the light-emitting element according to this embodiment, light with high luminance can be obtained while current density is kept low; thus, a light-emitting element having a long lifetime can be obtained.

By making the light-emitting units emit light of different colors from each other, the light-emitting element can provide light emission of a desired color as a whole. For example, by forming a light-emitting element having two light-emitting units such that the emission color of the first light-emitting unit and the emission color of the second light-emitting unit are complementary colors, the light-emitting element can provide white light emission as a whole. Note that the word “complementary” means color relationship in which an achromatic color is obtained when colors are mixed. In other words, when lights obtained from substances which emit light of complementary colors are mixed, white emission can be obtained. Further, the same can be applied to a light-emitting element having three light-emitting units. For example, the light-emitting element as a whole can provide white light emission when the emission color of the first light-emitting unit is red, the emission color of the second light-emitting unit is green, and the emission color of the third light-emitting unit is blue.

Alternatively, in the case of employing a light-emitting element in which an emission substance emitting phosphorescence is used for a light-emitting layer of one light-emitting unit and an emission substance emitting fluorescence is used for a light-emitting layer of the other light-emitting unit, both fluorescence and phosphorescence can be efficiently emitted from the light-emitting element. For example, when red phosphorescence and green phosphorescence are obtained from one light-emitting unit and blue fluorescence is obtained from the other light-emitting unit, white light with high emission efficiency can be obtained.

Since the light-emitting element of this embodiment contains the heterocyclic compound according to one embodiment of the present invention, the light-emitting element can have high emission efficiency or operate at low driving voltage. In addition, since light emission with high color purity which is derived from the emission substance can be obtained from the light-emitting unit including the heterocyclic compound, color adjustment of the light-emitting element as a whole is easy.

Note that this embodiment can be combined with any of the other embodiments and examples as appropriate.

### Embodiment 6

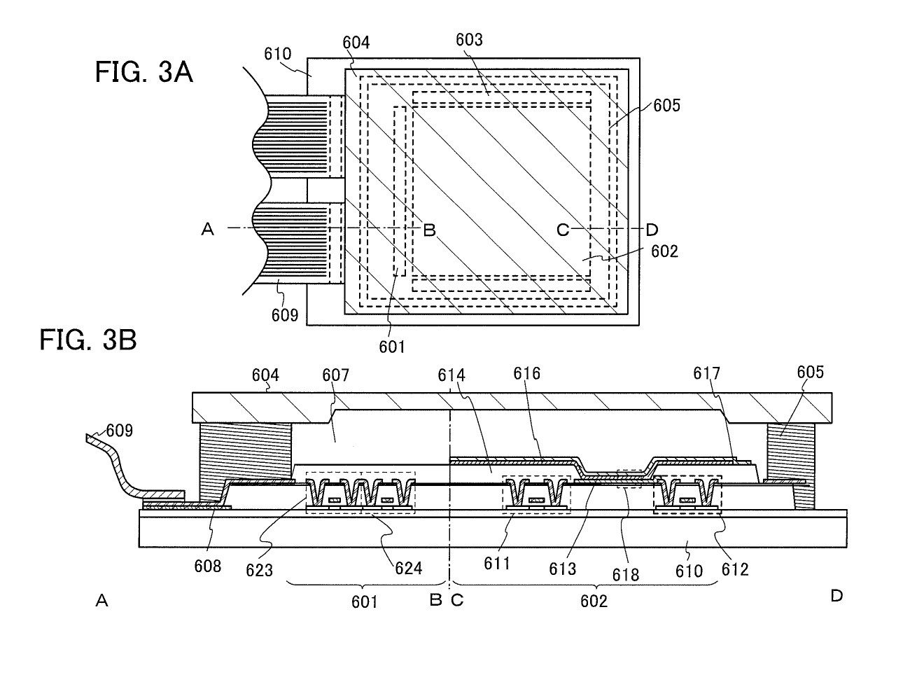

In this embodiment, explanation will be given with reference to FIGS. 3A and 3B of an example of the light-emitting device manufactured by using a light-emitting element that contains the heterocyclic compound having an indolo[3,2,1-jk]carbazole skeleton and a heterocyclic skeleton in which one ring has two or more nitrogen atoms. Note that FIG. 3A is a top view of the light-emitting device and FIG. 3B is a cross-sectional view taken along the lines A-B and C-D in FIG. 3A. This light-emitting device includes a driver circuit portion (source side driver circuit) 601, a pixel portion 602, and a driver circuit portion (gate side driver circuit) 603, which are to control light emission of a light-emitting element 618 and illustrated with dotted lines. A reference numeral 604 denotes a sealing substrate; 605, a sealing material; and 607, a space surrounded by the sealing material 605.

Reference numeral 608 denotes a wiring for transmitting signals to be input to the source side driver circuit 601 and the gate side driver circuit 603 and receiving signals such as a video signal, a clock signal, a start signal, and a reset signal from an FPC (flexible printed circuit) 609 serving as an external input terminal. Although only the FPC is illustrated here, a printed wiring board (PWB) may be attached to the FPC. The light-emitting device in the present specification includes, in its category, not only the light-emitting device itself but also the light-emitting device provided with the FPC or the PWB.

The driver circuit portion and the pixel portion are formed over an element substrate 610; FIG. 3B shows the source line driver circuit 601, which is a driver circuit portion, and one of the pixels in the pixel portion 602.

As the source line driver circuit 601, a CMOS circuit in which an n-channel TFT 623 and a p-channel TFT 624 are combined is formed. In addition, the driver circuit may be formed with any of a variety of circuits such as a CMOS circuit, a PMOS circuit, or an NMOS circuit. Although a driver integrated type in which the driver circuit is formed over the substrate is illustrated in this embodiment, the driver circuit is not necessarily formed over the substrate, and the driver circuit can be formed outside, not over the substrate. The structure of the transistor is not particularly limited. Either a staggered TFT or an inverted staggered TFT may be employed. A semiconductor layer included in the TFT may be formed using any material as long as the material exhibits semiconductor characteristics; for example, an element belonging to Group 14 of the periodic table such as silicon (Si) or germanium (Ge), a compound such as gallium arsenide or indium phosphide, and an oxide such as zinc oxide or tin oxide can be used. For the oxide exhibiting semiconductor characteristics (an oxide semiconductor), a composite oxide of an element selected from indium, gallium, aluminum, zinc, and tin can be used. Examples thereof are zinc oxide (ZnO), indium oxide containing zinc oxide (indium zinc oxide), and oxide containing indium oxide, gallium oxide, and zinc oxide (IGZO: indium gallium zinc oxide). An organic semiconductor may also be used. In addition, the crystallinity of a semiconductor used for the TFT is not particularly limited. The semiconductor layer may have either a crystalline structure or an amorphous structure. Specific examples of the crystalline semiconductor layer include a single crystal semiconductor, a polycrystalline semiconductor, and a microcrystalline semiconductor.

The pixel portion 602 includes a plurality of pixels including a switching TFT 611, a current controlling TFT 612, and a first electrode 613 electrically connected to a drain of the current controlling TFT 612. Note that to cover an end portion of the first electrode 613, an insulator 614 is formed, for which a positive photosensitive resin film is used here.

In order to improve coverage of a film formed over the insulator 614, the insulator 614 is formed to have a curved surface with curvature at its upper or lower end portion. For example, in the case where a positive photosensitive acrylic resin is used for a material of the insulator 614, only the upper end portion of the insulator 614 preferably has a surface with a curvature radius (0.2 μm to 3 μm). As the insulator 614, either a negative photosensitive material or a positive photosensitive material can be used.

An EL layer 616 and a second electrode 617 are formed over the first electrode 613. Here, as a material used for the first electrode 613 functioning as an anode, a stack of a titanium nitride film and a film containing aluminum as its main component, a stack of three layers of a titanium nitride film, a film containing aluminum as its main component, and a titanium nitride film, or the like can be used in addition to the materials described in Embodiment 4. The stacked-layer structure enables low wiring resistance, favorable ohmic contact, and a function as an anode.

The EL layer 616 is formed by any of a variety of methods such as an evaporation method using an evaporation mask, an inkjet method, and a spin coating method. The EL layer 616 contains the heterocyclic compound according to one embodiment of the present invention. Further, for another material included in the EL layer 616, any of low molecular-weight compounds and polymeric compounds (including oligomers and dendrimers) may be used.

As a material used for the second electrode 617, which is formed over the EL layer 616 and functions as a cathode, the materials described in Embodiment 4 can be used. In the case where light generated in the EL layer 616 is extracted through the second electrode 617, a stack of a thin metal film and a transparent conductive film (e.g., ITO, indium oxide containing zinc oxide at 2 wt % to 20 wt %, indium tin oxide containing silicon, or zinc oxide (ZnO)) is preferably used for the second electrode 617.

Note that the light-emitting element 618 is formed with the first electrode 613, the EL layer 616, and the second electrode 617. The light-emitting element has the structure described in Embodiment 4 or 5. In the light-emitting device of this embodiment, the pixel portion 602, which includes a plurality of light-emitting elements, may include both the light-emitting element described in Embodiment 4 or 5 and a light-emitting element having a different structure.

The sealing substrate 604 is attached to the element substrate 610 with the sealing material 605, so that the light-emitting element 618 is provided in the space 607 surrounded by the element substrate 610, the sealing substrate 604, and the sealing material 605. The space 607 is filled with filler. The filler may be an inert gas (such as nitrogen or argon), a resin, or a resin and/or a desiccant.

An epoxy-based resin or glass frit is preferably used for the sealing material 605. It is preferable that such a material do not transmit moisture or oxygen as much as possible. As the sealing substrate 604, a glass substrate, a quartz substrate, or a plastic substrate formed of fiberglass reinforced plastic (FRP), poly(vinyl fluoride) (PVF), a polyester, an acrylic resin, or the like can be used.

As described above, the light-emitting device manufactured by using the light-emitting element that contains the heterocyclic compound according to one embodiment of the present invention can be obtained.

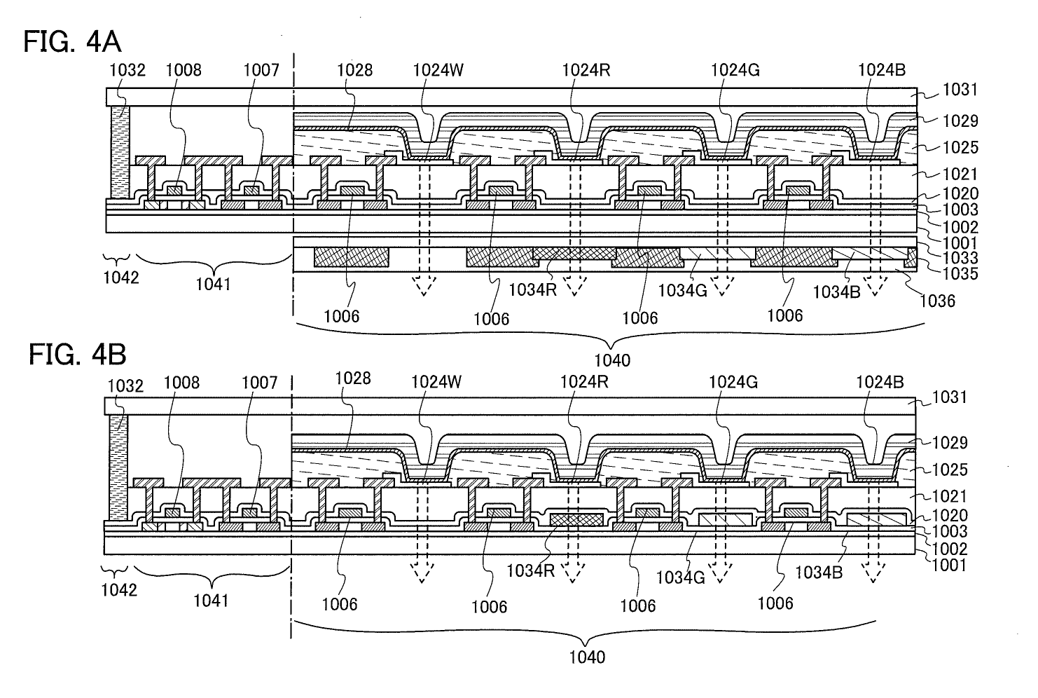

FIGS. 4A and 4B illustrates examples of light-emitting devices in which full color display is achieved by forming a light-emitting element exhibiting white light emission and providing a coloring layer (a color filter) and the like. In FIG. 4A, a substrate 1001, a base insulating film 1002, a gate insulating film 1003, gate electrodes 1006, 1007, and 1008, a first interlayer insulating film 1020, a second interlayer insulating film 1021, a peripheral portion 1042, a pixel portion 1040, a driver circuit portion 1041, first electrodes 1024W, 1024R, 1024G and 1024B of light-emitting elements, a partition wall 1025, an EL layer 1028, a second electrode 1029 of the light-emitting elements, a sealing substrate 1031, a sealant 1032, and the like are illustrated.

In FIG. 4A, coloring layers (a red coloring layer 1034R, a green coloring layer 1034G and a blue coloring layer 1034B) are provided on a transparent base material 1033. Further, a black layer (a black matrix) 1035 may be additionally provided. The transparent base material 1033 provided with the coloring layers and the black layer is positioned and fixed to the substrate 1001. Note that the coloring layers and the black layer are covered with an overcoat layer 1036. In FIG. 4A, light emitted from some of the light-emitting layers does not pass through the coloring layers, while light emitted from the others of the light-emitting layers passes through the coloring layers. Since light which does not pass through the coloring layers is white and light which passes through any one of the coloring layers is red, blue, or green, a full color image can be displayed using pixels of the four colors.

FIG. 4B illustrates an example in which coloring layers (a red coloring layer 1034R, a green coloring layer 1034G, and a blue coloring layer 1034B) are formed between the gate insulating film 1003 and the first interlayer insulating film 1020. As shown in FIG. 4B, the coloring layers may be provided between the substrate 1001 and the sealing substrate 1031.

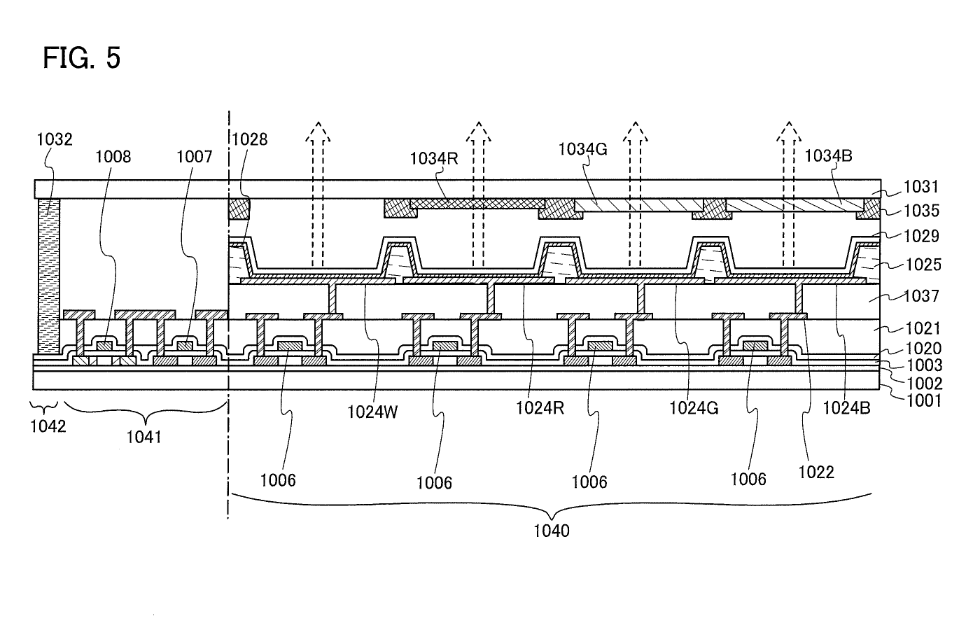

The above-described light-emitting device has a structure in which light is extracted from the substrate 1001 side where the TFTs are formed (a bottom emission structure), but may have a structure in which light is extracted from the sealing substrate 1031 side (a top emission structure). FIG. 5 is a cross-sectional view of a light-emitting device having a top emission structure. In this case, a substrate which does not transmit light can be used as the substrate 1001. The process up to the step of forming of a connection electrode 1022 which connects the TFTs and the first electrodes 1024W, 1024R, 1024G and 1024B of the light-emitting element is performed in a manner similar to that of the light-emitting device having a bottom emission structure. Then, a third interlayer insulating film 1037 is formed to cover the connection electrode 1022. This insulating film may have a planarization function. The third interlayer insulating film 1037 can be formed using a material similar to that of the second interlayer insulating film, and can alternatively be formed using any other known material.

The first electrodes 1024W, 1024R, 1024E and 1024B of the light-emitting elements each serve as an anode here, but may serve as a cathode. Further, in the case of a light-emitting device having a top emission structure as illustrated in FIG. 5, the first electrodes are preferably reflective electrodes. The EL layer 1028 is formed to have a structure similar to the structure described in Embodiments 3 and 4.

In FIGS. 4A and 4B and FIG. 5, the structure of the EL layer to obtain white light emission can be achieved by, for example, using a plurality of light-emitting layers or using a plurality of light-emitting units.

In the case of a top emission structure as illustrated in FIG. 5, sealing can be performed with the sealing substrate 1031 on which the coloring layers (the red coloring layer 1034R, the green coloring layer 1034G and the blue coloring layer 1034B) are provided. The sealing substrate 1031 may be provided with a black layer (the black matrix) 1035 which is positioned between pixels. The coloring layers and the black layer may be covered with an overcoat layer that is not illustrated. Note that a light-transmitting substrate is used as the sealing substrate 1031.

Although an example in which full color display is performed using four colors of red, green, blue, and white is shown here, there is no particular limitation and full color display using three colors of red, green, and blue may be performed.

Since the light-emitting device of this embodiment uses the light-emitting element described in Embodiment 4 or 5, the light-emitting device can have favorable characteristics. Specifically, the heterocyclic compound according to one embodiment of the present invention has a wide energy gap and high triplet level and can suppress energy transfer from a light-emitting substance; thus, a light-emitting element having high emission efficiency can be provided, leading to a light-emitting device having reduced power consumption. Furthermore, the heterocyclic compound has a high carrier-transport property, so that a light-emitting element with low driving voltage can be provided, leading to a light-emitting device with low driving voltage.

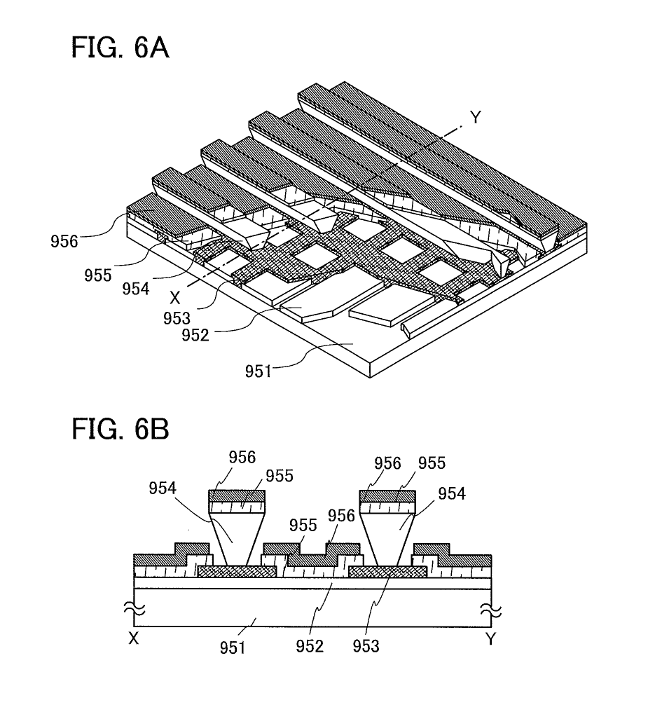

Although an active matrix light-emitting device is described above, a passive matrix light-emitting device will be described below. FIGS. 6A and 6B illustrate a passive matrix light-emitting device manufactured using the present invention. FIG. 6A is a perspective view of the light-emitting device, and FIG. 6B is a cross-sectional view taken along the line X-Y in FIG. 6A. In FIGS. 6A and 6B, over a substrate 951, an EL layer 955 is provided between an electrode 952 and an electrode 956. An end portion of the electrode 952 is covered with an insulating layer 953. A partition layer 954 is provided over the insulating layer 953. The sidewalls of the partition layer 954 are aslope such that the distance between both sidewalls is gradually narrowed toward the surface of the substrate. In other words, a cross section taken along the direction of the short side of the partition layer 954 is trapezoidal, and the lower side (a side which is in contact with the insulating layer 953) is shorter than the upper side (a side which is not in contact with the insulating layer 953). The partition layer 954 thus provided can prevent defects in the light-emitting element due to cross-talk or the like. The passive matrix light-emitting device can also be driven with low power consumption by including the heterocyclic compound according to one embodiment of the present invention.

In the light-emitting device described above, each of many minute light-emitting elements arranged in a matrix can be controlled; thus, the light-emitting device can be suitably used as a display device for displaying images.

### Embodiment 7

In this embodiment, electronic devices and light source devices each including the light-emitting element described in Embodiment 4 or 5 will be described.

Examples of the electronic device to which the above light-emitting element is applied include television devices (also referred to as TV or television receivers), monitors for computers and the like, cameras such as digital cameras and digital video cameras, digital photo frames, mobile phones (also referred to as cell phones or mobile phone devices), portable game machines, portable information terminals, audio playback devices, large game machines such as pachinko machines, and the like. Specific examples of these electronic devices are given below.

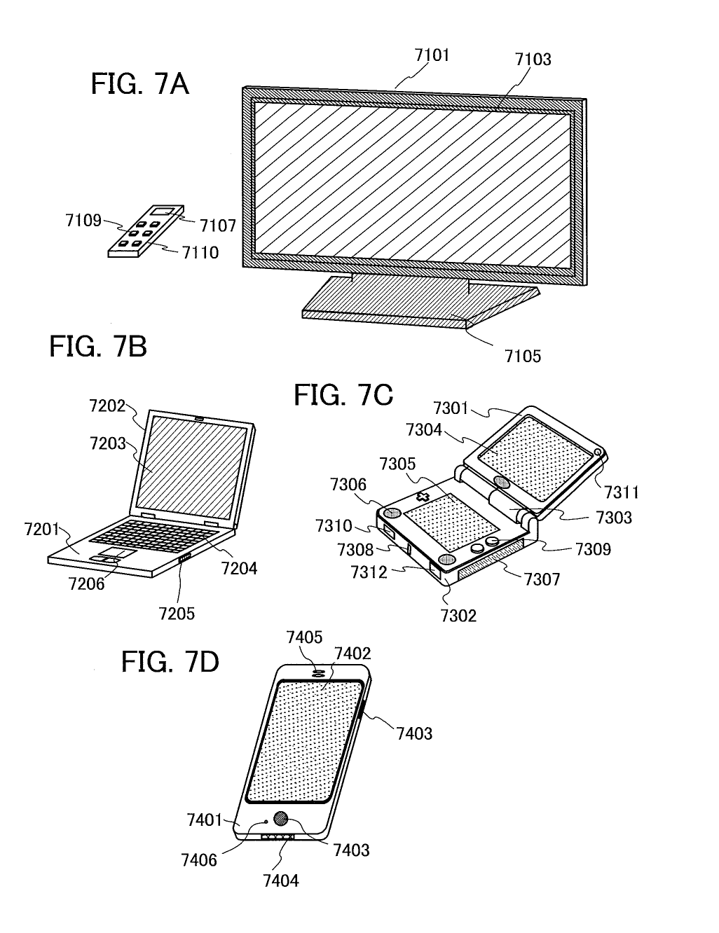

FIG. 7A illustrates an example of a television device. In the television device, a display portion 7103 is incorporated in a housing 7101. Here, the housing 7101 is supported by a stand 7105. Images can be displayed on the display portion 7103, and in the display portion 7103, the light-emitting elements described in Embodiment 4 or 5 are arranged in a matrix.

Operation of the television device can be performed with an operation switch of the housing 7101 or a separate remote controller 7110. With operation keys 7109 of the remote controller 7110, channels and volume can be controlled and images displayed on the display portion 7103 can be controlled. The remote controller 7110 may be provided with a display portion 7107 for displaying data output from the remote controller 7110.

Note that the television device is provided with a receiver, a modem, and the like. With the use of the receiver, general television broadcasting can be received. Moreover, when the television device is connected to a communication network with or without wires via the modem, one-way (from a sender to a receiver) or two-way (between a sender and a receiver or between receivers) information communication can be performed.

FIG. 7B illustrates a computer, which includes a main body 7201, a housing 7202, a display portion 7203, a keyboard 7204, an external connection port 7205, a pointing device 7206, and the like. Note that this computer is manufactured by arranging the light-emitting elements described in Embodiment 4 or 5 in a matrix in the display portion 7203.

FIG. 7C illustrates a portable game machine having two housings, a housing 7301 and a housing 7302, which are connected with a joint portion 7303 so that the portable game machine can be opened or folded. The housing 7301 incorporates a display portion 7304 including the light-emitting elements described in Embodiment 4 or 5 and arranged in a matrix, and the housing 7302 incorporates a display portion 7305. In addition, the portable game machine illustrated in FIG. 7C includes a speaker portion 7306, a recording medium insertion portion 7307, an LED lamp 7308, input means (an operation key 7309, a connection terminal 7310, a sensor 7311 (a sensor having a function of measuring or sensing force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), and a microphone 7312), and the like. Needless to say, the structure of the portable game machine is not limited to the above as long as the display portion which includes the light-emitting elements described in Embodiment 4 or 5 and arranged in a matrix is used as either the display portion 7304 or the display portion 7305, or both, and the structure can include other accessories as appropriate. The portable game machine illustrated in FIG. 7C has a function of reading out a program or data stored in a storage medium to display it on the display portion, and a function of sharing information with another portable game machine by wireless communication. Note that functions of the portable game machine illustrated in FIG. 7C are not limited to them, and the portable game machine can have various functions.

FIG. 7D illustrates an example of a mobile phone. A mobile phone is provided with a display portion 7402 incorporated in a housing 7401, operation buttons 7403, an external connection port 7404, a speaker 7405, a microphone 7406, and the like. Note that the mobile phone has the display portion 7402 including the light-emitting elements described in Embodiment 4 or 5 and arranged in a matrix.

When the display portion 7402 of the mobile phone illustrated in FIG. 7D is touched with a finger or the like, data can be input into the mobile phone. In this case, operations such as making a call and creating an e-mail can be performed by touching the display portion 7402 with a finger or the like.

There are mainly three screen modes of the display portion 7402. The first mode is a display mode mainly for displaying an image. The second mode is an input mode mainly for inputting information such as characters. The third mode is a display-and-input mode in which two modes of the display mode and the input mode are combined.

For example, in the case of making a call or creating an e-mail, a character input mode is selected for the display portion 7402 so that characters can be input on a screen. In this case, it is preferable to display a keyboard or number buttons on the screen of the display portion 7402.

When a sensing device including a sensor such as a gyroscope or an acceleration sensor for detecting inclination is provided inside the mobile phone, display on the screen can be automatically changed in direction by determining the orientation of the mobile phone (whether the mobile phone is placed horizontally or vertically).

The screen modes are switched by touch on the display portion 7402 or operation with the operation buttons 7403. The screen modes can be switched depending on the kind of images displayed on the display portion 7402. For example, when a signal of an image displayed on the display portion is a signal of moving image data, the screen mode is switched to the display mode. When the signal is a signal of text data, the screen mode is switched to the input mode.

In the input mode, when input by touching the display portion 7402 is not performed for a certain period, the screen mode may be controlled so as to be switched from the input mode to the display mode. Note that the touching operation may be sensed by an optical sensor in the display portion 7402.

The display portion 7402 may function as an image sensor. For example, an image of a palm print, a fingerprint, or the like is taken by the display portion 7402 while in touch with the palm or the finger, whereby personal authentication can be performed. Further, by providing a backlight or a sensing light source which emits a near-infrared light in the display portion, an image of a finger vein, a palm vein, or the like can be taken.

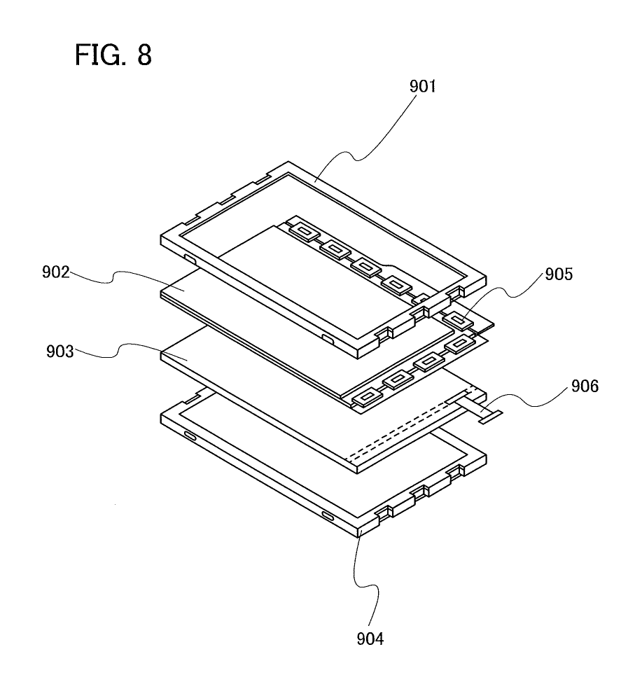

Next, description will be made with reference to FIG. 8 of one mode of a light source device using the light-emitting element that contains the heterocyclic compound according to one embodiment of the present invention. Note that a light source device includes a light-emitting element as a light irradiation unit and at least an input-output terminal portion that supplies current to the light-emitting element. The light-emitting element is preferably shielded from the outside atmosphere by sealing.

FIG. 8 illustrates an example of a liquid crystal display device in which the light-emitting element that contains the heterocyclic compound according to one embodiment of the present invention is applied to a backlight. The liquid crystal display device illustrated in FIG. 8 includes a housing 901, a liquid crystal layer 902, a backlight 903, and a housing 904, and the liquid crystal layer 902 is connected to a driver IC 905. The light-emitting element that contains the heterocyclic compound is used in the backlight 903, to which current is supplied through a terminal 906.

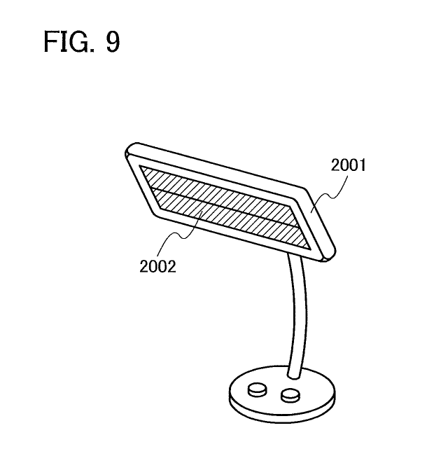

FIG. 9 illustrates an example of a desk lamp, which is a lighting device using the light-emitting element that contains the heterocyclic compound according to one embodiment of the present invention. The desk lamp illustrated in FIG. 9 includes a housing 2001 and a light source 2002. The light-emitting element that contains the heterocyclic compound is used for the light source 2002.

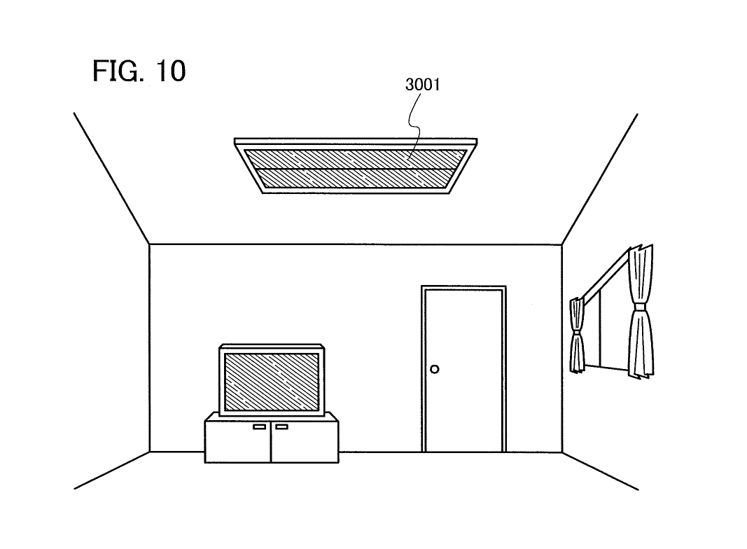

FIG. 10 illustrates an example in which the light-emitting element containing the heterocyclic compound according to one embodiment of the present invention is applied to an indoor lighting device 3001.

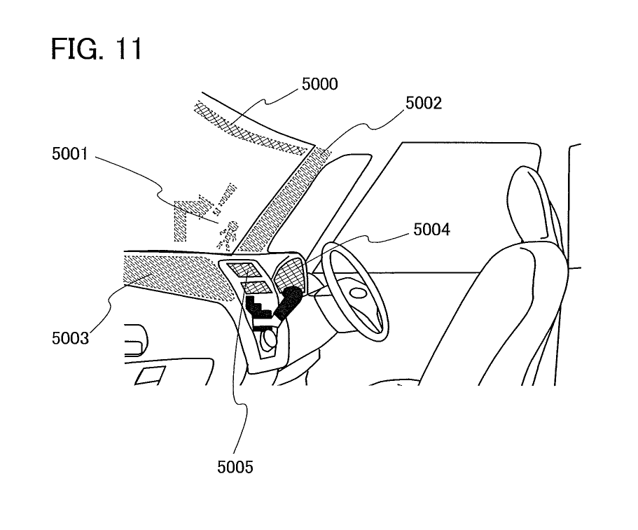

The light-emitting element that contains the heterocyclic compound according to one embodiment of the present invention can be used for an automobile windshield and an automobile dashboard. FIG. 11 illustrates one mode in which the light-emitting element that contains the heterocyclic compound is used for an automobile windshield and an automobile dashboard. In display regions 5000 to 5005, the light-emitting element that contains the heterocyclic compound is used.

The display region 5000 and the display region 5001 are provided in an automobile windshield. The light-emitting element that contains the heterocyclic compound can be formed into what is called a see-through display device, through which the opposite side can be seen, by including a first electrode and a second electrode formed of electrodes having light-transmitting properties. Such see-through display devices can be provided even in the automobile windshield, without hindering the vision. Note that in the case where a transistor for driving the display region is provided, a transistor having a light-transmitting property, such as an organic transistor using an organic semiconductor material or a transistor using an oxide semiconductor, is preferably used.

A display region 5002 is provided in a pillar portion. The display region 5002 can compensate for the view hindered by the pillar portion by showing an image taken by an imaging unit provided in the car body. Similarly, the display region 5003 provided in the dashboard can compensate for the view hindered by the car body by showing an image taken by an imaging unit provided in the outside of the car body, which leads to elimination of blind areas and enhancement of safety. Showing an image so as to compensate for the area which a driver cannot see makes it possible for the driver to confirm safety easily and comfortably.

The display region 5004 and the display region 5005 can provide a variety of kinds of information such as navigation data, speed, axial rotation speed of an engine, a mileage, a fuel level, a gearshift state, and air-condition setting. The content or layout of the display can be changed freely by a user as appropriate. Note that such information can also be shown by the display regions 5000 to 5003. The display regions 5000 to 5005 can also be used as lighting devices.

By containing the heterocyclic compound according to one embodiment of the present invention, a light-emitting element with low driving voltage or a light-emitting device with low power consumption can be achieved. Therefore, load on a battery is small even when a number of large screens such as the display regions 5000 to 5005 are provided, which provides comfortable use. For this reason, the light-emitting device and the lighting device each of which includes the light-emitting element containing the heterocyclic compound can be suitably used as an in-vehicle light-emitting device and lighting device.

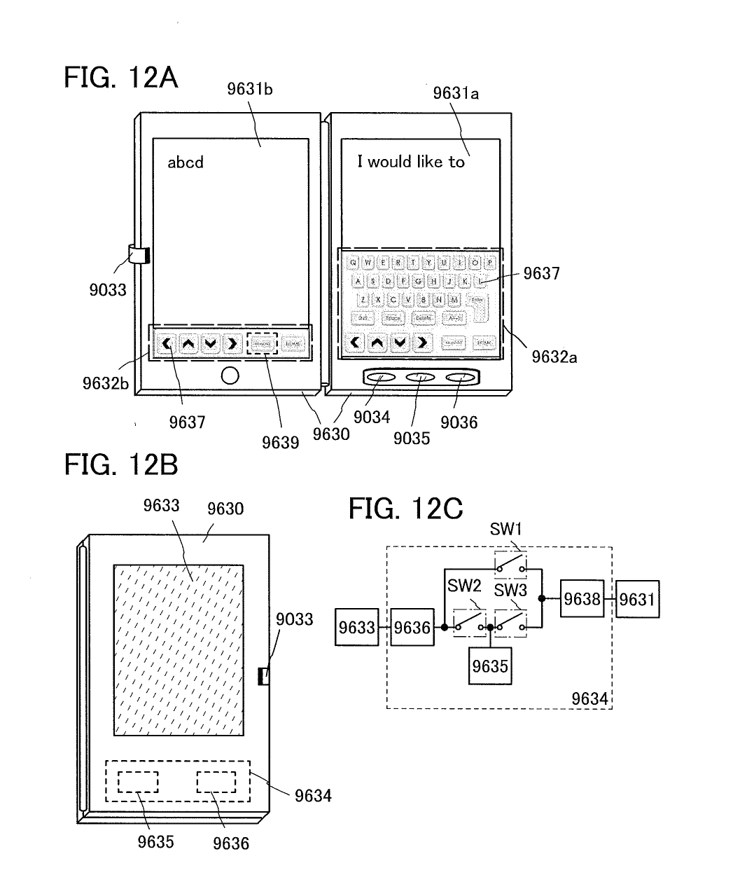

FIGS. 12A and 12B illustrate an example of a foldable tablet terminal. FIG. 12A illustrates the tablet terminal which is unfolded. The tablet terminal includes a housing 9630, a display portion 9631a, a display portion 9631b, a display mode switch 9034, a power switch 9035, a power-saving mode switch 9036, a clasp 9033, and an operation switch 9038. Note that in the tablet terminal, one or both of the display portion 9631a and the display portion 9631b is/are formed using a light-emitting device which includes a light-emitting element containing the heterocyclic compound.

Part of the display portion 9631a can be a touchscreen region 9632a and data can be input when a displayed operation key 9637 is touched. Although half of the display portion 9631a has only a display function and the other half has a touchscreen function, one embodiment of the present invention is not limited to the structure. The whole display portion 9631a may have a touchscreen function. For example, a keyboard can be displayed on the entire region of the display portion 9631a so that the display portion 9631a is used as a touchscreen, and the display portion 9631b can be used as a display screen.

Like the display portion 9631a, part of the display portion 9631b can be a touchscreen region 9632b. When a switching button 9639 for showing/hiding a keyboard on the touchscreen is touched with a finger, a stylus, or the like, the keyboard can be displayed on the display portion 9631b.

Touch input can be performed in the touchscreen region 9632a and the touchscreen region 9632b at the same time.

The display mode switch 9034 can switch the display between portrait mode, landscape mode, and the like, and between monochrome display and color display, for example. The power-saving mode switch 9036 can control display luminance in accordance with the amount of external light in use of the tablet terminal sensed by an optical sensor incorporated in the tablet terminal. Another sensing device including a sensor such as a gyroscope or an acceleration sensor for sensing inclination may be incorporated in the tablet terminal, in addition to the optical sensor.

Although FIG. 12A illustrates an example in which the display portion 9631a and the display portion 9631b have the same display area, one embodiment of the present invention is not limited to the example. The display portion 9631a and the display portion 9631b may have different display areas and different display quality. For example, higher definition images may be displayed on one of the display portions 9631a and 9631b.

FIG. 12B illustrates the tablet terminal which is folded. The tablet terminal in this embodiment includes the housing 9630, a solar cell 9633, a charge and discharge control circuit 9634, a battery 9635 and a DC-to-DC converter 9636.

Since the tablet terminal is foldable, the housing 9630 can be closed when the tablet terminal is not in use. As a result, the display portion 9631a and the display portion 9631b can be protected, thereby providing a tablet terminal with high endurance and high reliability for long-term use.

The tablet terminal illustrated in FIGS. 12A and 12B can have other functions such as a function of displaying various kinds of data (e.g., a still image, a moving image, and a text image), a function of displaying a calendar, a date, the time, or the like on the display portion, a touch-input function of operating or editing the data displayed on the display portion by touch input, and a function of controlling processing by various kinds of software (programs).

The solar cell 9633 provided on a surface of the tablet terminal can supply power to the touchscreen, the display portion, a video signal processing portion, or the like. Note that the solar cell 9633 can be provided on one or both surfaces of the housing 9630, so that the battery 9635 can be charged efficiently.

The structure and operation of the charge and discharge control circuit 9634 illustrated in FIG. 12B will be described with reference to a block diagram of FIG. 12C. FIG. 12C illustrates the solar cell 9633, the battery 9635, the DC-to-DC converter 9636, a converter 9638, switches SW1 to SW3, and a display portion 9631. The battery 9635, the DC-to-DC converter 9636, the converter 9638, and the switches SW1 to SW3 correspond to the charge and discharge control circuit 9634 illustrated in FIG. 12B.

First, description is made on an example of the operation in the case where power is generated by the solar cell 9633 with the use of external light. The voltage of the power generated by the solar cell is raised or lowered by the DC-to-DC converter 9636 so as to be voltage for charging the battery 9635. Then, when power from the solar cell 9633 is used for the operation of the display portion 9631, the switch SW1 is turned on and the voltage of the power is raised or lowered by the converter 9638 so as to be voltage needed for the display portion 9631. When images are not displayed on the display portion 9631, the switch SW1 is turned off and the switch SW2 is turned on so that the battery 9635 is charged.

Although the solar cell 9633 is described as an example of a power generation means, the power generation means is not particularly limited, and the battery 9635 may be charged by another power generation means such as a piezoelectric element or a thermoelectric conversion element (Peltier element). The battery 9635 may be charged by a non-contact power transmission module capable of performing charging by transmitting and receiving power wirelessly (without contact), or any of the other charge means used in combination, and the power generation means is not necessarily provided.

One embodiment of the present invention is not limited to the electronic device having the shape illustrated in FIGS. 12A to 12C as long as the display portion 9631 is included.

As described above, the light-emitting device including the light-emitting element that contains the heterocyclic compound according to one embodiment of the present invention has a markedly wide application range, and can be applied to electronic devices and light source devices in a variety of fields. Furthermore, with the use of the light-emitting element that contains the heterocyclic compound, a lighting device having a plane emission surface can be manufactured and can have a large area. Thus, the area of the display devices and the lighting devices can be increased. Moreover, they can be thinner than a conventional display device and lighting device; consequently, the display device and the lighting devices can also be thinner. Additionally, the light-emitting element has high emission efficiency and operates at low voltage, which contributes to the reduction of power consumption and driving voltage. Note that the structure described in this embodiment can be combined with any of the structures described in Embodiments 1 to 6 as appropriate.

### Example 1

In this example, description will be made of a synthesis method and properties of mIcBIm represented by Structural Formula (100) and included in the heterocyclic compound according to one embodiment of the present inventions.

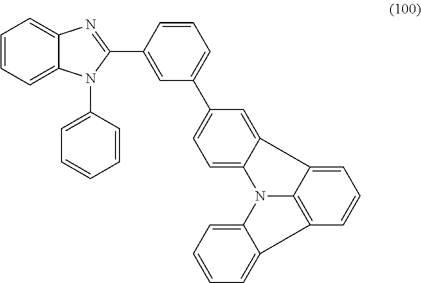 [SMILES: c1ccc(-n2c(-c3cccc(-c4ccc5c(c4)c4cccc6c7ccccc7n5c64)c3)nc3ccccc32)cc1]

### <Synthesis Method>

Into a 100-mL three-neck flask were put 1.6 g (4.0 mmol) of 2-[3-(1-phenyl-1H-benzimidazol-2-yl)phenyl]-4,4,5,5-tetramethyl-1,3,2-dioxaborolane, 1.1 g (3.4 mmol) of 5-bromoindolo[3,2,1-jk]carbazole, and 50 mg (0.16 mmol) of tris(2-methylphenyl)phosphine, and the atmosphere in the flask was replaced with nitrogen. To this mixture were added 4.0 mL of a 2M aqueous solution of potassium carbonate, 12 mL of toluene, and 4.0 mL of ethanol, and the mixture was degassed by being stirred under reduced pressure. To this mixture was added 7.4 mg (33 μmmol) of palladium(II) acetate and stirring was performed under a nitrogen stream at 90° C. for 12 hours. A precipitated solid was collected by suction filtration. Water was added to the obtained solid, irradiation with ultrasonic waves was performed, and a solid was collected by suction filtration. To the obtained solid was added methanol, irradiation with ultrasonic waves was performed, and an insoluble was collected by suction filtration. The obtained solid was dissolved in chloroform, and dried with magnesium sulfate. This mixture was subjected to natural filtration and the obtained filtrate was concentrated to give a white solid. This solid was recrystallized from hot toluene, whereby 1.4 g of a white solid was obtained in a yield of 82%. The synthesis scheme of this reaction is shown below.

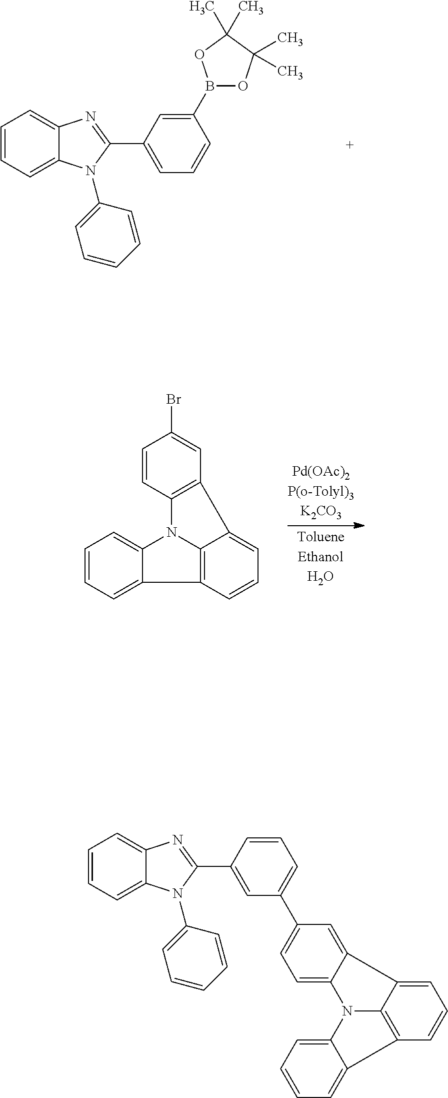 [SMILES: CC1(C)OB(c2cccc(-c3nc4ccccc4n3-c3ccccc3)c2)OC1(C)C ; Brc1ccc2c(c1)c1cccc3c4ccccc4n2c31 ; c1ccc(-n2c(-c3cccc(-c4ccc5c(c4)c4cccc6c7ccccc7n5c64)c3)nc3ccccc32)cc1]

Then, 1.4 g of the obtained white solid was purified by a train sublimation method. In the purification by sublimation, the white solid was heated at 245° C. under a pressure of 3.5 Pa with a flow rate of argon gas of 5.0 mL/min. After the purification by sublimation, 0.85 g of a white solid was obtained at a collection rate of 61%.

This compound was identified as mIcBIm, which was an objective substance, by a nuclear magnetic resonance (NMR) method.

¹H NMR data of the obtained mIcBIm are as follows: ¹H NMR (CDCl₃, 300 MHz): δ (ppm)=7.31 (d, 2H), 7.35-7.48 (m, 5H), 7.56-7.66 (m, 7H), 7.73 (d, 1H), 7.90-7.97 (m, 4H), 8.07-8.09 (m, 3H), 8.17 (d, 1H)

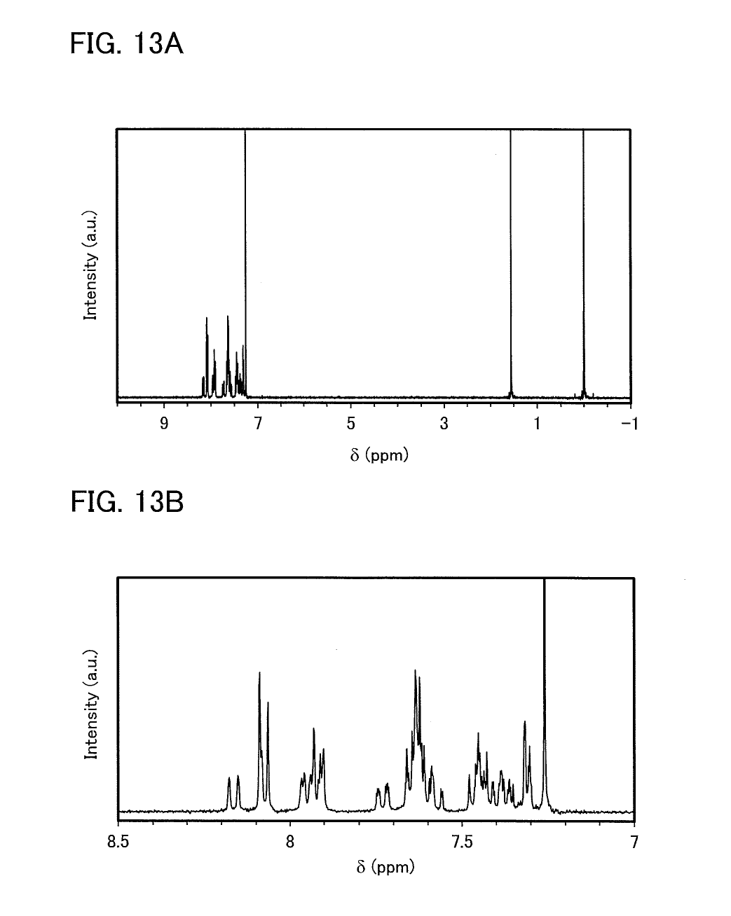

FIGS. 13A and 13B are ¹H NMR charts. Note that FIG. 13B shows an enlarged part of FIG. 13A in the range of 7.00 ppm to 8.50 ppm. The measurement results reveal that mIcBIm, which was the objective, was obtained.

<<Properties of mIcBIm>>

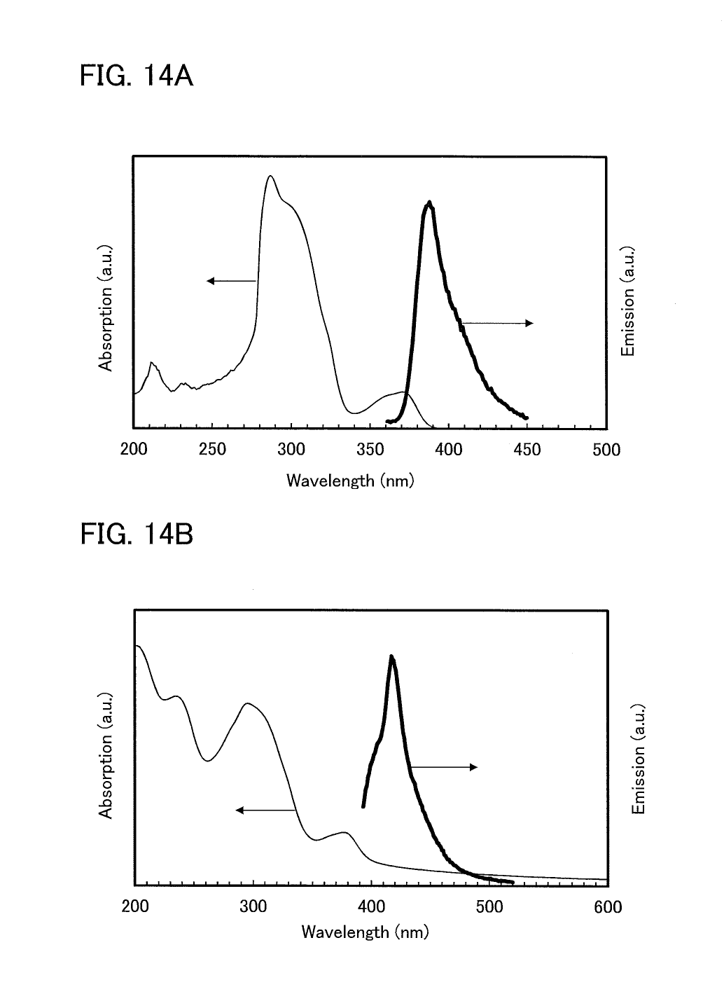

FIG. 14A shows an absorption spectrum and an emission spectrum of a toluene solution of mIcBIm, and FIG. 14B shows an absorption spectrum and an emission spectrum of a thin film of mIcBIm. The spectra were measured with a UV-visible spectrophotometer (V550, produced by JASCO Corporation). The spectra of the toluene solution were measured with a toluene solution of mIcBIm put in a quartz cell. The spectra of the thin film were measured with a sample prepared by deposition of mIcBIm on a quartz substrate by evaporation. Note that in the case of the absorption spectrum of the toluene solution of mIcBIm, the absorption spectrum obtained by subtraction of the absorption spectra of quartz and toluene from the measured spectra is shown in the drawing and that in the case of the absorption spectrum of the thin film of mIcBIm, the absorption spectrum obtained by subtraction of the absorption spectrum of the quartz substrate from the measured spectra is shown in the drawing.

FIG. 14A shows that in the case of a toluene solution of mIcBIm, absorption peaks are observed at 286 nm, 296 nm, and 370 nm, and an emission wavelength peak is observed at 388 nm (excitation wavelength: 280 nm). FIG. 14B shows that in the case of a thin film of mIcBIm, absorption peaks are observed at 201 nm, 232 nm, 292 nm, and 372 nm, and emission wavelength peaks are observed at 406 nm and 418 nm (excitation wavelength: 377 nm). Thus, absorption and light emission of mIcBIm occur in extremely short wavelength regions.

The ionization potential of mIcBIm in a thin film state was measured by a photoelectron spectrometer (AC-2, manufactured by Riken Keiki, Co., Ltd.) in the air. The obtained value of the ionization potential was converted into a negative value, so that the HOMO level of mIcBIm was −5.60 eV. From the data of the absorption spectra of the thin film in FIG. 14B, the absorption edge of mIcBIm, which was obtained from Tauc plot with an assumption of direct transition, was 3.11 eV. Therefore, the band gap of mIcBIm in a solid state was estimated at 3.11 eV; from the values of the HOMO level obtained above and this band gap, the LUMO level of mIcBIm was estimated at −2.49 eV. This reveals that mIcBIm in the solid state has a band gap as wide as 3.11 eV.

Furthermore, mIcBIm was analyzed by liquid chromatography mass spectrometry (LC/MS).

The analysis by LC/MS was carried out with Acquity UPLC (produced by Waters Corporation) and Xevo G2 T of MS (produced by Waters Corporation).

In the MS analysis, ionization was carried out by an electrospray ionization (ESI) method. Capillary voltage and sample cone voltage were set to 3.0 kV and 30 V, respectively. Detection was performed in a positive mode. A component which underwent the ionization under the above-mentioned conditions was collided with an argon gas in a collision cell to dissociate into product ions. Energy (collision energy) for the collision with argon was 70 eV. A mass range for the measurement was m/z=100 to 1200.

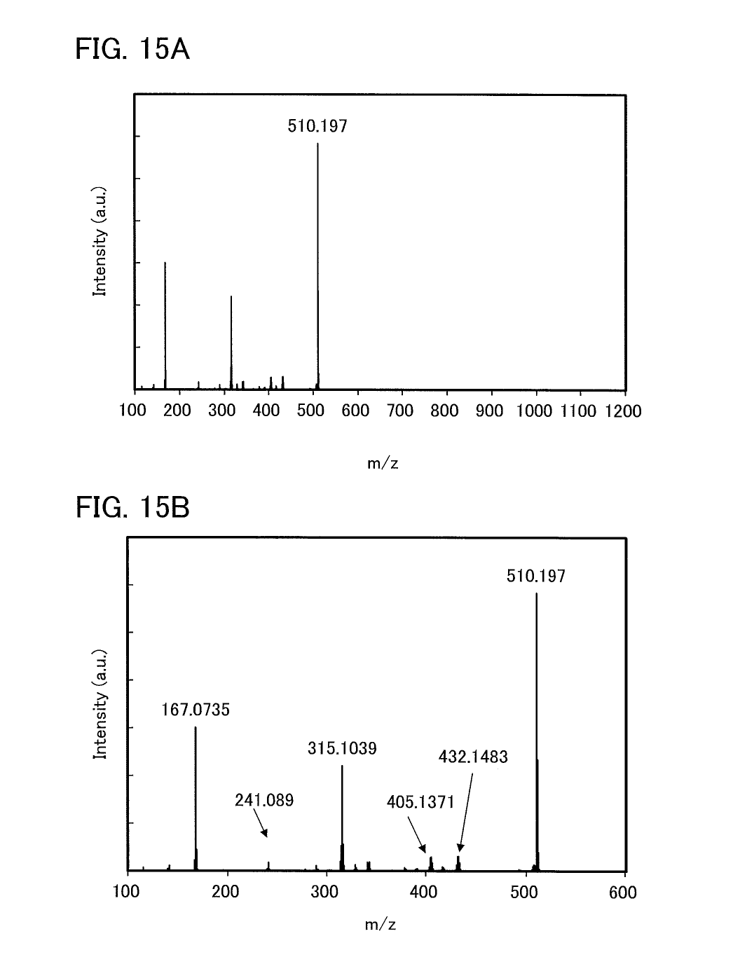

FIGS. 15A and 15B show the results. FIG. 15B is a graph where a range where m/z=100 to 600 in FIG. 15A is enlarged.

### Example 2

In this example, description will be made of a light-emitting element (a light-emitting element 1) in which mIcBIm, which is the heterocyclic compound according to one embodiment of the present invention is used as a host material in a light-emitting layer including a green-emissive phosphorescent material.

The molecular structures of organic compounds used in this example are shown in Structural Formulae (i) to (v) and (100) below. The element structure in FIG. 1A was employed.

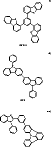 [SMILES: c1ccc2c(c1)sc1c(-c3cc(-c4cccc5c4sc4ccccc45)cc(-c4cccc5c4sc4ccccc45)c3)cccc12 ; "DBT3P-II" ; c1ccc(-n2c3ccccc3c3cc(-c4ccc5c(c4)c4ccccc4n5-c4ccccc4)ccc32)cc1 ; "PCCP" ; c1ccc(-n2c(-c3cccc(-c4ccc5c(c4)c4cccc6c7ccccc7n5c64)c3)nc3ccccc32)cc1]

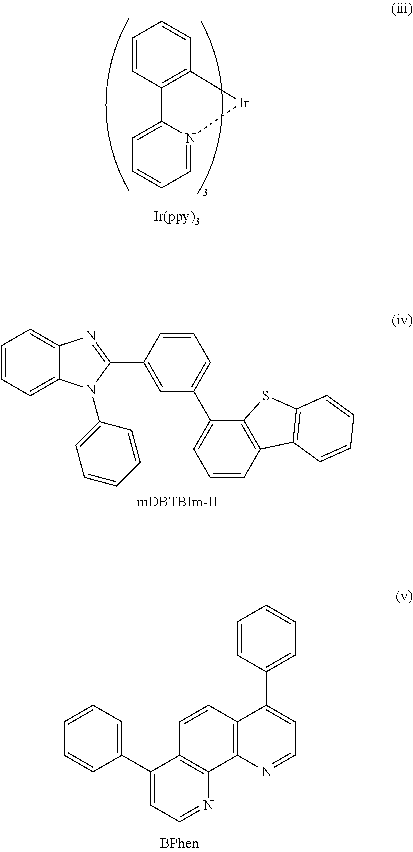

### <<Fabrication of Light-Emitting Element 1>>

First, a glass substrate, over which a film of indium tin oxide containing silicon (ITSO) was formed to a thickness of 110 nm as the first electrode 101, was prepared. A surface of the ITSO film was covered with a polyimide film so that an area of 2 mm×2 mm of the surface was exposed. As pretreatment for forming the light-emitting element over the substrate, the surface of the substrate was washed with water and baked at 200° C. for one hour, and then UV-ozone treatment was performed for 370 seconds. After that, the substrate was transferred into a vacuum evaporation apparatus where the pressure had been reduced to approximately 10⁻⁴ Pa, and was subjected to vacuum baking at 170° C. for 30 minutes in a heating chamber of the vacuum evaporation apparatus, and then the substrate was cooled down for about 30 minutes.

Then, the substrate was fixed to a holder provided in the vacuum evaporation apparatus so that the surface provided with ITSO faced downward.

The pressure in the vacuum evaporation apparatus was reduced to 10⁻⁴ Pa. Then, DBT3P-II represented by Structural Formula (i) and molybdenum oxide were co-evaporated such that DBT3P-II:molybdenum oxide=4:2 (weight ratio), whereby the hole-injection layer 111 was formed. The thickness was set to 60 nm.

Next, PCCP represented by Structural Formula (ii) was evaporated to a thickness of 20 nm, whereby the hole-transport layer 112 was formed.

Moreover, PCCP, mIcBIm, and Ir(ppy)₃ represented by Structural Formula (iii) were evaporated to a thickness of 20 nm on the hole-transport layer 112 such that PCCP:mIcBIm:Ir(ppy)₃=1:0.3:0.06 (weight ratio), and then, mIcBIm and Ir(ppy)₃ were evaporated to a thickness of 20 nm such that mIcBIm:Ir(ppy)₃=1:0.06 (weight ratio), whereby the light-emitting layer 113 was formed.

Next, mDBTBIm-II represented by Structural Formula (Iv) was evaporated to a thickness of 10 nm, and then BPhen represented by Structural Formula (v) was evaporated to a thickness of 15 nm, whereby the electron-transport layer 114 was formed.

Then, lithium fluoride was evaporated to a thickness of 1 nm on the electron-transport layer 114, whereby the electron-injection layer 115 was formed. Lastly, a film of aluminum was formed to a thickness of 200 nm as the second electrode 102 which serves as a cathode. Thus, the light-emitting element 1 was completed. Note that the above evaporation steps were all performed by a resistance-heating method.

### <<Operation Characteristics of Light-Emitting Element 1>>

The light-emitting element 1 obtained as described above was sealed in a glove box containing a nitrogen atmosphere so as not to be exposed to the air (specifically, a sealing material was applied onto an outer edge of the element and UV treatment was performed at 80° C. for one hour at the time of sealing). Then, the operating characteristics of the light-emitting element 1 were measured. Note that the measurement was carried out at room temperature (in an atmosphere kept at 25° C.).

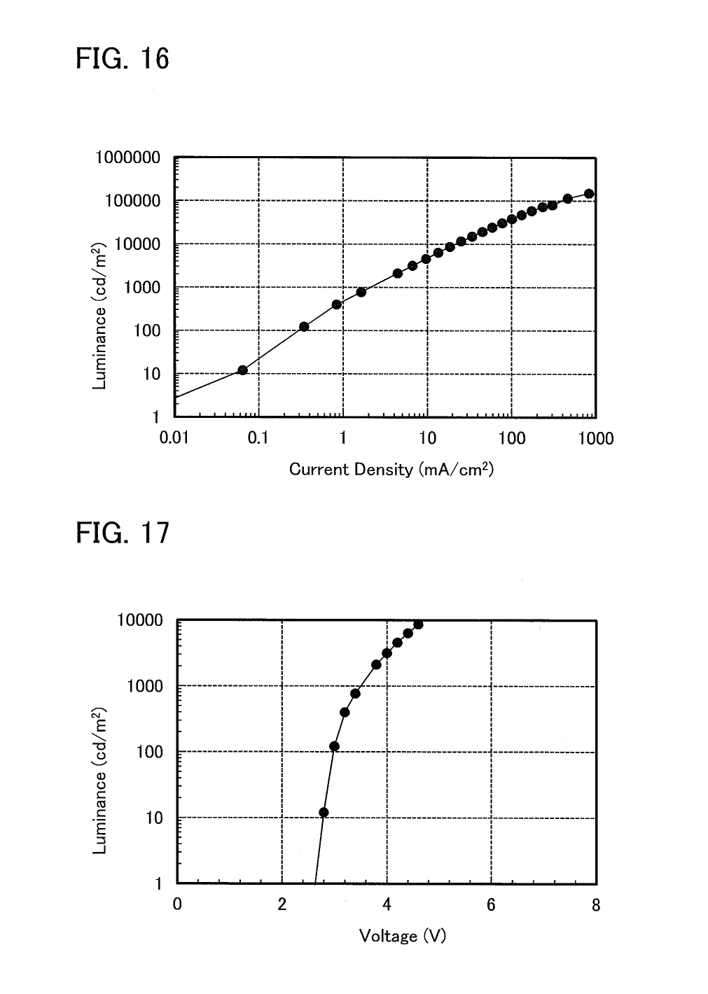

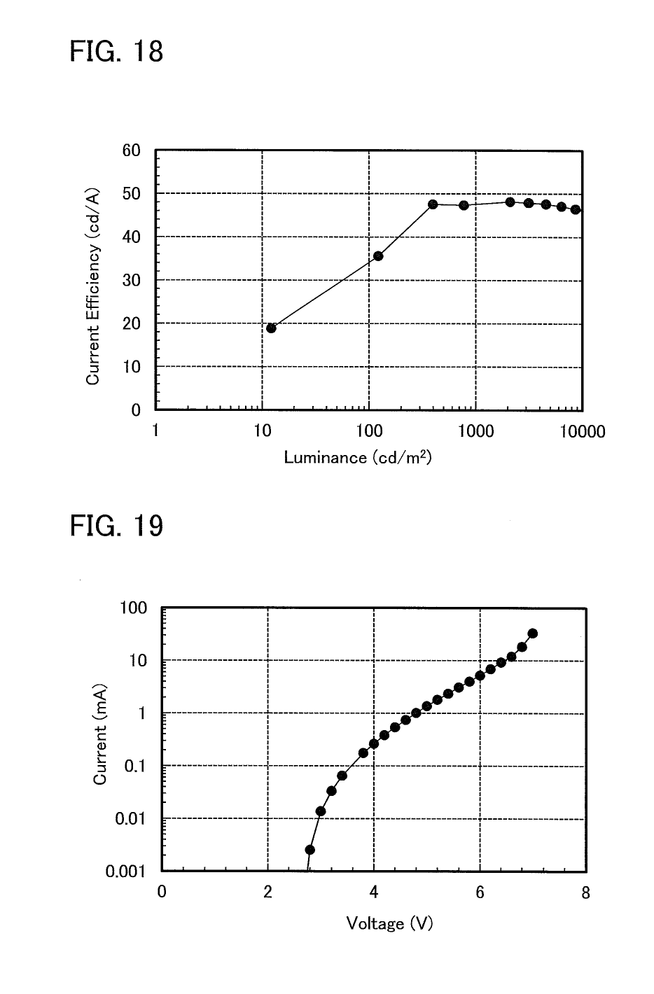

As to the light-emitting element 1, FIG. 16 shows the current density-luminance characteristics, FIG. 17 shows the voltage-luminance characteristics, FIG. 18 shows the luminance-current efficiency characteristics, and FIG. 19 shows the voltage-current characteristics.

FIG. 18 shows that the light-emitting element 1 has high luminance-current efficiency characteristics and thus has high emission efficiency. Accordingly, mIcBIm, which is the heterocyclic compound according to one embodiment of the present invention, has high triplet level and a wide band gap, allows even a green-emissive phosphorescent material to be effectively excited. Moreover, FIG. 17 shows that the light-emitting element 1 has favorable voltage-luminance characteristics and thus has low driving voltage. This means that mIcBIm has a high carrier-transport property. FIG. 16 similarly shows that the light-emitting element 1 has favorable current density-luminance characteristics.

Therefore, the light-emitting element that contains the heterocyclic compound according to one embodiment of the present invention has favorable characteristics, such as high emission efficiency and low driving voltage. Note that in mIcBIm, the heterocyclic skeleton is an imidazole skeleton to which benzene is fused.

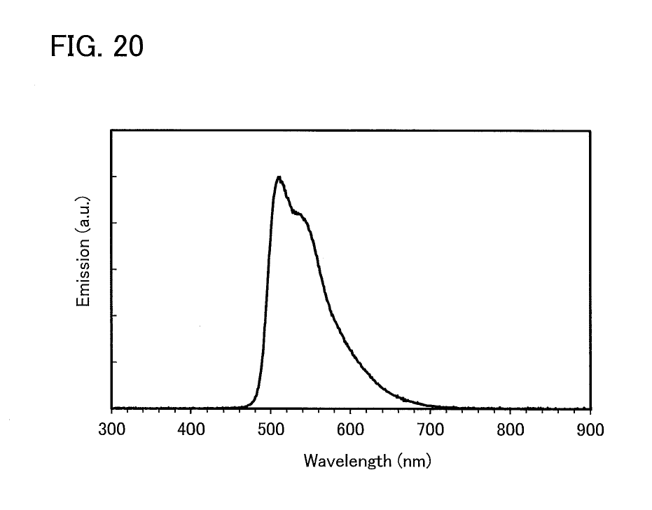

FIG. 20 shows an emission spectrum at the time when a current of 0.1 mA was made to flow in the manufactured light-emitting element. FIG. 20 reveals that the light-emitting element 1 emits green light originating from Ir(ppy)₃ functioning as the emission substance.

### Example 3

In this example, description will be made of a light-emitting element (a light-emitting element 2) in the aforementioned mIcBIm is used as a host material in a light-emitting layer including a blue-green emissive phosphorescent material.

The molecular structures of organic compounds used in this example are shown in Structural Formulae (i), (ii), (iv), (v), (vi), and (100) below. The element structure in FIG. 1A was employed. Differences from the light-emitting element 1 are only the thickness of the hole-injection layer (20 nm in the case of the light-emitting element 1) and the structure of the light-emitting layer. Thus, explanation is given below only for the formation of the light-emitting layer.

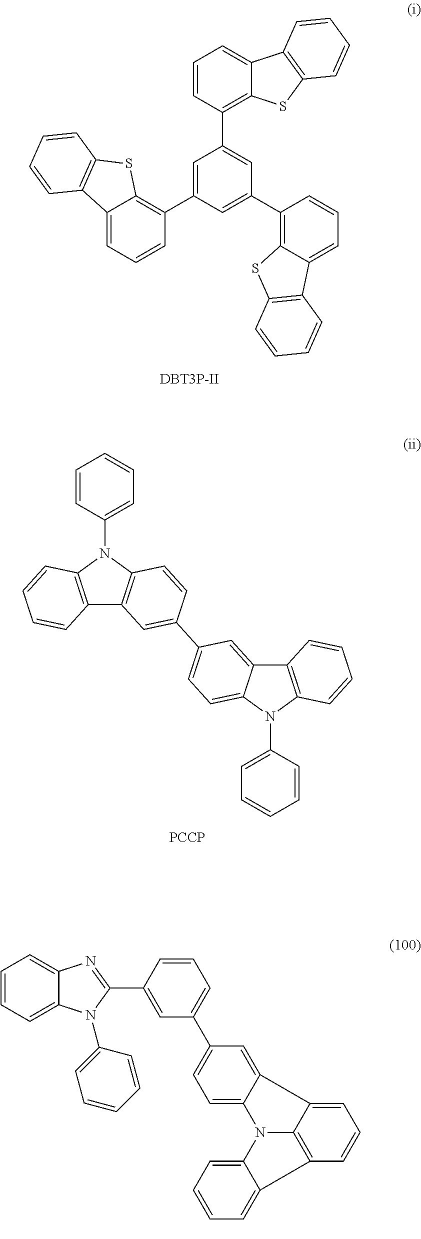 [SMILES: c1ccc2c(c1)sc1c(-c3cc(-c4cccc5c4sc4ccccc45)cc(-c4cccc5c4sc4ccccc45)c3)cccc12 ; "DBT3P-II" ; c1ccc(-n2c3ccccc3c3cc(-c4ccc5c(c4)c4ccccc4n5-c4ccccc4)ccc32)cc1 ; "PCCP" ; c1ccc(-n2c(-c3cccc(-c4ccc5c(c4)c4cccc6c7ccccc7n5c64)c3)nc3ccccc32)cc1]

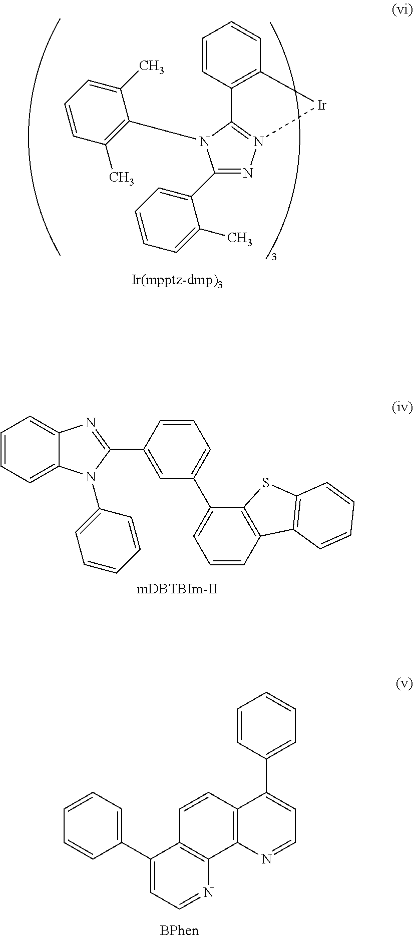

### <<Fabrication of Light-Emitting Element 2>>

After the formation of the hole-injection layer 111 and the hole-transport layer 112 in a similar way to those of the light-emitting element 1, PCCP, mIcBIm, and Ir(mpptz-dmp)₃ represented by Structural Formula (vi) were evaporated to a thickness of 30 nm on the hole-transport layer 112 such that PCCP:mIcBIm:Ir(mpptz-dmp)₃=1:0.3:0.06 (weight ratio), and then, mIcBIm and Ir(mpptz-dmp)₃ were evaporated to a thickness of 10 nm such that mIcBIm:Ir(mpptz-dmp)₃=1:0.06 (weight ratio), whereby the light-emitting layer 113 was formed.

Next, the electron-transport layer 114, electron-injection layer 115 and the second electrode 102 which have the same structure as those of the light-emitting element 1 were formed to complete the light-emitting element 2.

### <<Operation Characteristics of Light-Emitting Element 2>>

The light-emitting element 2 obtained as described above was sealed by the same method as that of the light-emitting element 1, and the operating characteristics were measured.

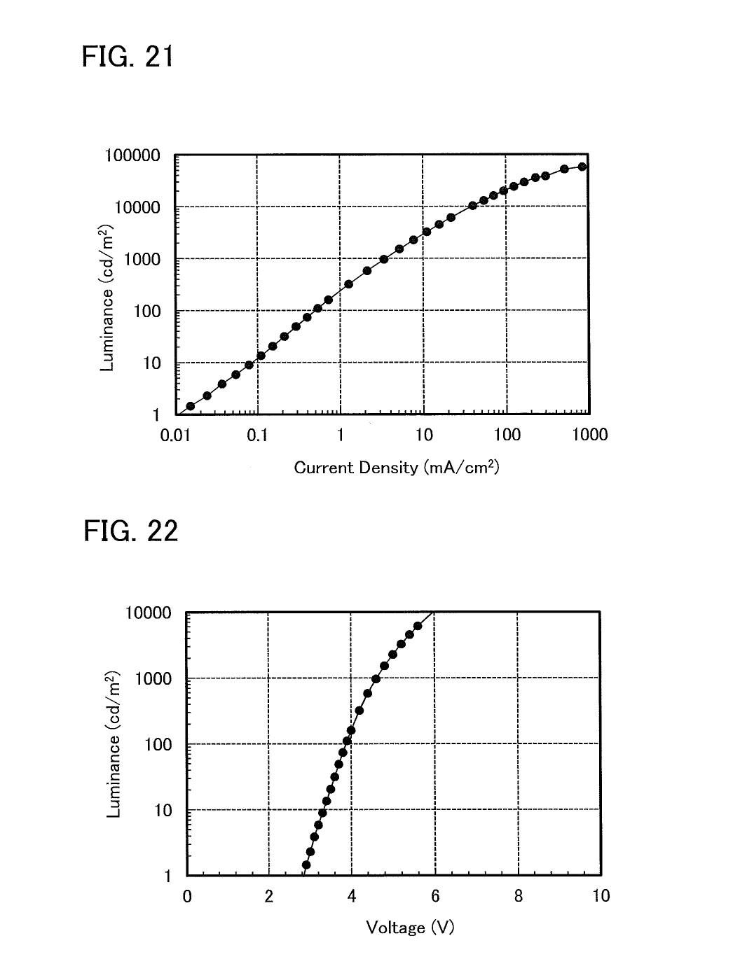

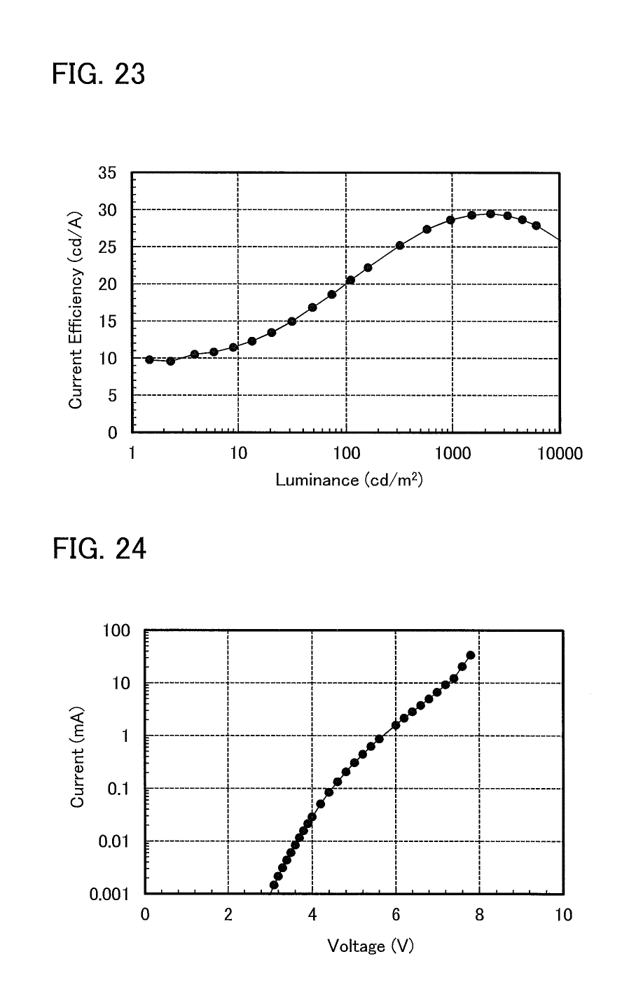

As to the light-emitting element 2, FIG. 21 shows the current density-luminance characteristics, FIG. 22 shows the voltage-luminance characteristics, FIG. 23 shows the luminance-current efficiency characteristics, and FIG. 24 shows the voltage-current characteristics.

FIG. 23 shows that the light-emitting element 2 has high luminance-current efficiency characteristics and thus has high emission efficiency. Accordingly, mIcBIm, which is the heterocyclic compound according to one embodiment of the present invention has high triplet level and a wide energy gap, which allows even a blue-green emissive phosphorescent material to be effectively excited. Moreover, FIG. 22 shows that the light-emitting element 2 has favorable voltage-luminance characteristics and thus has low driving voltage. This means that mIcBIm has a high carrier-transport property. FIG. 21 similarly shows that the light-emitting element 2 has favorable current density-luminance characteristics.

Therefore, the light-emitting element 2 is a light-emitting element having favorable characteristics, such as high emission efficiency and low driving voltage.

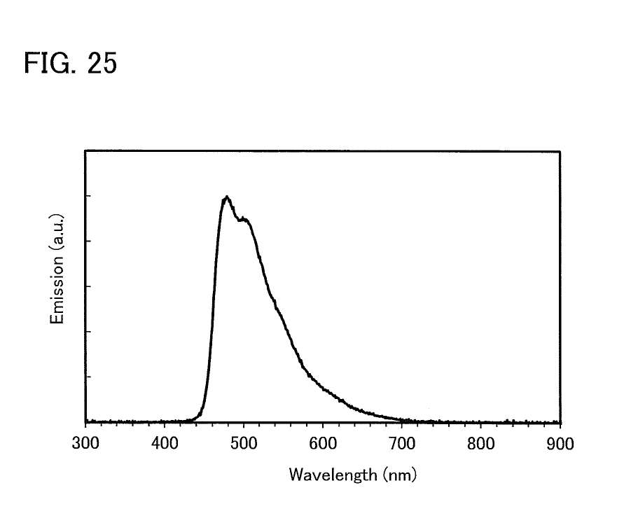

FIG. 25 shows an emission spectrum at the time when a current of 0.1 mA was made to flow in the manufactured light-emitting element 2. FIG. 25 reveals that the light-emitting element 2 emits blue-green light originating from Ir(mpptz-dmp)₃ functioning as the emission substance.

### Example 4

In this example, description will be made of a light-emitting element (a light-emitting element 3) in which 5-[3-(dibenzo[f,h]quinoxalin-2-yl)phenyl]indolo[3,2,1-jk]carbazole (abbreviation: 2mIcPDBq), which is the heterocyclic compound according to one embodiment of the present invention, is used as a host material in a light-emitting layer including a yellow-green emissive phosphorescent material.

The molecular structures of organic compounds used in this example are shown in Structural Formulae (i) to (v) and (100) below. The element structure in FIG. 1A was employed. Differences from the light-emitting element 1 are only the structures of the hole-transport layer, the light-emitting layer, and the electron-transport Thus, explanation is given below only for the formation of these light-emitting layers.

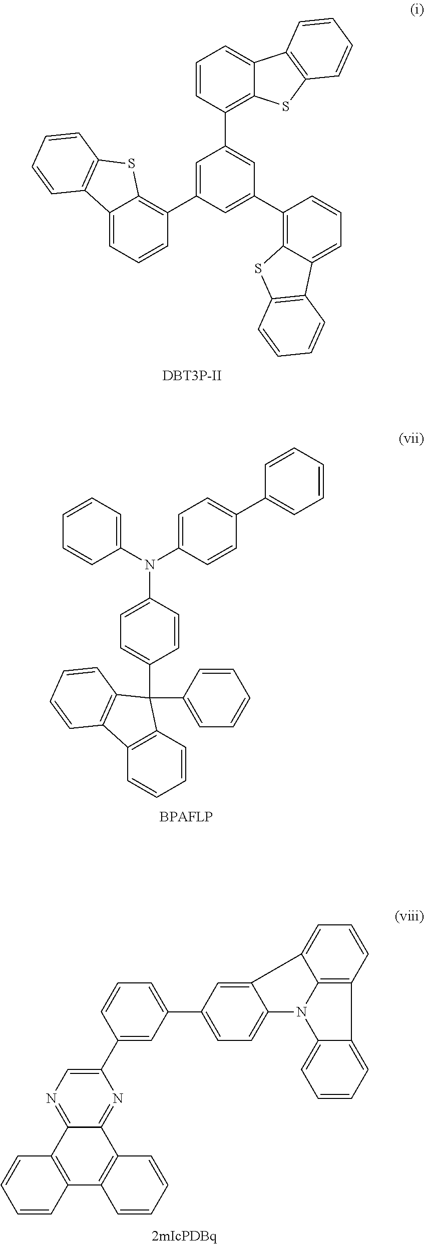 [SMILES: c1ccc2c(c1)sc1c(-c3cc(-c4cccc5c4sc4ccccc45)cc(-c4cccc5c4sc4ccccc45)c3)cccc12 ; "DBT3P-II" ; c1ccc(-c2ccc(N(c3ccccc3)c3ccc(C4(c5ccccc5)c5ccccc5-c5ccccc54)cc3)cc2)cc1 ; c1cc(-c2ccc3c(c2)c2cccc4c5ccccc5n3c42)cc(-c2cnc3c4ccccc4c4ccccc4c3n2)c1]

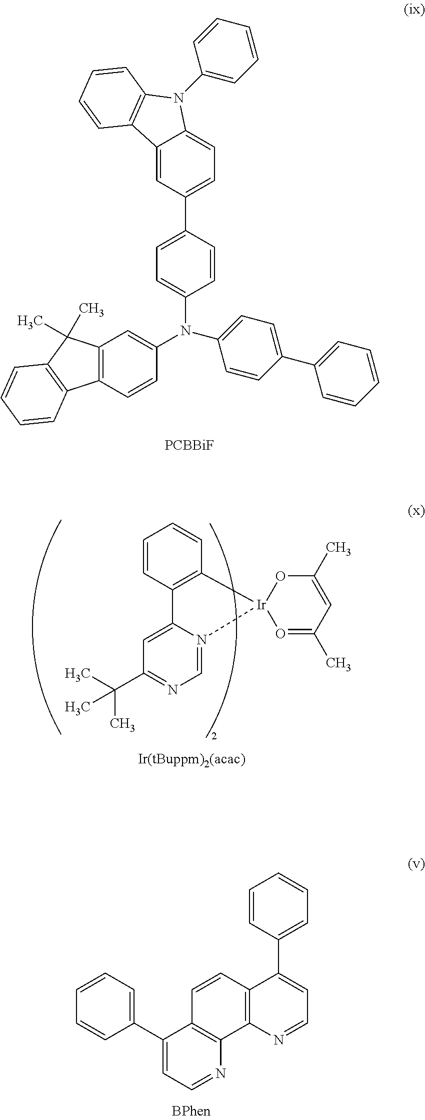

### <<Fabrication of Light-Emitting Element 3>>

After the hole-injection layer 111 was formed in the same way as that of the light-emitting element 1, BPAFLP represented by Structural Formula (vii) was evaporated to a thickness of 20 nm, whereby the hole-transport layer 112 was formed.

Moreover, 2mIcPDBq represented by Structural Formula (viii), N-(1,1′-biphenyl-4-yl)-N-[4-(9-phenyl-9H-carbazol-3-yl)phenyl]-9,9-dimethyl-9H-fluor en-2-amine (abbreviation: PCBBiF) represented by Structural Formula (ix), and Ir(tBuppm)₂(acac) represented by Structural Formula (x) were evaporated to a thickness of 20 nm on the hole-transport layer 112 such that 2mIcPDBq:PCBBiF:Ir(tBuppm)₂(acac)=0.7:0.3:0.05 (weight ratio), and then, 2mIcPDBq, PCBBiF, and Ir(tBuppm)₂(acac) were evaporated to a thickness of 20 nm such that 2mIcPDBq:PCBBiF:Ir(tBuppm)₂(acac)=0.8:0.2:0.05 (weight ratio), whereby the light-emitting layer 113 was formed.

Next, 2mIcPDBq was evaporated to a thickness of 20 nm and then BPhen was evaporated to a thickness of 20 nm, whereby the electron-transport layer 114 was formed.

Then, the electron-injection layer 115 and the second electrode 102 which have the same structures as those of the light-emitting element 1 were formed to complete the light-emitting elopement 3.

### <<Operation Characteristics of Light-Emitting Element 3>>

The light-emitting element 3 obtained as described above was sealed in the same way as that of the light-emitting element 1, and the operating characteristics were measured.

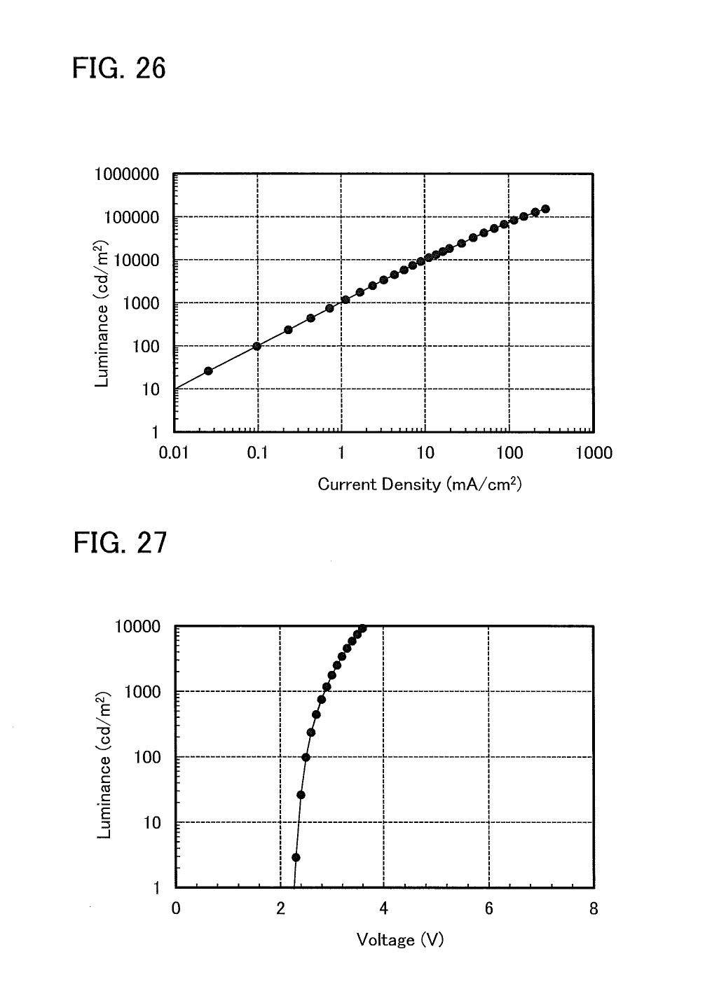

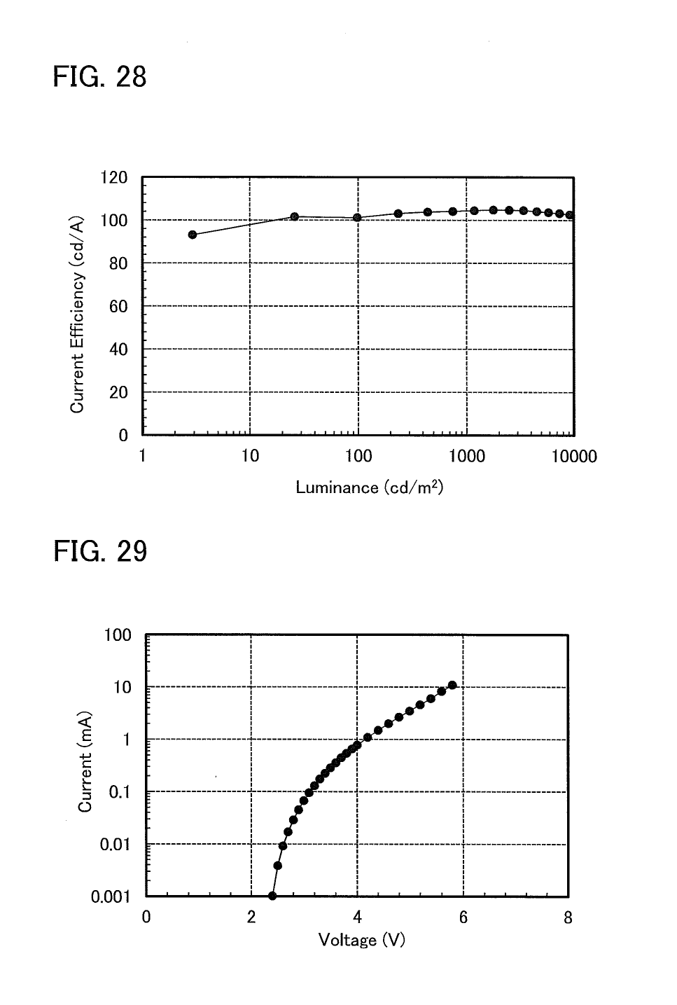

As to the light-emitting element 3, FIG. 26 shows the current density-luminance characteristics, FIG. 27 shows the voltage-luminance characteristics, FIG. 28 shows the luminance-current efficiency characteristics, and FIG. 29 shows the voltage-current characteristics.

FIG. 28 shows that the light-emitting element 3 has favorable luminance-current efficiency characteristics and thus has high emission efficiency. Accordingly, 2mIcPDBq, which is the heterocyclic compound according to one embodiment of the present invention, has high triplet level and a wide band gap, allows even a yellow-green emissive phosphorescent material to be effectively excited. Moreover, FIG. 27 shows that the light-emitting element 3 has favorable voltage-luminance characteristics and thus has low driving voltage. This means that 2mIcPDBq has a high carrier-transport property. FIG. 26 similarly shows that the light-emitting element 3 has favorable current density-luminance characteristics.

Therefore, the light-emitting element that contains the heterocyclic compound according to one embodiment of the present invention has favorable characteristics, such as high emission efficiency and low driving voltage. Note that in 2mIcPDBq, the heterocyclic skeleton is a pyrazine skeleton to which benzene is fused.

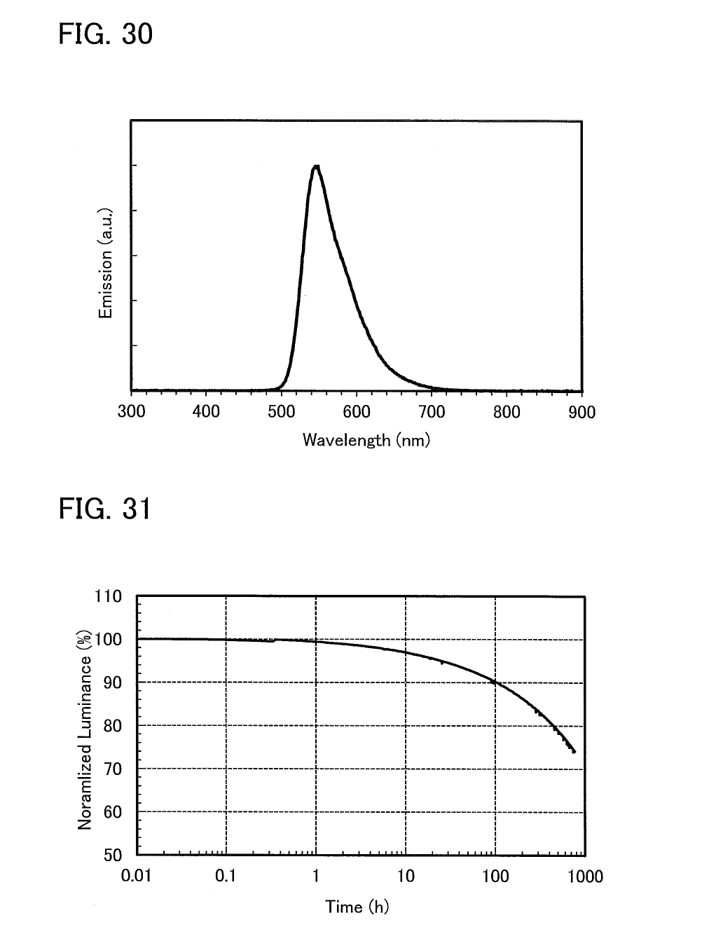

FIG. 30 shows an emission spectrum at the time when a current of 0.1 mA was made to flow in the manufactured light-emitting element. FIG. 30 reveals that the light-emitting element 3 emits yellow-green light originating from Ir(tBuppm)₂(acac) functioning as the emission substance.

FIG. 31 shows the results of a reliability test performed on the light-emitting element 3. In the reliability test, a change in normalized luminance over driving time was measured with an initial luminance of 5000 cd/m² at a constant current density. From FIG. 31, the light-emitting element 3 keeps its luminance 74% of the initial luminance even after the driving for 770 hours, so that the light-emitting element 3 has high reliability.

### Example 5

In this example, description will be made of a light-emitting element (a light-emitting element 4) in which 2mIcPDBq, which is the heterocyclic compound according to one embodiment of the present invention, is used as a host material in a light-emitting layer including an orange-emissive phosphorescent material.

The molecular structures of organic compounds used in this example are shown in Structural Formulae (i) to (v) and (100) below. The element structure in FIG. 1A was employed. A difference from the light-emitting element 3 is only the structure of the light-emitting layer. Thus, explanation is given below only for the formation of the light-emitting layer.

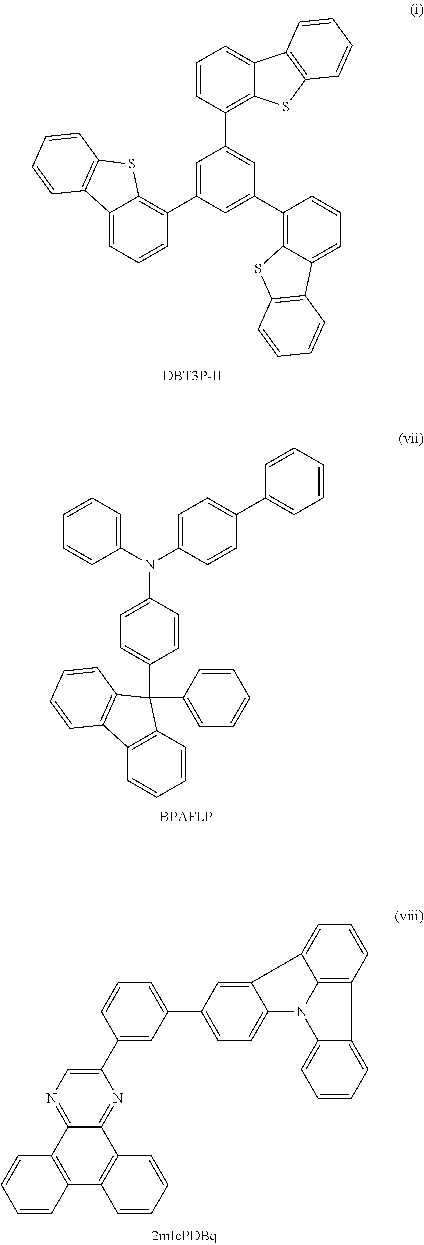 [SMILES: c1ccc2c(c1)sc1c(-c3cc(-c4cccc5c4sc4ccccc45)cc(-c4cccc5c4sc4ccccc45)c3)cccc12 ; "DBT3P-II" ; c1ccc(-c2ccc(N(c3ccccc3)c3ccc(C4(c5ccccc5)c5ccccc5-c5ccccc54)cc3)cc2)cc1 ; c1cc(-c2ccc3c(c2)c2cccc4c5ccccc5n3c42)cc(-c2cnc3c4ccccc4c4ccccc4c3n2)c1]

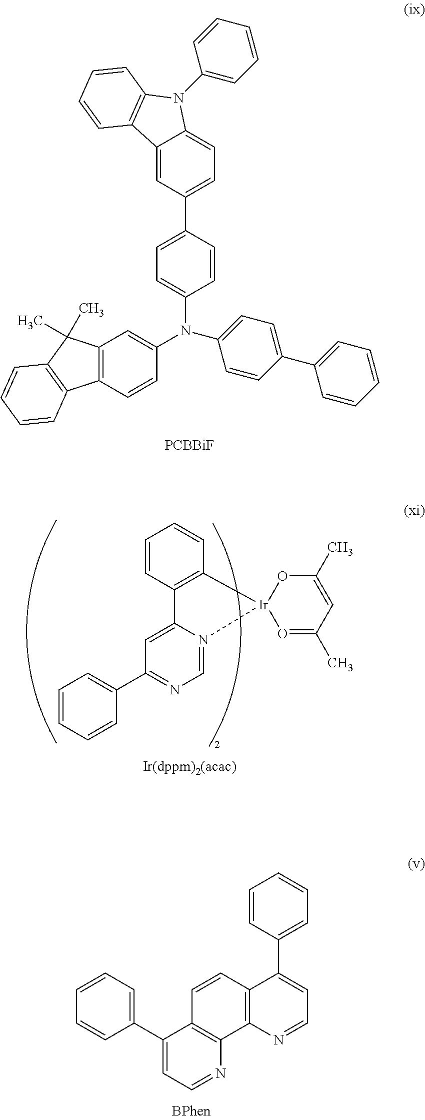

### <<Fabrication of Light-Emitting Element 4>>

After the formation of the hole-injection layer 111 and the hole-transport layer 112 having the same structures as those of the light-emitting element 3, 2mIcPDBq represented by Structural Formula (viii), PCBBiF represented by Structural Formula (ix), and Ir(dppm)₂(acac) represented by Structural Formula (xi) were evaporated to a thickness of 20 nm on the hole-transport layer 112 such that 2mIcPDBq:PCBBiF:Ir(dppm)₂(acac)=0.7:0.3:0.05 (weight ratio), and then, 2mIcPDBq, PCBBiF, and Ir(dppm)₂(acac) were evaporated to a thickness of 20 nm such that 2mIcPDBq:PCBBiF:Ir(dppm)₂(acac)=0.8:0.2:0.05 (weight ratio), whereby the light-emitting layer 113 was formed.

Next, the electron-transport layer 114, the electron-injection layer 115, and the second electrode 102 which have the same structures as those of the light-emitting element 3 were formed to complete the light-emitting element 4.

### <<Operation Characteristics of Light-Emitting Element 4>>

The light-emitting element 4 obtained as described above was sealed in the same way as that of the light-emitting element 1, and the operating characteristics were measured.

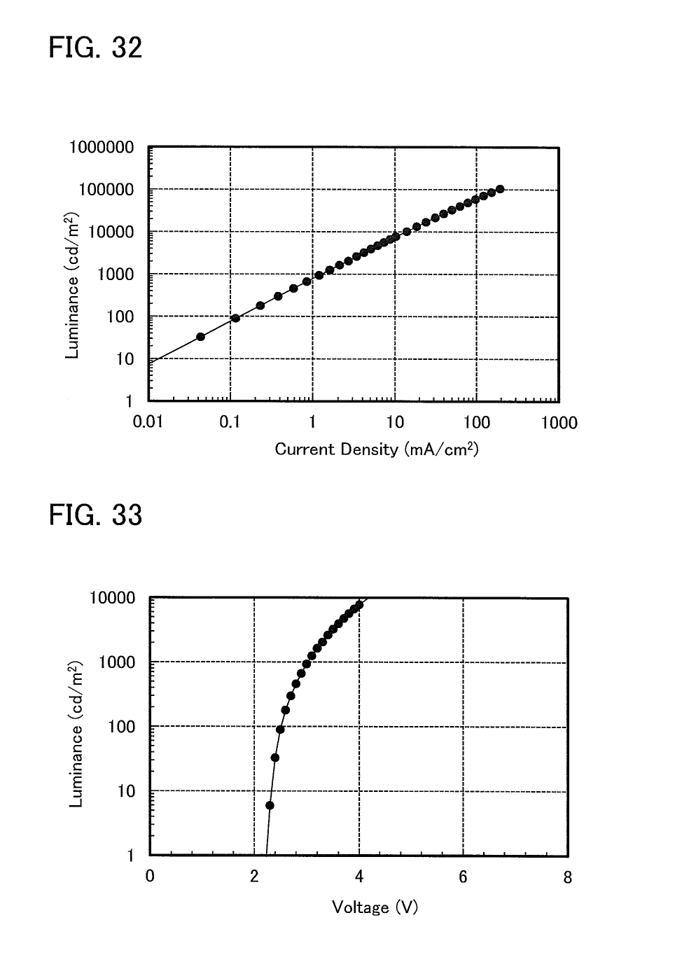

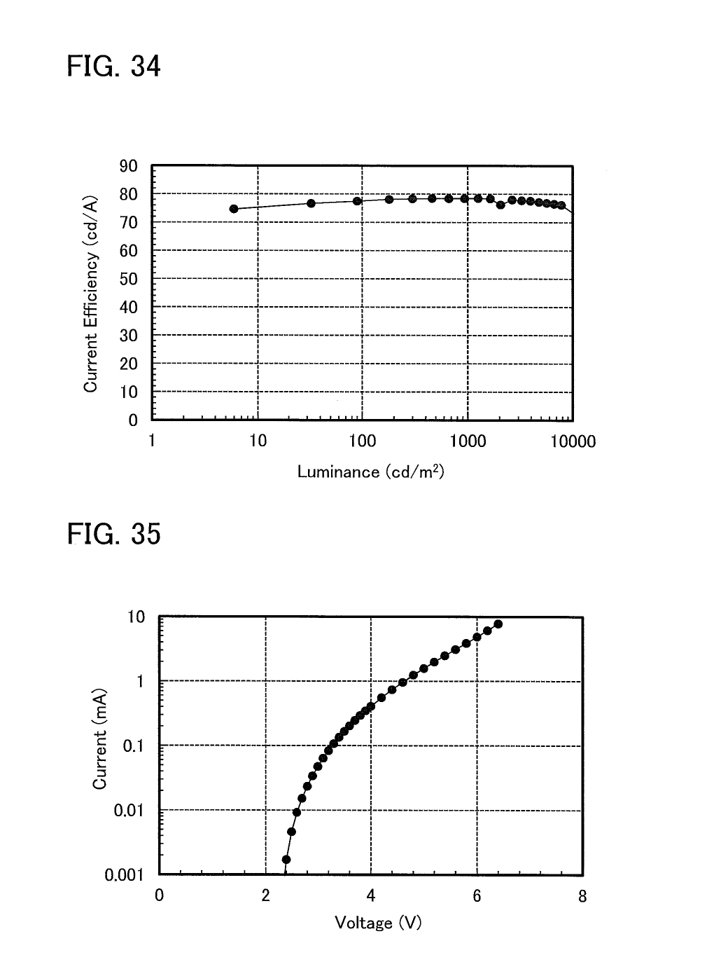

As to the light-emitting element 4, FIG. 32 shows the current density-luminance characteristics, FIG. 33 shows the voltage-luminance characteristics, FIG. 34 shows the luminance-current efficiency characteristics, and FIG. 35 shows the voltage-current characteristics.

FIG. 34 shows that the light-emitting element 4 has favorable luminance-current efficiency characteristics and thus has high emission efficiency. Accordingly, 2mIcPDBq, which is the heterocyclic compound according to one embodiment of the present invention, has high triplet level and a wide band gap, allows even an orange-emissive phosphorescent material to be effectively excited. Moreover, FIG. 33 shows that the light-emitting element 4 has favorable voltage-luminance characteristics and thus has low driving voltage. This means that 2mIcPDBq has a high carrier-transport property. FIG. 32 similarly shows that the light-emitting element 4 has favorable current density-luminance characteristics.

Therefore, the light-emitting element that contains the heterocyclic compound according to one embodiment of the present invention has favorable characteristics, such as high emission efficiency and low driving voltage. Note that in 2mIcPDBq, the heterocyclic skeleton is a pyrazine skeleton to which benzene is fused.

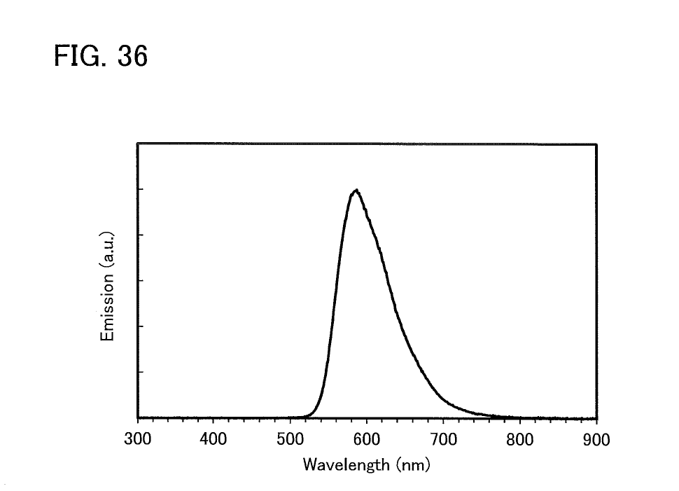

FIG. 36 shows an emission spectrum at the time when a current of 0.1 mA was made to flow in the manufactured light-emitting element. FIG. 36 reveals that the light-emitting element 4 emits orange light originating from Ir(dppm)₂(acac) functioning as the emission center substance.

### Reference Example 1

In this reference example, a synthesis method of Ir(mpptz-dmp)₃, which is used in the above example, will be described. A structure of Ir(mpptz-dmp)₃ is shown below.

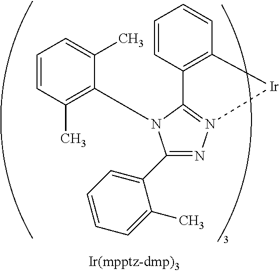

### Step 1: Synthesis of N-Benzoyl-N′-2-methylbenzoylhydrazide

First, 15.0 g (110.0 mmol) of benzoylhydrazine and 75 ml of N-methyl-2-pyrrolidinone (NMP) were put into a 300-ml three-neck flask and stirred while being cooled with ice. To this solution, a solution of 17.0 g (110.0 mmol) of o-toluoyl chloride and 15 ml of N-methyl-2-pyrrolidinone (NMP) was slowly added dropwise. After the addition, the mixture was stirred at room temperature for 24 hours. The reaction solution was slowly added to 500 ml of water, so that a white solid was precipitated. The precipitated solid was subjected to ultrasonic washing in which water and 1M hydrochloric acid were used alternately. Then, ultrasonic washing using hexane was performed, so that 19.5 g of a white solid of N-benzoyl-N′-2-methylbenzoylhydrazide was obtained in a yield of 70%. A synthesis scheme of Step 1 is shown below.

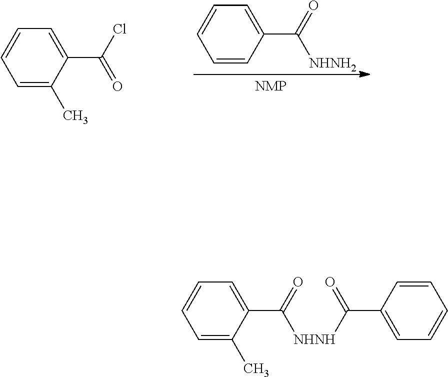

### Step 2: Synthesis of N-[1-Chloro-1-(2-methylphenyl)methylidene]-N′-[1-chloro-(1-phenyl)methylidene]hydr azine

Next, 12.0 g (47.2 mmol) of N-benzoyl-N′-2-methylbenzoylhydrazide obtained in Step 1 and 200 ml of toluene were put into a 500-ml three-neck flask. To this solution, 19.4 g (94.4 mmol) of phosphorus pentachloride was added and the mixture was heated and stirred at 120° C. for 6 hours. The reaction solution was slowly poured into 200 ml of water and the mixture was stirred for one hour. After the stirring, an organic layer and an aqueous layer were separated, and the organic layer was washed with water and a saturated aqueous solution of sodium hydrogen carbonate. After the washing, the organic layer was dried with anhydrous magnesium sulfate. The magnesium sulfate was removed from this mixture by gravity filtration, and the filtrate was concentrated; thus, 12.6 g of a brown liquid of N-[1-chloro-1-(2-methylphenyl)methylidene]-N′-[1-chloro-(1-phenyl)methylidene]hydrazine was obtained in a yield of 92%. A synthesis scheme of Step 2 is shown below.

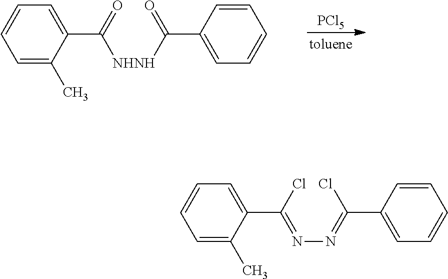

### Step 3: Synthesis of 3-(2-Methylphenyl)-4-(2,6-dimethylphenyl)-5-phenyl-4H-1,2,4-triazole (abbreviation: Hmpptz-dmp)

First, 12.6 g (43.3 mmol) of N-[1-chloro-1-(2-methylphenyl)methylidene]-N′-[1-chloro-(1-phenyl)methylidene]hydrazine obtained in Step 2, 15.7 g (134.5 mmol) of 2,6-dimethylaniline, and 100 ml of N,N-dimethylaniline were put into a 500-ml recovery flask and heated with stirring at 120° C. for 20 hours. The reaction solution was slowly added to 200 ml of 1N hydrochloric acid. Dichloromethane was added to this solution and an objective substance was extracted to an organic layer. The obtained organic layer was washed with water and an aqueous solution of sodium hydrogen carbonate, and was dried with magnesium sulfate. The magnesium sulfate was removed by gravity filtration, and the obtained filtrate was concentrated to give a black liquid. This liquid was purified by silica gel column chromatography. A mixed solvent of ethyl acetate and hexane in a ratio of 1:5 was used as a developing solvent. The obtained fraction was concentrated to give a white solid. This solid was recrystallized with ethyl acetate to give 4.5 g of a white solid of Hmpptz-dmp in a yield of 31%. A synthesis scheme of Step 3 is shown below.

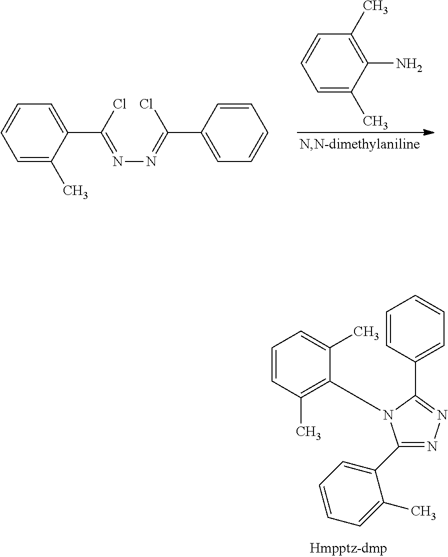

### Step 4: Synthesis of Ir(mpptz-dmp)₃

Then, 2.5 g (7.4 mmol) of Hmpptz-dmp, which was the ligand obtained in Step 3, and 0.7 g (1.5 mmol) of tris(acetylacetonato)iridium(III) were put into a container for high-temperature heating, and degasification was carried out. The mixture in the reaction container was heated and stirred at 250° C. for 48 hours under Ar flow. The obtained solid was washed with dichloromethane, and an insoluble green solid was obtained by suction filtration. This solid was dissolved in toluene and filtered through a stack of alumina and Celite. The obtained filtrate was concentrated to give a green solid. This solid was recrystallized with toluene, so that 0.8 g of a green powder was obtained in a yield of 45%. A synthesis scheme of Step 4 is shown below.

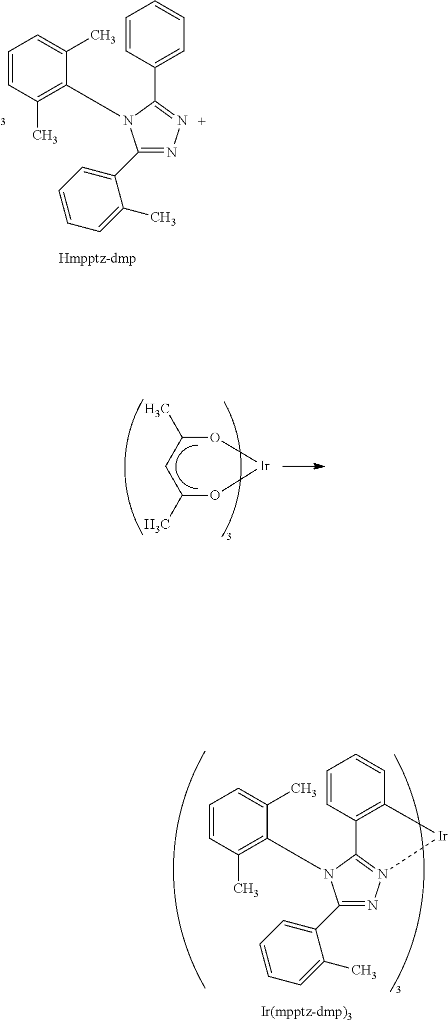

An analysis result by the ¹H-NMR spectroscopy of the green powder obtained in Step 4 is described below. The result revealed that Ir(mpptz-dmp)₃ was obtained by the synthesis method.

¹H-NMR. δ (toluene-d8): 1.82 (s, 9H), 1.90 (s, 9H), 2.64 (s, 9H), 6.56-6.62 (m, 9H), 6.67-6.75 (m, 9H), 6.82-6.88 (m, 3H), 6.91-6.97 (t, 3H), 7.00-7.12 (m, 6H), 7.63-7.67 (d, 3H).

### Reference Example 2

In this reference example, a synthesis method of PCBBiF, which was used in the above example, will be described.

### Step 1: Synthesis of N-(1,1′-Biphenyl-4-yl)-9,9-dimethyl-N-phenyl-9H-fluoren-2-amine

Into a 1-L three-neck flask were put 45 g (0.13 mol) of N-(1,1′-biphenyl-4-yl)-9,9-dimethyl-9H-fluoren-2-amine, 36 g (0.38 mol) of sodium tert-butoxide, 21 g (0.13 mol) of bromobenzene, and 500 mL of toluene. This mixture was degassed by being stirred under reduced pressure. After the degassing, the atmosphere in the flask was replaced with nitrogen. After that, 0.8 g (1.4 mmol) of bis(dibenzylideneacetone)palladium(0) and 12 mL (5.9 mmol) of tri(tert-butyl)phosphine (a 10 wt % hexane solution) were added thereto. This mixture was stirred under a nitrogen stream at 90° C. for two hours. After that, the mixture was cooled down to room temperature, and an insoluble part was separated by suction filtration. The obtained filtrate was concentrated to give about 200 mL of a brown liquid. This brown liquid and toluene were mixed, and the obtained solution was filtrated through Celite (produced by Wako Pure Chemical Industries, Ltd., Catalog No. 531-16855, the same shall apply hereinafter) and Florisil (produced by Wako Pure Chemical Industries, Ltd., Catalog No. 540-00135, the same shall apply hereinafter). The obtained filtrate was concentrated to give a light yellow liquid. To the obtained light yellow liquid was added hexane to a precipitate light yellow powder, whereby 52 g of an objective was obtained in a yield of 95%. The synthesis scheme of Step 1 is shown below.

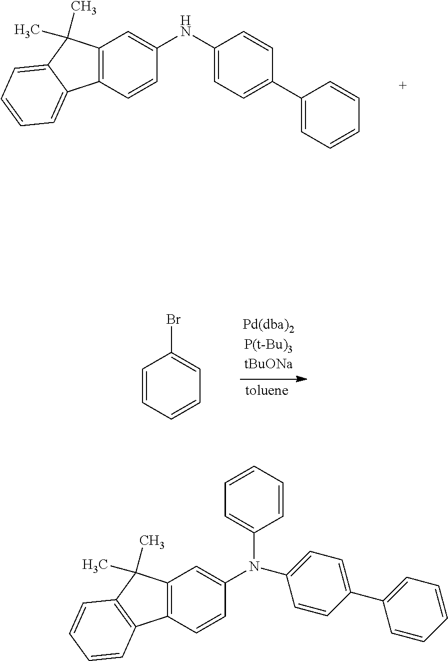 [SMILES: CC1(C)c2ccccc2-c2ccc(Nc3ccc(-c4ccccc4)cc3)cc21 ; Brc1ccccc1 ; CC1(C)c2ccccc2-c2ccc(N(c3ccccc3)c3ccc(-c4ccccc4)cc3)cc21]

### Step 2: Synthesis of N-(1,1′-Biphenyl-4-yl)-N-(4-bromophenyl)-9,9-dimethyl-9H-fluoren-2-amine

Into a 1-L Mayer flask was put 45 g (0.10 mol) of N-(1,1′-biphenyl-4-yl)-9,9-dimethyl-N-phenyl-9H-fluoren-2-amine which was then dissolved in 225 mL of toluene by stirring while being heated. This solution was cooled down to room temperature, 225 mL of ethyl acetate was added thereto, and 18 g (0.10 mol) of N-bromosuccinimide (abbreviation: NBS) was added thereto. The mixture was stirred at room temperature for 2.5 hours. After the stirring, the mixture was washed three times with a saturated aqueous solution of sodium hydrogen carbonate, and washed once with saturated saline. Then, magnesium sulfate was added to the obtained organic layer, and the obtained mixture was dried for two hours. The obtained mixture was subjected to natural filtration to remove magnesium sulfate, and the filtrate was concentrated to give a yellow liquid. This yellow liquid and toluene were mixed, and the obtained solution was filtrated through Celite, alumina, and Florisil. The resulting filtrate was concentrated to give a light yellow solid. This light yellow solid was recrystallized from toluene/ethanol to give 47 g of an objective white powder in a yield of 89%. The synthesis scheme of Step 2 is shown below.

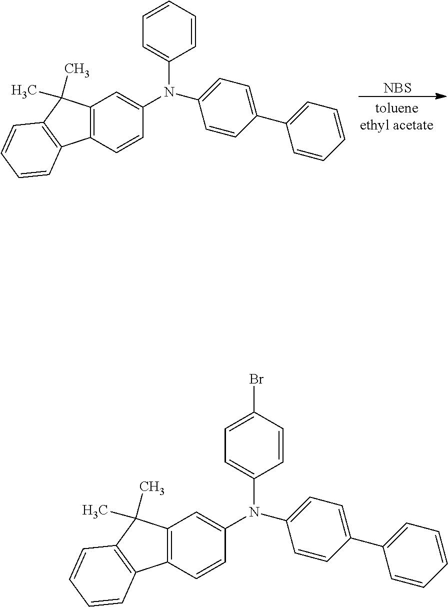

### Step 3: Synthesis of PCBBiF

Into a 1-L three-neck flask were put 41 g (80 mmol) of N-(1,1′-biphenyl-4-yl)-N-(4-bromophenyl)-9,9-dimethyl-9H-fluoren-2-amine and 25 g (88 mmol) of 9-phenyl-9H-carbazole-3-boronic acid, and 240 mL of toluene, 80 mL of ethanol, and 120 mL (2.0 mol/L) of a potassium carbonate solution were added thereto. This mixture was degassed by being stirred under reduced pressure, and then the atmosphere in the flask was replaced with nitrogen. To the mixture were added 27 mg (0.12 mmol) of palladium(II) acetate and 154 mg (0.5 mmol) of tri(ortho-tolyl)phosphine, and this mixture was degassed by being stirred under reduced pressure, and then the atmosphere in the flask was replaced with nitrogen. This mixture was stirred under a nitrogen stream at 110° C. for 1.5 hours.

After that, the mixture was cooled down to room temperature while being stirred, and an aqueous layer of the mixture was extracted twice with toluene. The extracted solution and the organic layer were combined and washed twice with water and twice with saturated saline. To this solution was added magnesium sulfate, and the mixture was dried. The obtained mixture was subjected to natural filtration to remove magnesium sulfate, and the filtrate was concentrated to give a brown solution. This brown solution and toluene were mixed, and the obtained solution was filtrated through Celite, alumina, and Florisil. The resulting filtrate was concentrated to give a light yellow solid. This light yellow solid was recrystallized from ethyl acetate/ethanol to give 46 g of an objective light yellow powder in a yield of 88%. The synthesis scheme of Step 3 is shown below.

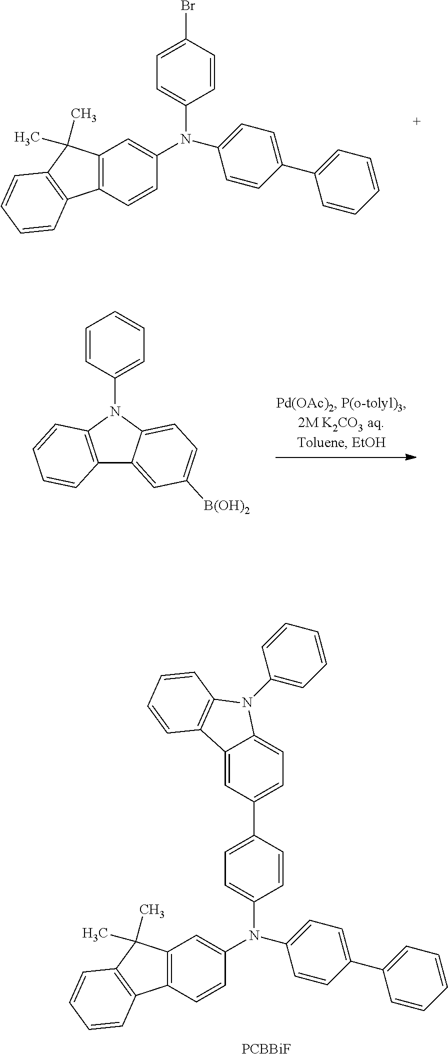

Then, 38 g of the obtained light yellow powder was purified by a train sublimation method. In the purification by sublimation, the light yellow powder was heated at 345° C. under a pressure of 3.7 Pa with a flow rate of argon gas of 15 mL/min. After the purification by sublimation, 31 g of a light yellow powder was obtained at a collection rate of 83%.

This compound was identified as PCBBiF, which was an objective substance, by a the NMR method.

¹H NMR data of the obtained light yellow solid are as follows: ¹H NMR (CDCl₃, 500 MHz): δ=1.45 (s, 6H), 7.18 (d, J=8.0 Hz, 1H), 7.27-7.32 (m, 8H), 7.40-7.50 (m, 7H), 7.52-7.53 (m, 2H), 7.59-7.68 (m, 12H), 8.19 (d, J=8.0 Hz, 1H), 8.36 (d, J=1.1 Hz, 1H).

This application is based on Japanese Patent Applications serial no. 2012-169696 and 2013-097202 filed with Japan Patent Office on Jul. 31, 2012 and May 3, 2013, respectively, the entire contents of which are hereby incorporated by reference.

What is claimed is:

1. A compound comprising:
an indolo[3,2,1-jk]carbazole skeleton; and
a heterocyclic skeleton bonded to the indolo[3,2,1-jk]carbazole skeleton through an arylene group,
wherein the heterocyclic skeleton contains a heterocycle selected from imidazole, pyrazine, pyrimidine, triazole.

2. The compound according to claim 1,
wherein the heterocycle is condensed with a benzene ring.

3. The compound according to claim 1,
wherein the arylene group is a substituted or unsubstituted phenylene group or a substituted or unsubstituted biphenyldiyl group.

4. The compound according to claim 1,
wherein the arylene group is a m-phenylene group.

5. A compound represented by a formula (G1): 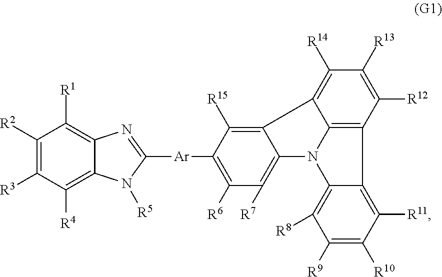
wherein:
R¹ to R⁴ and R⁶ to R¹⁵ each independently represent any one of hydrogen, an alkyl group having 1 to 4 carbon atoms, and an aryl group having 6 to 13 carbon atoms;
R⁵ represents an alkyl group having 1 to 4 carbon atoms or an aryl group having 6 to 13 carbon atoms; and
Ar represents an arylene group having 6 to 13 carbon atoms.

6. The compound according to claim 5,
wherein Ar is a substituted or unsubstituted phenylene group or a substituted or unsubstituted biphenyldiyl group.

7. The compound according to claim 5,
wherein the compound is represented by a formula (G2):

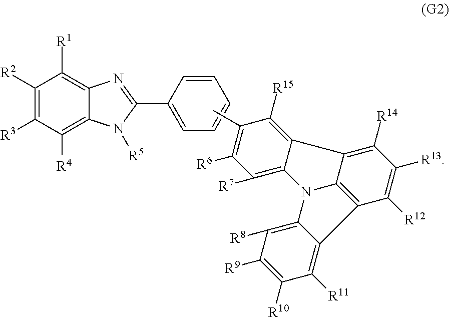

8. The compound according to claim 5,
wherein the compound is represented by a formula (G3):

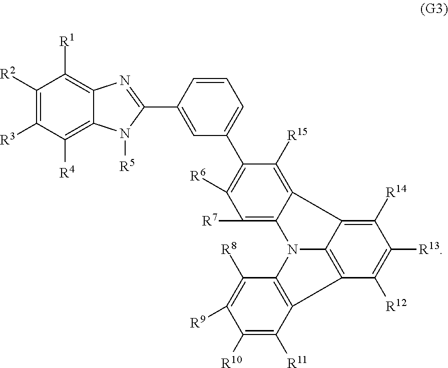

9. The compound according to claim 5,
wherein the compound is represented by a formula (G4):

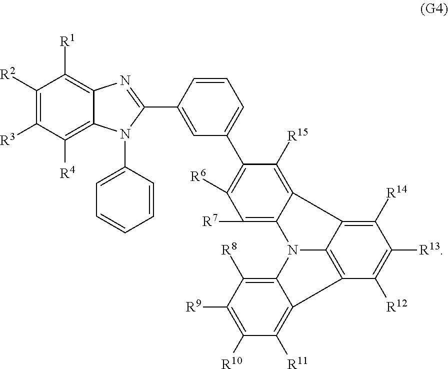

10. The compound according to claim 5,
wherein the compound is represented by a formula (100):

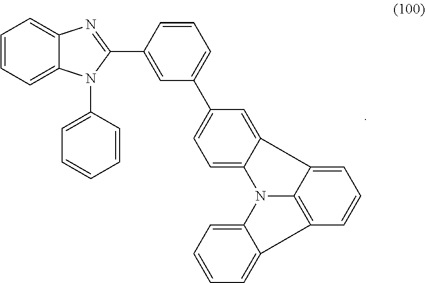 [SMILES: c1ccc(-n2c(-c3cccc(-c4ccc5c(c4)c4cccc6c7ccccc7n5c64)c3)nc3ccccc32)cc1]

11. A light-emitting element comprising:
a pair of electrodes; and
a layer between the pair of electrodes, the layer comprising the compound according to claim 5.

12. The light-emitting element according to claim 11, further comprising a phosphorescent material in the layer.

13. The light-emitting element according to claim 11, further comprising a substance which forms an exciplex with the compound.

14. An electronic device comprising the light-emitting element according to claim 11.

15. A lighting device comprising the light-emitting element according to claim 11.

16. A compound represented by a formula
wherein the compound is represented by a following formula:

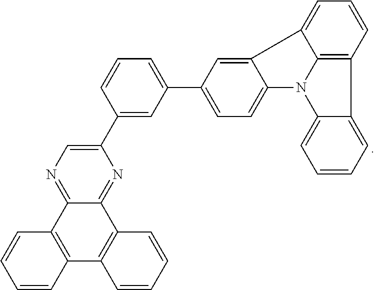 [SMILES: c1cc(-c2ccc3c(c2)c2cccc4c5ccccc5n3c42)cc(-c2cnc3c4ccccc4c4ccccc4c3n2)c1]

17. A light-emitting element comprising:
a pair of electrodes; and
a layer between the pair of electrodes, the layer comprising the compound according to claim 16.

18. The light-emitting element according to claim 17, further comprising a phosphorescent material in the layer.

19. An electronic device comprising the light-emitting element according to claim 17.

20. A lighting device comprising the light-emitting element according to claim 17.
